(19) United States
(12) Patent Application Publication
(10) Pub. No.: US 2025/0194160 A1
(43) Pub. Date: Jun. 12, 2025

(54) SEMICONDUCTOR DEVICE, MEMORY DEVICE, AND ELECTRONIC DEVICE

(71) Applicant: SEMICONDUCTOR ENERGY LABORATORY CO., LTD., Atsugi-shi, Kanagawa-ken (JP)

(72) Inventors: Hajime KIMURA, Atsugi, Kanagawa (JP); Shunpei YAMAZAKI, Setagaya, Tokyo (JP)

(21) Appl. No.: 18/845,571

(22) PCT Filed: Mar. 20, 2023
(86) PCT No.: PCT/IB2023/052692

§ 371 Date: Sep. 10, 2024

(30) Foreign Application Priority Data
Mar. 31, 2022 (JP) 2022-059018

(51) Int. Cl. H10D 30/67; H10B 12/00

(52) U.S. Cl. CPC H10D 30/6755; H10B 12/31

(57) ABSTRACT

A semiconductor device with high recording density is used. First and second transistors, first and second conductors, and first to third insulators are included. In the first transistor, an oxide semiconductor is located above the first insulator, a source and a drain are located over the semiconductor layer and the first insulator, and a gate is located above the semiconductor layer. The second insulator is located above the first insulator and includes an opening whose bottom surface corresponds to the first insulator and in which the first conductor is provided, in a region not overlapping with the source or the drain of the first transistor. The third insulator is located over the second insulator and the first conductor and includes an opening whose bottom surface corresponds to the gate of the first transistor and in which the second conductor is provided. In the second transistor, a semiconductor layer is located above the third insulator in a region overlapping with the first conductor, and a source and a drain are located over the semiconductor layer and the third insulator. In particular, one of the source and the drain is also located over the second conductor.

### TECHNICAL FIELD

One embodiment of the present invention relates to a semiconductor device, a memory device, and an electronic device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting apparatus, a power storage device, an image capturing device, a memory device, a signal processing device, a sensor, a processor, an electronic device, a system, a driving method thereof, a manufacturing method thereof, and a testing method thereof.

### BACKGROUND ART

In recent years, the amount of data subjected to processing has been increasing, which makes a demand for a memory device having a higher memory capacity. To increase memory capacity per unit area, stacking memory cells as in the case of a 3D NAND memory device or the like is effective (see Patent Document 1 to Patent Document 3). Stacking memory cells can increase memory capacity per unit area in accordance with the number of stacked memory cells.

### REFERENCES

### Patent Document

[Patent Document 1] United States Patent Application Publication No. 2011/0065270
[Patent Document 2] United States Patent Application Publication No. 2016/0149004
[Patent Document 3] United States Patent Application Publication No. 2013/0069052

### SUMMARY OF THE INVENTION

### Problems to be Solved by the Invention

An object of one embodiment of the present invention is to provide a semiconductor device with high memory capacity. Another object of one embodiment of the present invention is to provide a semiconductor device with high recording density. Another object of one embodiment of the present invention is to provide a novel semiconductor device or the like. Another object of one embodiment of the present invention is to provide a memory device including the above semiconductor device. Another object of one embodiment of the present invention is to provide an electronic device including the above memory device. Another object of one embodiment of the present invention is to provide a novel memory device or a novel electronic device.

Note that the objects of one embodiment of the present invention are not limited to the objects listed above. The objects listed above do not preclude the existence of other objects. Note that the other objects are objects that are not described in this section and will be described below. The objects that are not described in this section are derived from the description of the specification, the drawings, and the like and can be extracted as appropriate from the description by those skilled in the art. One embodiment of the present invention achieves at least one of the above objects and the other objects. Note that one embodiment of the present invention does not necessarily achieve all of the objects listed above and the other objects.

### Means for Solving the Problems

(1)

One embodiment of the present invention is a semiconductor device including a first layer and a first insulator. The first layer is located on a top surface of the first insulator. The first layer includes a first transistor, a second transistor, a first conductor, a second conductor, a second insulator, and a third insulator. Each of the first transistor and the second transistor includes a source electrode, a drain electrode, a gate electrode, and an oxide semiconductor.

The oxide semiconductor of the first transistor is located above the first insulator, each of the source electrode and the drain electrode of the first transistor is located on a top surface and a side surface of the oxide semiconductor of the first transistor and the top surface of the first insulator, and the gate electrode of the first transistor is located in a region overlapping with the oxide semiconductor of the first transistor. The second insulator is located above the first insulator and each of the source electrode and the drain electrode of the first transistor. The second insulator includes a first opening reaching the first insulator, in a region not overlapping with the source electrode or the drain electrode of the first transistor. Note that the first conductor is located in the first opening. The third insulator is located on a top surface of the second insulator, a top surface of the first conductor, and a top surface of the gate electrode of the first transistor. The third insulator includes a second opening reaching the gate electrode of the first transistor, in a region above the gate electrode of the first transistor. Note that the second conductor is located in the second opening.

The oxide semiconductor of the second transistor is located above the third insulator in a region overlapping with the first conductor; one of the source electrode and the drain electrode of the second transistor is located on a top surface and a side surface of the oxide semiconductor of the second transistor and a top surface of the third insulator; and the other of the source electrode and the drain electrode of the second transistor is located on the top surface and the side surface of the oxide semiconductor of the second transistor, the top surface of the third insulator, and a top surface of the second conductor. The gate electrode of the second transistor is located in a region overlapping with the oxide semiconductor of the second transistor.

(2)

Alternatively, in (1) described above, one embodiment of the present invention may have a structure in which the first layer includes a fourth insulator, a fifth insulator, and a third conductor. Note that the fourth insulator is preferably located above the third insulator and each of the source electrode and the drain electrode of the second transistor. The fourth insulator preferably includes a third opening reaching the other of the source electrode and the drain electrode of the second transistor, in a region not overlapping with the oxide semiconductor of the second transistor. The fifth insulator is preferably located on the top surface of the second conductor in the third opening and a side surface of the third insulator in the third opening, and the third conductor is preferably located on a top surface of the fifth insulator.

(3)

Alternatively, in (2) described above, one embodiment of the present invention may have a structure in which the gate electrode of the first transistor and the first conductor include the same conductive material. Furthermore, the gate electrode of the second transistor and the third conductor may include the same conductive material.

(4)

Alternatively, in (3) described above, one embodiment of the present invention may include a second layer and a sixth insulator. In particular, the second layer is preferably located on a top surface of the sixth insulator. The second layer preferably includes a third transistor. The third transistor preferably includes an oxide semiconductor. The sixth insulator is preferably located on a top surface of the fourth insulator, the top surface of the fifth insulator, a top surface of the third conductor, and a top surface of the gate electrode of the second transistor; and the oxide semiconductor of the third transistor is preferably located above the sixth insulator in a region overlapping with the third conductor.

(5)

Alternatively, in (4) described above, one embodiment of the present invention may have a structure in which each of the oxide semiconductor of the first transistor, the oxide semiconductor of the second transistor, and the oxide semiconductor of the third transistor includes one or more selected from indium, zinc, and an element M. In particular, the element M is preferably one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium.

(6)

Alternatively, one embodiment of the present invention is a memory device including the semiconductor device according to any one of (1) to (5) described above and a driver circuit, in which the first layer is located above the driver circuit.

(7)

Alternatively, one embodiment of the present invention is an electronic device including the memory device according to (6) described above and a housing.

### Effect of the Invention

According to one embodiment of the present invention, a semiconductor device with high memory capacity can be provided. According to another embodiment of the present invention, a semiconductor device with high recording density can be provided. According to another embodiment of the present invention, a novel semiconductor device or the like can be provided. According to another embodiment of the present invention, a memory device including the above semiconductor device can be provided. According to another embodiment of the present invention, an electronic device including the above memory device can be provided. According to another embodiment of the present invention, a novel memory device or a novel electronic device can be provided.

Note that the effects of one embodiment of the present invention are not limited to the effects listed above. The effects listed above do not preclude the presence of other effects. Note that the other effects are effects that are not described in this section and will be described below. The effects that are not described in this section can be derived from the description of the specification, the drawings, and the like and can be extracted as appropriate from the description by those skilled in the art. Note that one embodiment of the present invention has at least one of the effects listed above and the other effects. Accordingly, one embodiment of the present invention does not have the effects listed above in some cases.

### BRIEF DESCRIPTION OF THE DRAWINGS

FIG. 1 is a circuit diagram illustrating a structure example of a semiconductor device.

FIG. 2 is a circuit diagram illustrating a structure example of a semiconductor device.

FIG. 3 is a schematic cross-sectional view illustrating a structure example of a semiconductor device.

FIG. 4 is a schematic perspective view illustrating a structure example of a semiconductor device.

FIG. 5 is a schematic cross-sectional view illustrating a structure example of a semiconductor device.

FIG. 6 is a schematic cross-sectional view illustrating a structure example of a semiconductor device.

FIG. 7 is a schematic perspective view illustrating a structure example of a semiconductor device.

FIG. 8 is a layout diagram illustrating a structure example of a semiconductor device.

FIG. 9A is a schematic plan view illustrating a structure example of a semiconductor device, and FIG. 9B and FIG. 9C are schematic cross-sectional views illustrating the structure example of the semiconductor device.

FIG. 10A is a schematic plan view illustrating an example of a method for manufacturing a semiconductor device, and FIG. 10B and FIG. 10C are schematic cross-sectional views illustrating the example of the method for manufacturing a semiconductor device.

FIG. 11A is a schematic plan view illustrating an example of a method for manufacturing a semiconductor device, and FIG. 11B and FIG. 11C are schematic cross-sectional views illustrating the example of the method for manufacturing a semiconductor device.

FIG. 12A is a schematic plan view illustrating an example of a method for manufacturing a semiconductor device, and FIG. 12B and FIG. 12C are schematic cross-sectional views illustrating the example of the method for manufacturing a semiconductor device.

FIG. 13A is a schematic plan view illustrating an example of a method for manufacturing a semiconductor device, and FIG. 13B and FIG. 13C are schematic cross-sectional views illustrating the example of the method for manufacturing a semiconductor device.

FIG. 14A is a schematic plan view illustrating an example of a method for manufacturing a semiconductor device, and FIG. 14B and FIG. 14C are schematic cross-sectional views illustrating the example of the method for manufacturing a semiconductor device.

FIG. 15A is a schematic plan view illustrating an example of a method for manufacturing a semiconductor device, and FIG. 15B and FIG. 15C are schematic cross-sectional views illustrating the example of the method for manufacturing a semiconductor device.

FIG. 16A is a schematic plan view illustrating an example of a method for manufacturing a semiconductor device, and FIG. 16B and FIG. 16C are schematic cross-sectional views illustrating the example of the method for manufacturing a semiconductor device.

FIG. 17A is a schematic plan view illustrating an example of a method for manufacturing a semiconductor device, and FIG. 17B and FIG. 17C are schematic cross-sectional views illustrating the example of the method for manufacturing a semiconductor device.

FIG. 18A is a schematic plan view illustrating an example of a method for manufacturing a semiconductor device, and FIG. 18B and FIG. 18C are schematic cross-sectional views illustrating the example of the method for manufacturing a semiconductor device.

FIG. 19A is a schematic plan view illustrating an example of a method for manufacturing a semiconductor device, and FIG. 19B and FIG. 19C are schematic cross-sectional views illustrating the example of the method for manufacturing a semiconductor device.

FIG. 20A is a schematic plan view illustrating an example of a method for manufacturing a semiconductor device, and FIG. 20B and FIG. 20C are schematic cross-sectional views illustrating the example of the method for manufacturing a semiconductor device.

FIG. 21A is a schematic plan view illustrating an example of a method for manufacturing a semiconductor device, and FIG. 21B and FIG. 21C are schematic cross-sectional views illustrating the example of the method for manufacturing a semiconductor device.

FIG. 22A is a schematic plan view illustrating an example of a method for manufacturing a semiconductor device, and FIG. 22B and FIG. 22C are schematic cross-sectional views illustrating the example of the method for manufacturing a semiconductor device.

FIG. 23A is a schematic plan view illustrating an example of a method for manufacturing a semiconductor device, and FIG. 23B and FIG. 23C are schematic cross-sectional views illustrating the example of the method for manufacturing a semiconductor device.

FIG. 24A is a schematic plan view illustrating an example of a method for manufacturing a semiconductor device, and FIG. 24B and FIG. 24C are schematic cross-sectional views illustrating the example of the method for manufacturing a semiconductor device.

FIG. 25A is a schematic plan view illustrating an example of a method for manufacturing a semiconductor device, and FIG. 25B and FIG. 25C are schematic cross-sectional views illustrating the example of the method for manufacturing a semiconductor device.

FIG. 26A is a schematic plan view illustrating an example of a method for manufacturing a semiconductor device, and FIG. 26B and FIG. 26C are schematic cross-sectional views illustrating the example of the method for manufacturing a semiconductor device.

FIG. 27A is a schematic plan view illustrating an example of a method for manufacturing a semiconductor device, and FIG. 27B and FIG. 27C are schematic cross-sectional views illustrating the example of the method for manufacturing a semiconductor device.

FIG. 28A is a schematic plan view illustrating an example of a method for manufacturing a semiconductor device, and FIG. 28B and FIG. 28C are schematic cross-sectional views illustrating the example of the method for manufacturing a semiconductor device.

FIG. 29 is a circuit diagram illustrating a structure example of a semiconductor device.

FIG. 30 is a schematic cross-sectional view illustrating a structure example of a semiconductor device.

FIG. 31 is a circuit diagram illustrating a structure example of a semiconductor device.

FIG. 32 is a schematic cross-sectional view illustrating a structure example of a semiconductor device.

FIG. 33 is a circuit diagram illustrating a structure example of a semiconductor device.

FIG. 34 is a schematic cross-sectional view illustrating a structure example of a semiconductor device.

FIG. 35 is a schematic perspective view illustrating a structure example of a semiconductor device.

FIG. 36 is a circuit diagram illustrating a structure example of a semiconductor device.

FIG. 37 is a schematic cross-sectional view illustrating a structure example of a semiconductor device.

FIG. 38 is a schematic perspective view illustrating a structure example of a semiconductor device.

FIG. 39 is a schematic cross-sectional view illustrating a structure example of a semiconductor device.

FIG. 40A is a schematic plan view illustrating an example of a method for manufacturing a semiconductor device, and FIG. 40B and FIG. 40C are schematic cross-sectional views illustrating the example of the method for manufacturing a semiconductor device.

FIG. 41A is a schematic plan view illustrating an example of a method for manufacturing a semiconductor device, and FIG. 41B and FIG. 41C are schematic cross-sectional views illustrating the example of the method for manufacturing a semiconductor device.

FIG. 42A is a schematic plan view illustrating an example of a method for manufacturing a semiconductor device, and FIG. 42B and FIG. 42C are schematic cross-sectional views illustrating the example of the method for manufacturing a semiconductor device.

FIG. 43 is a circuit diagram illustrating a structure example of a semiconductor device.

FIG. 44 is a schematic cross-sectional view illustrating a structure example of a semiconductor device.

FIG. 45 is a circuit diagram illustrating a structure example of a semiconductor device.

FIG. 46 is a schematic cross-sectional view illustrating a structure example of a semiconductor device FIG. 47 is a schematic cross-sectional view illustrating a structure example of a semiconductor device.

FIG. 48A is a perspective view illustrating a structure example of the memory device, and FIG. 48B is a block diagram illustrating the structure example of the memory device.

FIG. 49 is a block diagram illustrating a structure example of a memory device.

FIG. 50 is a schematic cross-sectional view illustrating a structure example of a memory device.

FIG. 51A is a schematic perspective view illustrating an example of a semiconductor wafer, FIG. 51B is a perspective view illustrating an example of a chip, and FIG. 51C and FIG. 51D are schematic perspective views illustrating examples of electronic components.

FIG. 52 is a block diagram illustrating a CPU.

FIG. 53A is a block diagram illustrating a structure example of a display apparatus, and FIG. 53B is a circuit diagram illustrating an example of a pixel circuit included in the display apparatus.

FIG. 54 is a schematic cross-sectional view illustrating a structure example of a display apparatus.

FIG. 55A to FIG. 55J are schematic perspective views illustrating examples of electronic devices.

FIG. 56A to FIG. 56D are diagrams illustrating structure examples of electronic devices.

FIG. 57A to FIG. 57E are schematic perspective views illustrating examples of electronic devices.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. For example, an integrated circuit, a chip including an integrated circuit, and an electronic component including a chip in a package are each an example of the semiconductor device. Moreover, for example, a memory device, a display apparatus, a light-emitting apparatus, a lighting device, an electronic device, and the like themselves are semiconductor devices and include semiconductor devices in some cases.

In the case where there is description “X and Y are connected” in this specification and the like, a case where X and Y are electrically connected, a case where X and Y are functionally connected, and a case where X and Y are directly connected are regarded as being disclosed in this specification and the like. Accordingly, without being limited to a predetermined connection relation, for example, a connection relation shown in drawings or described with texts, a connection relation other than one shown in drawings or described with texts is regarded as being disclosed in the drawings or description with the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y. Note that a switch has a function of being controlled to be turned on or off. That is, the switch has a function of being in a conducting state (on state) or a non-conducting state (off state) to control whether current flows or not.

In the case where an element and a power supply line (e.g., a wiring supplying VDD (high power supply potential), VSS (low power supply potential), GND (the ground potential), or a desired potential) are both provided between X and Y, X and Y are not defined as being electrically connected. In the case where only a power supply line is provided between X and Y, there is no element between X and Y; therefore, X and Y are directly connected. Accordingly, in the case where only a power supply line is provided between X and Y, X and Y can be expressed as being “electrically connected”. However, in the case where an element and a power supply line are both provided between X and Y, X and Y are not defined as being electrically connected, although X and the power supply line are electrically connected (through the element) and Y and the power supply line are electrically connected. Note that in the case where a gate and a source of a transistor are provided between X and Y, X and Y are not defined as being electrically connected. Note that in the case where a gate and a drain of a transistor are provided between X and Y, X and Y are not defined as being electrically connected. That is, in the case where a drain and a source of a transistor are provided between X and Y, X and Y are defined as being electrically connected. Note that in the case where a capacitor is provided between X and Y, X and Y are defined as being electrically connected in some cases and not defined in other cases. For example, in the case where a capacitor is provided between X and Y in a structure of a digital circuit or a logic circuit, X and Y are not defined as being electrically connected in some cases. On the other hand, for example, in the case where a capacitor is provided between X and Y in a structure of an analog circuit, X and Y are defined as being electrically connected in some cases.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of current, or the like, an operational amplifier, a differential amplifier circuit, a source follower circuit, or a buffer circuit); a signal generation circuit; a memory circuit; or a control circuit) can be connected between X and Y. For instance, even if another circuit is interposed between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

The expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used, for example. Alternatively, it can be expressed as “X is electrically connected to Y through a source and a drain of a transistor, and X, the source of the transistor, the drain of the transistor, and Y are provided in this connection order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression similar to the above examples, a source and a drain of a transistor can be distinguished from each other to specify the technical scope. Note that these expressions are examples and the expression is not limited to these expressions. Here, each of X and Y denotes an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” includes a wiring having a resistance value, a transistor in which current flows between a source and a drain, a diode, and a coil. Thus, the term “resistor” can sometimes be replaced with the term “resistance”, “load”, “region having a resistance value”, or the like. Conversely, the term “resistance”, “load”, “region having a resistance value”, or the like can sometimes be replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can sometimes be replaced with the term “capacitance”. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

In this specification and the like, a transistor includes three terminals called a gate, a source, and a drain. The gate is a control terminal for controlling the conducting state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals.

In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of off-state current can be reduced, and the withstand voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

In this specification and the like, circuit elements such as a “light-emitting device” and a “light-receiving device” sometimes have polarities called an “anode” and a “cathode”. In the case of a “light-emitting device”, the “light-emitting device” can sometimes emit light when a forward bias is applied (a positive potential with respect to a “cathode” is applied to an “anode”). In the case of a “light-receiving device”, current is sometimes generated between an “anode” and a “cathode” when a zero bias or a reverse bias is applied (a negative potential with respect to a “cathode” is applied to an “anode”) and the “light-receiving device” is irradiated with light. As described above, an “anode” and a “cathode” are sometimes regarded as input/output terminals of the circuit elements such as a “light-emitting device” and a “light-receiving device”. In this specification and the like, an “anode” and a “cathode” of the circuit element such as a “light-emitting device” or a “light-receiving device” are sometimes called terminals (a first terminal, a second terminal, and the like). For example, one of an “anode” and a “cathode” is called a first terminal and the other of the “anode” and the “cathode” is called a second terminal in some cases.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

“Current” means a charge transfer phenomenon (electrical conduction); for example, the description “electrical conduction of positively charged particles occurs” can be rephrased as “electrical conduction of negatively charged particles occurs in the opposite direction”. Thus, unless otherwise specified, “current” in this specification and the like refers to a charge transfer phenomenon (electrical conduction) accompanied by carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of current” in a wiring or the like refers to the direction in which a carrier with a positive charge moves, and the amount of current is expressed as a positive value. In other words, the direction in which a carrier with a negative charge moves is opposite to the direction of current, and the amount of current is expressed as a negative value. Thus, in the case where the polarity of current (or the direction of current) is not specified in this specification and the like, the description “current flows from element A to element B” can be rephrased as “current flows from element B to element A”. The description “current is input to element A” can be rephrased as “current is output from element A”.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the scope of claims. Moreover, in this specification and the like, for example, a “first” component in one embodiment can be omitted in other embodiments or the scope of claims.

In this specification and the like, the terms for describing positioning, such as “over” and “under”, are sometimes used for convenience to describe the positional relation between components with reference to drawings. The positional relationship between components is changed as appropriate in accordance with the direction in which the components are described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relation are sometimes described using terms such as “row” and “column”. The positional relationship between components is changed as appropriate in accordance with the direction in which the components are described. Thus, the positional relation is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where two or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Similarly, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. In this specification and the like, the timing chart shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the circumstances. For example, even when two periods are shown to have an equal length, the two periods have different lengths in some cases. Furthermore, for example, even when one of two periods is shown long and the other is shown short, the two periods can have the equal length in some cases, or the one period has a short length and the other has a long length in other cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also collectively referred to as a metal oxide in some cases. A metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, at least one of an increase in the density of defect states in a semiconductor, a decrease in carrier mobility, and a decrease in crystallinity occurs in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen. In the case where the semiconductor is a silicon layer, examples of an impurity that changes characteristics of the semiconductor include Group 1 elements, Group 2 elements, Group 13 elements, and Group 15 elements (except oxygen and hydrogen).

In this specification and the like, a switch has a function of being in a conducting state (on state) or a non-conducting state (off state) to control whether current flows or not. Alternatively, a switch has a function of selecting and changing a current path. Thus, a switch may have two terminals or three or more terminals through which current flows, in addition to a control terminal. For example, an electrical switch or a mechanical switch can be used. That is, a switch can be any element capable of controlling current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conducting state” of the transistor refers to a state where a source electrode and a drain electrode of the transistor can be regarded as being electrically short-circuited or a state where a current can be made to flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

In the drawings in this specification, the size, the layer thickness, or the region is exaggerated for clarity in some cases. Therefore, the size, the layer thickness, or the region is not limited to the illustrated scale. The drawings are schematic views showing ideal examples, and embodiments of the present invention are not limited to shapes, values, or the like shown in the drawings. For example, variations in a signal, a voltage, or a current due to noise, variations in a signal, a voltage, or a current due to difference in timing, or the like can be included.

### Embodiment 1

In this embodiment, a semiconductor device of one embodiment of the present invention is described.

### <Circuit Structure Example 1 of Semiconductor Device>

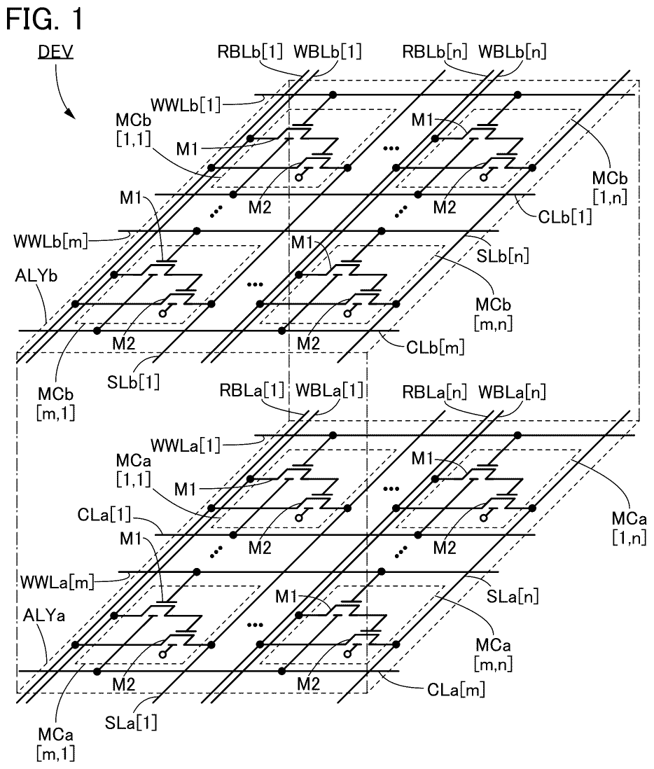

FIG. 1 is a circuit diagram illustrating a structure example of a semiconductor device DEV of one embodiment of the present invention. The semiconductor device DEV includes a memory layer ALYa and a memory layer ALYb, for example. Note that the memory layer ALYb is located above the memory layer ALYa in FIG. 1.

The memory layer ALYa and the memory layer ALYb each include memory cells. Specifically, in each of the memory layer ALYa and the memory layer ALYb, a plurality of memory cells may be arranged in an array. In FIG. 1, for example, the memory cells are arranged in a matrix of m rows and n columns (m is an integer of 1 or more and n is an integer of 1 or more) in each of the memory layer ALYa and the memory layer ALYb.

Note that in this specification and drawings, for example, a memory cell located in the first column and the first row of the matrix of the memory layer ALYa is referred to as a memory cell MCa[1,1], and a memory cell located in the m-th row and the n-th column of the matrix of the memory layer ALYb is referred to as a memory cell MCb[m,n].

In FIG. 1, a memory cell MCa and a memory cell MCb have similar circuit structures. Therefore, in the description common to the memory cell MCa and the memory cell MCb in this specification and the drawings, the memory cell MCa and the memory cell MCb are each described as a memory cell MC.

Note that although the number of rows and the number of columns of the matrix of the memory layer ALYa are equal to the number of rows and the number of columns of the matrix of the memory layer ALYb in FIG. 1, respectively, the number of rows and the number of columns of the matrix of the memory layer ALYa are not necessarily equal to the number of rows and the number of columns of the matrix of the memory layer ALYb, respectively.

Note that the memory cell MC illustrated in FIG. 1 is an example of a memory cell called a gain cell and includes a transistor M1 and a transistor M2. In particular, in this specification and the like, the structure of the memory cell MC in which OS transistors are used as the transistor M1 and the transistor M2 is referred to as a NOSRAM (registered trademark) (Nonvolatile Oxide Semiconductor Random Access Memory) in some cases.

OS transistors are preferably used as the transistor M1 and the transistor M2, for example. Specifically, examples of a metal oxide included in a channel formation region of the OS transistor include indium oxide, gallium oxide, and zinc oxide. The metal oxide preferably includes one or more selected from indium, an element M, and zinc. Note that the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more selected from aluminum, gallium, yttrium, and tin.

It is particularly preferable that an oxide containing indium (In), gallium (Ga), and zinc (Zn) (also referred to as IGZO) be used as the metal oxide used for the channel formation region. Alternatively, it is preferable to use an oxide containing indium (In), tin (Sn), and zinc (Zn) (also referred to as ITZO (registered trademark)). Alternatively, it is preferable to use an oxide containing indium (In), gallium (Ga), tin (Sn), and zinc (Zn). Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO). Note that the OS transistor will be described in detail in description of a cross-sectional structure example of the semiconductor device.

Transistors other than OS transistors may be used as the transistor M1 and the transistor M2. For example, transistors including silicon in channel formation regions (hereinafter referred to as Si transistors) can be employed as the transistor M1 and the transistor M2. As the silicon, single crystal silicon, amorphous silicon (sometimes referred to as hydrogenated amorphous silicon), microcrystalline silicon, or polycrystalline silicon (including low-temperature polycrystalline silicon) can be used, for example.

Examples of a transistor that can be used as each of the transistor M1 and the transistor M2 other than an OS transistor and a Si transistor include a transistor including germanium in a channel formation region, a transistor including a compound semiconductor, such as zinc selenide, cadmium sulfide, gallium arsenide, indium phosphide, gallium nitride, or silicon germanium, in a channel formation region, a transistor including a carbon nanotube in a channel formation region, and a transistor including an organic semiconductor in a channel formation region.

As the transistor M1 and the transistor M2, transistors having the same structure or different structures may be used. For example, the transistor M1 and the transistor M2 may each be an OS transistor; alternatively, the transistor M1 may be an OS transistor and the transistor M2 may be a Si transistor.

Although the transistor M1 and the transistor M2 illustrated in FIG. 1 are n-channel transistors, the transistor M1 and the transistor M2 may be p-channel transistors depending on conditions or circumstances. In the case where n-channel transistors are replaced with p-channel transistors, a potential or the like input to the memory cell MC needs to be appropriately changed so that the memory cell MC normally operates. Note that the same applies to transistors described in other parts of the specification and transistors illustrated in other drawings, not only to that in FIG. 1. In this embodiment, the structure of the memory cell MC is described assuming that the transistor M1 and the transistor M2 are n-channel transistors.

Each of the transistor M1 and the transistor M2 in an on state preferably operates in a saturation region. For example, in the case where the gate-source voltage of the transistor M1 or the transistor M2 is constant, current flowing between the source and the drain of the transistor M1 or the transistor M2 is larger in the case where the transistor M1 or the transistor M2 operates in a saturation region than in the case where the transistor M1 or the transistor M2 operates in a linear region. When the amount of current is increased, the transmission speed of a signal is increased; as a result, the operation speed of the circuit can be increased.

Depending on circumstances, the transistor M1 and the transistor M2 in an on state may operate in a linear region. Alternatively, the transistor M1 and the transistor M2 may operate in a subthreshold region.

The transistor M1 is, for example, a transistor having a structure including a pair of gates with a channel sandwiched therebetween; the transistor M1 includes a first gate and a second gate. For convenience, the first gate is referred to as a gate (sometimes referred to as a front gate) and the second gate is referred to as a back gate so that they are distinguished from each other, but the first gate and the second gate can be interchanged; thus, the term “gate” can be replaced with the term “back gate”. Therefore, in this specification and the like, the term “gate” can be replaced with the term “back gate”. Similarly, the term “back gate” can be replaced with the term “gate”. As a specific example, a connection structure in which “a gate is electrically connected to a first wiring and a back gate is electrically connected to a second wiring” can be replaced with a connection structure in which “a back gate is electrically connected to a first wiring and a gate is electrically connected to a second wiring”.

Similarly, for example, the transistor M2 may be a transistor having a structure including a pair of gates with a channel sandwiched therebetween, like the transistor M1. Note that the memory cell MC in the semiconductor device of one embodiment of the present invention does not depend on the connection structure of the back gate of the transistor M2. The back gate of the transistor M2 is illustrated in FIG. 1. Although the connection structure of the back gate is not illustrated, the destination to which the back gate is electrically connected can be determined at the design stage. For example, in a transistor including a back gate, a gate and the back gate may be electrically connected to each other to increase the on-state current of the transistor. In other words, the gate and the back gate of the transistor M2 may be electrically connected to each other. Alternatively, for example, in a transistor including a back gate, a wiring electrically connected to an external circuit may be provided and a fixed potential or a variable potential (also referred to as a pulse voltage in some cases) may be supplied to the back gate of the transistor with the external circuit to change the threshold voltage of the transistor or to reduce the off-state current of the transistor.

Note that the transistor M2 may have a transistor structure not including a back gate.

Note that the above description of the transistor applies to not only the transistor M1 and the transistor M2 but also transistors described in other parts of this specification and transistors illustrated in the other drawings.

Next, circuit structures of the memory cell MCa[1,1] to a memory cell MCa[m,n] are described.

In each of the memory cell MCa[1,1] to the memory cell MCa[m,n], a first terminal of the transistor M1 is electrically connected to the gate of the transistor M2.

In the memory cell MCa[1,1] to the memory cell MCa[m, 1] arranged in the first column of the matrix of the memory layer ALYa, a second terminal of the transistor M1 is electrically connected to a wiring WBLa[1], a first terminal of the transistor M2 is electrically connected to a wiring RBLa[1], and a second terminal of the transistor M2 is electrically connected to a wiring SLa[1]. In the memory cell MCa[1,n] to the memory cell MCa[m,n] arranged in the n-th column of the matrix of the memory layer ALYa, the second terminal of the transistor M1 is electrically connected to a wiring WBLa[n], the first terminal of the transistor M2 is electrically connected to a wiring RBLa[n], and the second terminal of the transistor M2 is electrically connected to a wiring SLa[n].

In each of the memory cell MCa[1,1] to the memory cell MCa[1,n] arranged in the first row of the matrix of the memory layer ALYa, the gate of the transistor M1 is electrically connected to a wiring WWLa[1], and the back gate of the transistor M1 is electrically connected to a wiring CLa[1]. In each of the memory cell MCa[m, 1] to the memory cell MCa[m,n] arranged in the m-th row of the matrix of the memory layer ALYa, the gate of the transistor M1 is electrically connected to a wiring WWLa[m], and the back gate of the transistor M1 is electrically connected to a wiring CLa[m].

For example, the wiring WWLa[1] to the wiring WWLa[m] function as write word lines for the memory cell MCa[1,1] to the memory cell MCa[m,n] included in the memory layer ALYa. That is, the wiring WWLa[1] to the wiring WWLa[m] function as wirings that transmit selection signals (which may be current or variable potentials (including pulse voltages)) for selecting the memory cells MCa on which writing is to be performed. Note that the wiring WWLa[1] to the wiring WWLa[m] may function as wirings that supply a constant potential depending on circumstances.

For example, the wiring WBLa[1] to the wiring WBLa[n] function as write bit lines for the memory cell MCa[1,1] to the memory cell MCa[m,n] included in the memory layer ALYa. That is, the wiring WBLa[1] to the wiring WBLa[n] function as wirings that transmit write data to the selected memory cells MCa. Note that the wiring WBLa[1] to the wiring WBLa[n] may function as wirings that supply a constant potential depending on circumstances.

For example, the wiring RBLa[1] to the wiring RBLa[n] function as read bit lines for the memory cell MCa[1,1] to the memory cell MCa[m,n] included in the memory layer ALYa. That is, the wiring RBLa[1] to the wiring RBLa[n] function as wirings that transmit data read from the selected memory cells MCa. Note that the wiring RBLa[1] to the wiring RBLa[n] and may function as wirings that supply a constant potential depending on circumstances.

For example, the wiring CLa[1] to the wiring CLa[m] function as wirings that supply a constant potential to the memory cell MCa[1,1] to the memory cell MCa[m,n] included in the memory layer ALYa. Note that the wiring CLa[1] to the wiring CLa[m] may function as wirings that supply variable potentials depending on circumstances.

Note that as illustrated in FIG. 1, the structure of the memory layer ALYb can be the same as that of the memory layer ALYa. Accordingly, the structure of the memory cell MCb can be the one in which, in the above description of the structure of the memory cell MCa, the wiring WWLa[1] to the wiring WWLa[m] are replaced with a wiring WWLb[1] to a wiring WWLb[m], respectively, the wiring WBLa[1] to a wiring WBLa[m] are replaced with a wiring WBLb[1] to a wiring WBLb[m], respectively, the wiring RBLa[1] to a wiring RBLa[m] are replaced with a wiring RBLb[1] to a wiring RBLb[m], respectively, and the wiring CLa[1] to the wiring CLa[m] are replaced with a wiring CLb[1] to a wiring CLb[m], respectively.

Thus, the wiring WWLb[1] to the wiring WWLb[m] function as write word lines in the memory layer ALYb. The wiring WBLb[1] to the wiring WBLb[m] function as write bit lines in the memory layer ALYb. The wiring RBLb[1] to the wiring RBLb[m] function as read bit lines in the memory layer ALYb. The wiring CLb[1] to the wiring CLb[m] can be wirings that function in a manner similar to that for the wiring CLa[1] to the wiring CLa[m].

Next, data writing to the memory cells MC of the semiconductor device DEV illustrated in FIG. 1 and data reading from the memory cells MC are described. Here, as an example, data writing to the memory cell MCa[1,1] in the memory layer ALYa of the semiconductor device DEV and data reading from the memory cell MCa[1,1] are described.

To write data to the memory cell MCa[1,1] of the semiconductor device DEV illustrated in FIG. 1, first, a first potential (which can be, for example, a common potential, a low-level potential, or a ground potential) is supplied to the back gate of the transistor M2, for example. Next, a high-level potential is supplied to the wiring WWLa[1] to turn on the transistor M1 included in the memory cell MCa[1,1], and a low-level potential is supplied to the wiring WWLa[2] to the wiring WWLa[m] to turn off the transistors M1 included in the memory cells MCa of the second row to the m-th row. Then, data for writing is transmitted to the wiring WBLa[1], and a potential corresponding to the data is written to the gate of the transistor M2 of the memory cell MCa[1,1]. After the data writing to the gate of the transistor M2 of the memory cell MCa[1,1], a low-level potential is supplied to the wiring WWLa[1] to turn off the transistor M1 included in the memory cell MCa[1,1]. After that, a second potential (e.g., a negative potential) is supplied to the back gate of the transistor M2 to increase the threshold voltage of the transistor M2. Note that at that time, it is preferable that the transistor M2 be brought into an off state owing to the increase in the threshold voltage of the transistor M2.

To read data from the memory cell MCa[1,1] of the semiconductor device DEV illustrated in FIG. 1, first, the second potential supplied to the back gate of the transistor M2 is raised to the first potential, for example. At that time, the threshold voltage of the transistor M2 returns to the threshold voltage at the time of the data writing to the memory cell MCa[1,1]. Next, a constant potential is supplied to the wiring SLa[1], whereby a read signal (potential or current) corresponding to the potential of the gate of the transistor M2 is transmitted from the wiring SLa[1] to the wiring RBLa[1] through the transistor M2. After that, the read signal is input to a read circuit through the wiring RBLa[1], whereby the data written to the memory cell MCa[1,1] can be read.

That is, in the above read operation, a wiring electrically connected to the back gate of the transistor M2 of the memory cell MCa[1,1] functions as a read word line.

Note that data writing or data reading to/from another memory cell MCa can be performed by an operation similar to that described above. Data writing to the memory cell MCb of the memory layer ALYb or data reading from the memory cell MCb of the memory layer ALYb can also be performed by an operation similar to that described above.

Note that the circuit structure of the semiconductor device of one embodiment of the present invention is not limited to the structure in FIG. 1. The circuit structure of the semiconductor device DEV in FIG. 1 may be changed depending on circumstances.

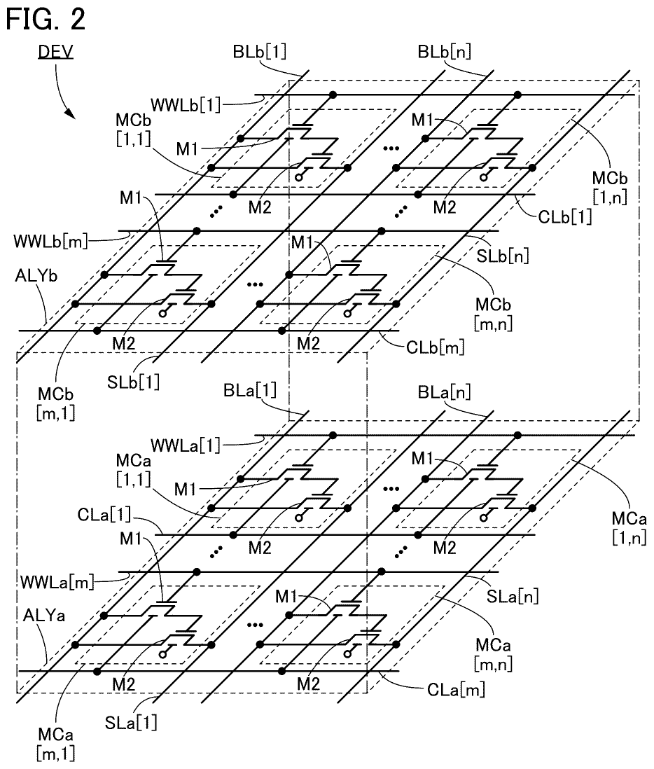

For example, the circuit structure of the semiconductor device DEV illustrated in FIG. 1 may be changed to that of the semiconductor device DEV illustrated in FIG. 2. The semiconductor device DEV in FIG. 2 has a structure in which one wiring has a function of a write bit line and a function of a read bit line in the semiconductor device DEV in FIG. 1. Specifically, the semiconductor device DEV in FIG. 2 has a structure in which the wiring WBLa[1] and the wiring RBLa[1] are combined into one wiring BLa[1], the wiring WBLa[n] and the wiring RBLa[n] are combined into one wiring BLa[n], the wiring WBLb[1] and the wiring RBLb[1] are combined into one wiring BLb[1], and the wiring WBLb[n] and the wiring RBLb[n] are combined into one wiring BLb[n].

The number of wirings extending to each of the memory layer ALYa and the memory layer ALYb in the semiconductor device DEV in FIG. 2 can be smaller than that in the semiconductor device DEV in FIG. 1. Furthermore, the area of the reduced wiring can be used as part of the memory cell MC, and thus the recording density of each of the memory layer ALYa and the memory layer ALYb can be increased in some cases.

### <Cross-Sectional Structure Example 1 of Semiconductor Device>

Next, a structure example of the semiconductor device DEV in FIG. 1 is described.

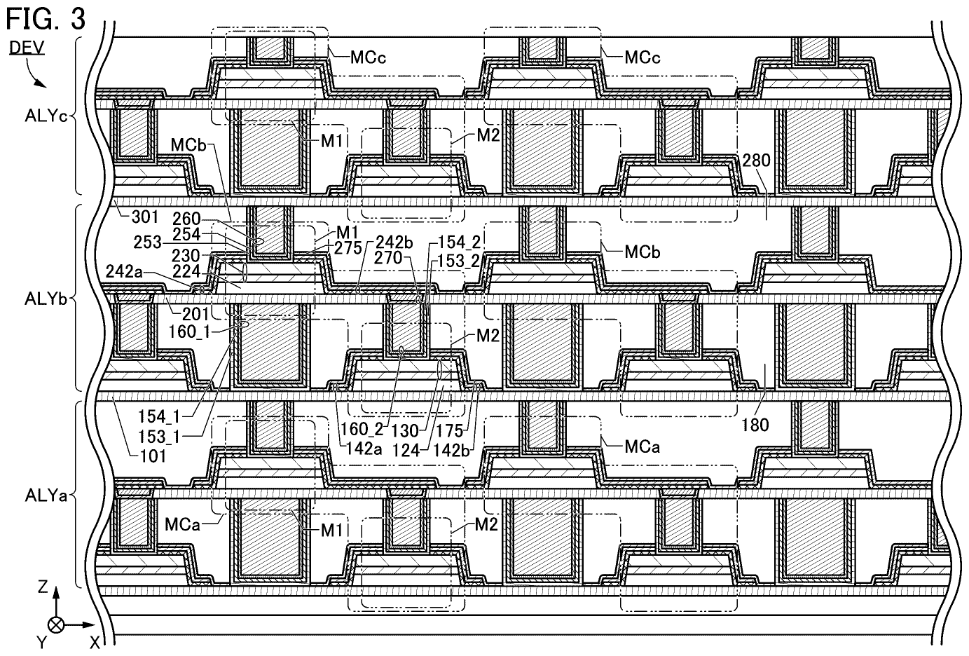

FIG. 3 is a schematic cross-sectional view illustrating the structure example of the semiconductor device DEV in FIG. 1 of one embodiment of the present invention. In FIG. 3, the semiconductor device DEV includes not only the memory layer ALYa and the memory layer ALYb but also a memory layer ALYc provided above the memory layer ALYb. The structure of the memory layer ALYc can be similar to that of the memory layer ALYa or the memory layer ALYb. Specifically, for example, a memory cell MCc included in the memory layer ALYc can have a structure similar to that of the memory cell MCa included in the memory layer ALYa or the memory cell MCb included in the memory layer ALYb.

Note that FIG. 3 illustrates a structure example in which the memory layer ALYa is provided below an insulator 101, the memory layer ALYb is provided over the insulator 101, an insulator 301 is provided over the memory layer ALYb, and the memory layer ALYc is provided over the insulator 301. Note that the details of the insulator 101 and the insulator 301 are described later.

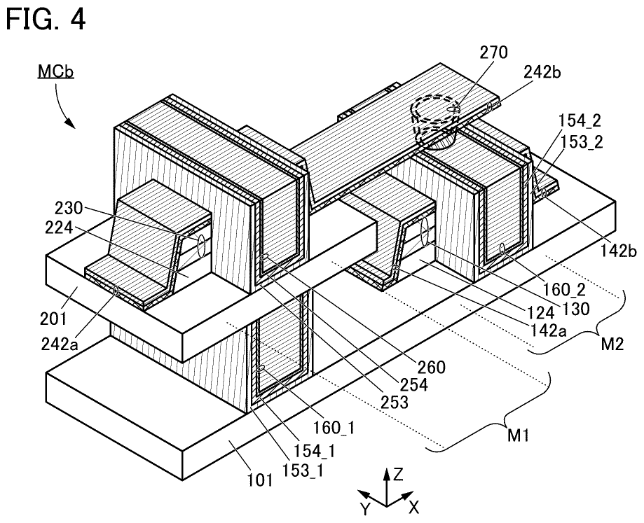

FIG. 4 is a schematic perspective view illustrating a structure example of the memory cell MCb of the semiconductor device DEV in FIG. 3. Note that in FIG. 4, hatching of the insulator 101, an insulator 201, and the insulator 301 is omitted intentionally, and part of the insulator 201, an insulator 180, an insulator 280, an insulator 175, and an insulator 275, which are described later, are not illustrated for easy viewing of the structure of the memory layer ALYb. Note that the details of the insulator 201, the insulator 180, the insulator 280, the insulator 175, and the insulator 275 are described later.

The X direction shown in FIG. 3 is parallel to the channel length directions of the transistor M1 and the transistor M2, the Y direction is perpendicular to the X direction, and the Z direction is perpendicular to the X direction and the Y direction. The X direction, the Y direction, and the Z direction shown in FIG. 3 form right-handed systems. Note that arrows indicating the X direction, the Y direction, and the Z direction in FIG. 3 are also shown in drawings described later.

In order to briefly describe the structure example of the semiconductor device DEV, first, attention is focused on the memory layer ALYb in FIG. 3.

In the memory layer ALYb, the memory cell MCb is provided over the insulator 101.

As described in the circuit structure example, the memory cell MC includes the transistor M1 and the transistor M2. Note that in FIG. 3, the transistor M1 and the transistor M2 are OS transistors, for example. That is, the semiconductor layer of each of the transistor M1 and the transistor M2 includes a metal oxide.

The transistor M1 includes an insulator 253, an insulator 254, a conductor 160_1, a conductor 242a, a conductor 242b, a conductor 260, and an oxide 230. In addition, the transistor M1 may include part of an insulator 224. The transistor M2 includes an insulator 153_2, an insulator 154_2, a conductor 160_2, a conductor 142a, a conductor 142b, and an oxide 130. In addition, the transistor M2 may include part of an insulator 124.

The transistor M2 is provided over the insulator 101, for example.

In the transistor M2, the conductor 160_2 is provided to overlap with a region including the oxide 130, for example. The conductor 160_2 functions as the gate (sometimes referred to as a first gate) of the transistor M2. Therefore, in this specification and the like, the conductor 160_2 is referred to as a gate electrode or a first gate electrode in some cases.

The insulator 153_2 and the insulator 154_2 functions as a first gate insulating film.

The insulator 124 and the oxide 130 are formed in this order over the insulator 101, for example. In particular, the oxide 130 functions as a semiconductor included in the channel formation region of the transistor M2.

The conductor 142a is provided over part of the top surface of the oxide 130 and part of the top surface of the insulator 101, for example. Similarly, the conductor 142b is provided over part of the top surface of the oxide 130 and part of the top surface of the insulator 101, for example. In particular, the conductor 142a and the conductor 142b are physically separated from each other by the conductor 160_2. The conductor 142a functions as one of a source and a drain of the transistor M2, and the conductor 142b functions as the other of the source and the drain of the transistor M2. The conductor 142a functions as any one of the wiring RBLb[1] to the wiring RBLb[n] in FIG. 1 or a conductor electrically connected to the wiring. The conductor 142b functions as any one of a wiring SLb[1] to a wiring SLb[n] in FIG. 1 or a conductor electrically connected to the wiring. Note that the insulator 175 for preventing diffusion of oxygen into the conductor 142a and the conductor 142b is provided over the conductor 142a and the conductor 142b.

In addition, the insulator 180 functioning as a planarization film or an interlayer film is provided over the insulator 175. Note that the insulator 180 is formed to cover the transistor M2. Note that the details of the insulator 180 are described later.

The conductor 160_1 is formed to be embedded in the insulator 180. The insulator 180 has an opening in a region overlapping with part of the oxide 230. An insulator 153_1, an insulator 154_1, and the conductor 160_1 are formed in this order in the opening.

The insulator 201 is provided over the insulator 180, the conductor 160_1, and the conductor 160_2. The insulator 201 has an opening reaching the conductor 160_2 in a region overlapping with part of the conductor 160_2. A conductor 270 is formed over the insulator 201 corresponding to a side surface of the opening and over the conductor 160_2 corresponding to a bottom portion of the opening. Thus, the conductor 270 and the conductor 160_2 are brought into conduction.

The transistor M1 is provided over the insulator 201, for example.

In the transistor M1, the conductor 260 is provided to overlap with a region including the oxide 230, for example. The conductor 260 functions as the gate (sometimes referred to as a first gate) of the transistor M1. Therefore, in this specification and the like, the conductor 260 is referred to as a gate electrode or a first gate electrode in some cases. The conductor 260 functions as any one of the wiring WWLb[1] to the wiring WWLb[m] in FIG. 1.

The insulator 253 and the insulator 254 functions as a first gate insulating film. The oxide 230 is provided to overlap with a region including the conductor 160_1 with the insulator 201 therebetween, for example. The oxide 230 functions as a semiconductor included in the channel formation region of the transistor M1.

The conductor 160_1 functions as the back gate (sometimes referred to as a second gate) of the transistor M1. Therefore, in this specification and the like, the conductor 160_1 is referred to as a back gate electrode or a second gate electrode in some cases.

In the case where the transistor M1 includes the back gate, the insulator 201 and the insulator 224 function as a second gate insulating film.

In the transistor M1, the conductor 242a is provided over part of the top surface of the oxide 230 and part of the top surface of the insulator 201, for example. Similarly, the conductor 242b is provided over part of the top surface of the oxide 230, part of the top surface of the insulator 201, and the top surface of the conductor 270, for example. In particular, the conductor 242a and the conductor 242b are physically separated from each other by the conductor 260. The conductor 242a functions as one of the source and the drain of the transistor M1, and the conductor 242b functions as the other of the source and the drain of the transistor M1. Therefore, in this specification and the like, the conductor 242a may be referred to as one of a source electrode and a drain electrode, and the conductor 242b may be referred to as the other of the source electrode and the drain electrode. The conductor 242a functions as any one of the wiring WBLb[1] to the wiring WBLb[n] in FIG. 1 or a conductor electrically connected to the wiring. Note that the insulator 275 for preventing diffusion of oxygen into the conductor 242a and the conductor 242b is provided over the conductor 242a and the conductor 242b.

In the transistor M1, the conductor 242b is provided over the top surface of the conductor 270; thus, the other of the source and the drain of the transistor M1 (the conductor 242b) is electrically connected to the gate (conductor 160_2) of the transistor M2.

The insulator 280 functioning as a planarization film or an interlayer film is provided over the insulator 275. Note that the insulator 280 is formed to cover the transistor M1. Note that the details of the insulator 280 are described later.

The insulator 301 is provided over the insulator 280 and the conductor 260.

The memory cell MCa is provided below the insulator 101. The memory cell MCc is provided over the insulator 301.

For the structures of the transistor M1 and the transistor M2 included in the memory cell MCa, the above description of the structures of the transistor M1 and the transistor M2 in the memory cell MCb is referred to. Similarly, for the structures of the transistor M1 and the transistor M2 included in the memory cell MCc, the above description of the structures of the transistor M1 and the transistor M2 in the memory cell MCb is referred to.

The same insulating material can be used for the insulator 101, the insulator 201, and the insulator 301. Note that specific insulating materials that are usable for the insulator 101, the insulator 201, and the insulator 301 are described later.

The same insulating material can be used for the insulator 180 and the insulator 280. Note that specific insulating materials that are usable for the insulator 180 and the insulator 280 are described later.

When the semiconductor device DEV is structured as illustrated in FIG. 3, the conductor corresponding to the gate of the transistor M2 and the conductor corresponding to the back gate of the transistor M1 can be formed at the same time. That is, the structure illustrated in FIG. 3 offers the following advantages: the number of photomasks for manufacturing the semiconductor device DEV is reduced as compared with that in the case of a conventional structure, and the manufacturing process of the semiconductor device DEV is shortened.

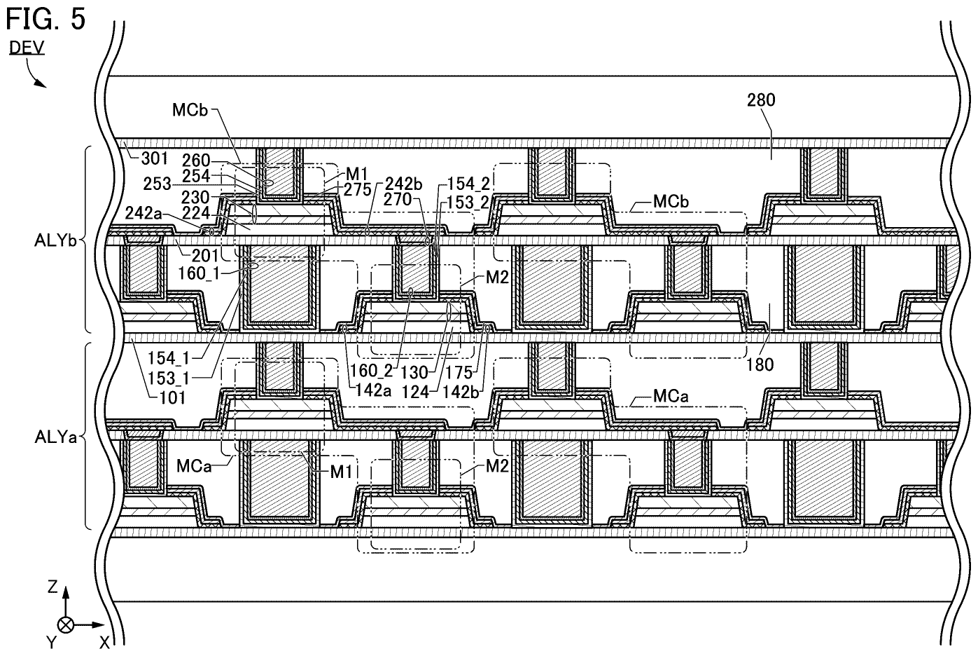

The structure of the semiconductor device DEV in FIG. 3 may be changed depending on circumstances. For example, the semiconductor device DEV illustrated in FIG. 3 includes three memory layers; however, the semiconductor device DEV of one embodiment of the present invention may include two memory layers as illustrated in FIG. 5. Note that FIG. 5 illustrates a structure of the semiconductor device DEV including only the memory layer ALYa and the memory layer ALYb. The semiconductor device DEV of one embodiment of the present invention may include four or more memory layers (not illustrated).

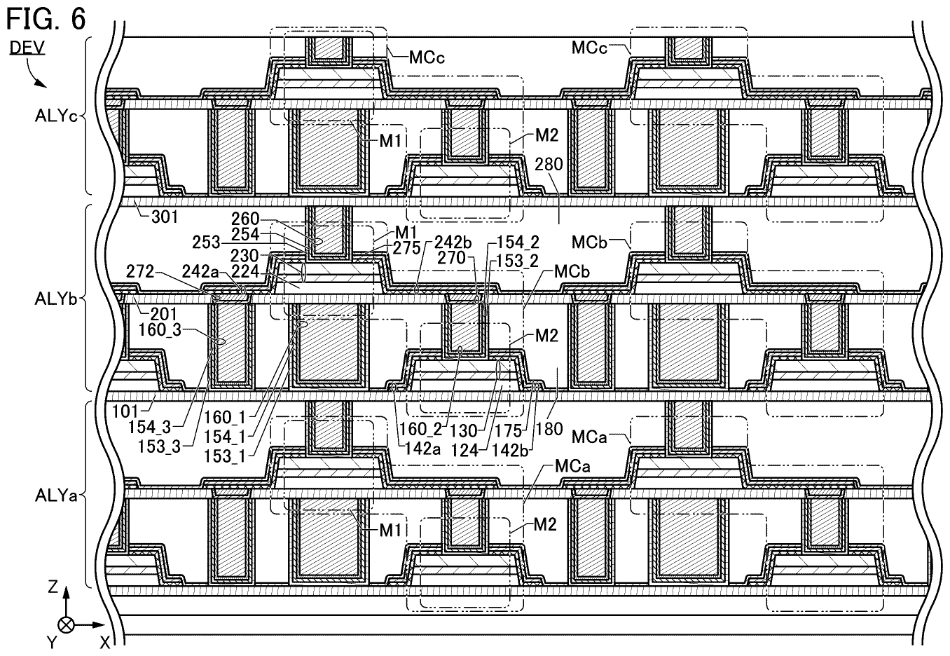

The structure of the semiconductor device DEV in FIG. 3 may be changed to that of the semiconductor device DEV illustrated in FIG. 6, for example. In the semiconductor device DEV in FIG. 6, an opening is provided in the insulator 180 in a region overlapping with the conductor 242a and not overlapping with the insulator 224 or the oxide 230, and an insulator 153_3, an insulator 154_3, and a conductor 160_3 are formed in this order in the opening. An opening is provided in the insulator 201 in a region overlapping with the conductor 242a and not overlapping with the insulator 224 or the oxide 230, and a conductor 272 is provided in the opening. Note that the conductor 242a is electrically connected to the conductor 160_3 through the conductor 272.

In the insulator 180, the opening where the insulator 153_3, the insulator 154_3, and the conductor 160_3 are embedded can be formed at the same time as the opening where the insulator 153_1, the insulator 154_1, and the conductor 160_1 are embedded, for example. Alternatively, the opening where the insulator 153_3, the insulator 154_3, and the conductor 160_3 are embedded may be formed at the same time as the opening where the insulator 153_2, the insulator 154_2, and the conductor 160_2 are embedded, for example. The insulator 153_3 can be formed at the same time as one or both of the insulator 153_1 and the insulator 153_2, for example. Thus, a material that is usable for one or both of the insulator 153_1 and the insulator 153_2 can be used for the insulator 153_3. Similarly, the insulator 154_3 can be formed at the same time as one or both of the insulator 154_1 and the insulator 154_2, for example. Thus, a material that is usable for one or both of the insulator 154_1 and the insulator 154_2 can be used for the insulator 154_3. Similarly, the conductor 160_3 can be formed at the same time as one or both of the conductor 160_1 and the conductor 160_2, for example. Thus, a material that is usable for one or both of the conductor 160_1 and the conductor 160_2 can be used for the conductor 160_3.

In the insulator 201, the opening where the conductor 272 is embedded can be formed at the same time as the opening where the conductor 270 is embedded, for example. The conductor 272 can be formed at the same time as the conductor 270, for example. Thus, a material that is usable for the conductor 270 can be used for the conductor 272.

One or both of the conductor 160_3 and the conductor 272 function as any one of the wiring WBLb[1] to the wiring WBLb[n] in the memory layer ALYb in FIG. 1, for example.

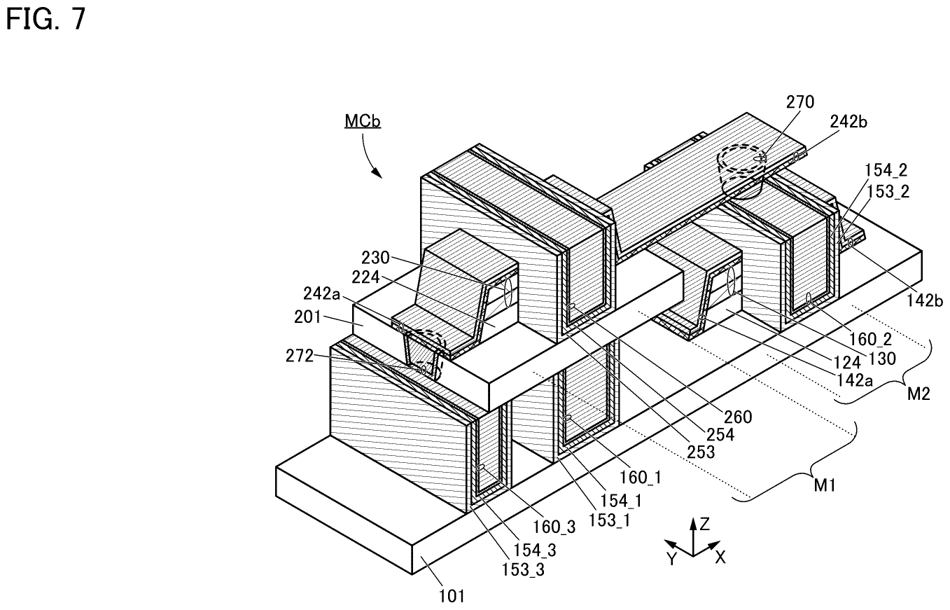

FIG. 7 is a schematic perspective view illustrating a structure example of the memory cell MCb of the semiconductor device DEV in FIG. 6. Note that in FIG. 6, hatching of the insulator 101 and the insulator 201 is omitted intentionally, and part of the insulator 201, part of the conductor 272, the insulator 180, the insulator 280, the insulator 175, and the insulator 275 are not illustrated for easily viewing of the stacked-layer structure of the memory layer ALYb. As illustrated in FIG. 7, the conductor 160_3 is extended along the channel width directions of the transistor M1 and the transistor M2 (the Y direction).

When the conductor functioning as the back gate of the transistor M1 and the conductor functioning as the gate of the transistor M2 are provided in the memory layer ALYb as illustrated in FIG. 3, FIG. 5, and FIG. 6, for example, the area occupied by the memory cell MC can be reduced. Accordingly, the semiconductor device can be miniaturized or highly integrated, resulting in high recording density.

### <Layout Example 1 of Semiconductor Device>

Next, the layout of the memory layer included in the semiconductor device DEV is described.

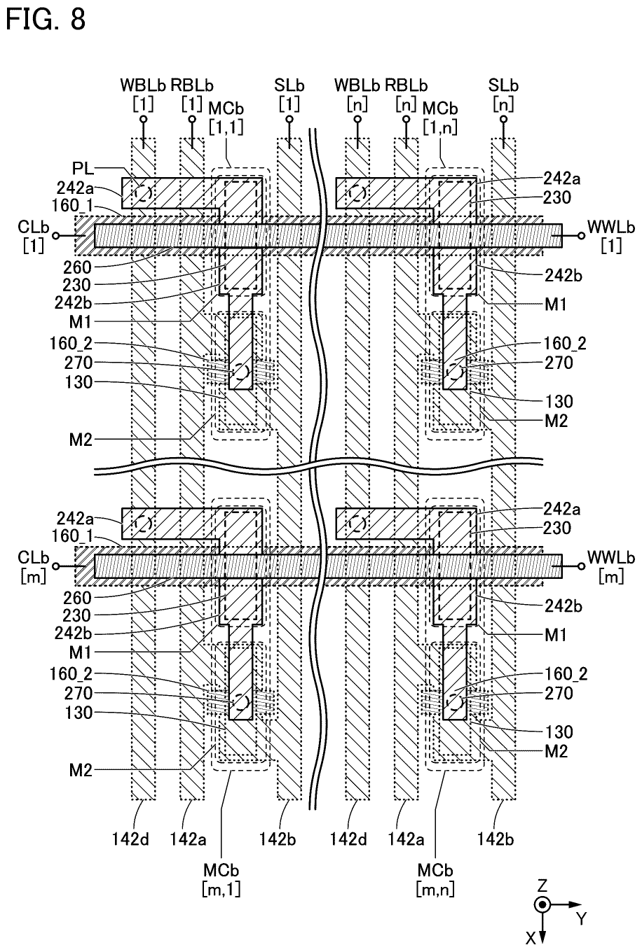

FIG. 8 is an example of a layout diagram (plan view) illustrating the circuit structure of the memory layer ALYb of the semiconductor device DEV illustrated in FIG. 3. Specifically, FIG. 8 selectively illustrates a memory cell MCb[1,1], a memory cell MCb[1,n], a memory cell MCb[m,1], and the memory cell MCb[m,n]. In addition, the insulators included in the semiconductor device DEV are not illustrated in FIG. 8.

In FIG. 8, the oxide 130 is provided in a region where the transistor M2 is formed. The conductor 142a and the conductor 142b are provided to cover part of the oxide 130. The conductor 160_2 is provided over part of the top surface of the oxide 130. The conductor 270 is provided over the conductor 160_2.

In FIG. 8, a conductor 142d is provided in a manner similar to those for the conductor 142a and the conductor 142b. Note that the conductor 142d can be formed at the same time as one or both of the conductor 142a and the conductor 142b.

Note that in FIG. 8, the conductor 142a, the conductor 142b, the conductor 142d, the oxide 130, and the conductor 270 are each indicated by a dotted line.

An opening PL provided in an interlayer film (not illustrated) is located over the conductor 142d. A conductor is embedded in the opening PL over the conductor 142d. Accordingly, the conductor embedded in the opening PL functions as a wiring or a plug.

In the memory layer ALYb in FIG. 8, the oxide 230 is provided in a region where the transistor M1 is formed. The conductor 242a and the conductor 242b that are different from the conductor 242a and the conductor 242b of the transistor M1 are provided to cover part of the oxide 230. The conductor 260 is provided above a region including the oxide 230.

The conductor 242a is electrically connected to the conductor 142d through the conductor provided in the opening PL. The conductor 242b is electrically connected to the conductor 160_2 through the conductor 270.

In the memory layer ALYb in FIG. 8, the conductor 142d is extended in the column direction. The conductor 142a and the conductor 142b of the transistor M2 are also extended in the column direction.

Since the conductor 142d and the conductor 242a of the transistor M1 are electrically connected to each other, the conductor 242a is provided above part of the conductor 142a of the transistor M2 in the layout in FIG. 8.

As illustrated in FIG. 8, the conductor 142d functions as the wiring WBLb[1] to the wiring WBLb[n] extending in the column direction.

As illustrated in FIG. 8, the conductor 142a of the transistor M2 functions as the wiring RBLb[1] to the wiring RBLb[n] extending in the column direction.

As illustrated in FIG. 8, the conductor 142b of the transistor M2 functions as the wiring SLb[1] to the wiring SLb[n] extending in the column direction.

As illustrated in FIG. 8, the conductor 260 functions as the wiring WWLb[1] to the wiring WWLb[m] extending in the row direction.

As illustrated in FIG. 8, the conductor 160_1 functions as the wiring CLb[1] to the wiring CLb[m] extending in the row direction.

Each of the oxide 130, the conductor 142a, the conductor 142b, the conductor 142d, the conductor 160_1, the conductor 160_2, the oxide 230, the conductor 242a, the conductor 242b, the conductor 260, the conductor 270, and the conductor provided in the opening PL can be formed by a photolithography method, for example. Specifically, for example, in the case where the conductor 242a is formed, a conductive material to be the conductor 242a is formed by one or more methods selected from a sputtering method, a CVD (Chemical Vapor Deposition) method, a PLD (Pulsed Laser Deposition) method, and an ALD (Atomic Layer Deposition) method, and then a desired pattern is formed by a photolithography method. The oxide 130, the conductor 142a, the conductor 142b, the conductor 142d, the conductor 160_1, the conductor 160_2, the oxide 230, the conductor 242b, the conductor 260, the conductor 270, and the conductor provided in the opening PL can also be formed by a method similar to the above.

For example, an insulator may be provided between the oxide 130 and the conductor 160_2 and between the oxide 230 and the conductor 260. In particular, each of the insulators functions as a first gate insulating film (also referred to as a gate insulating film or a front gate insulating film in some cases) of the transistor M1 or the transistor M2 in some cases.

In a process of forming the memory layer ALYb, planarization treatment using a chemical mechanical polishing method or the like may be performed in order that the heights of film surfaces on which one or more selected from an insulator, a conductor, and a semiconductor are formed can be equal to each other.

### <<Structure Example of Memory Cell>

Next, a structure example of the memory layer ALYb of the semiconductor device DEV illustrated in FIG. 3 is described.

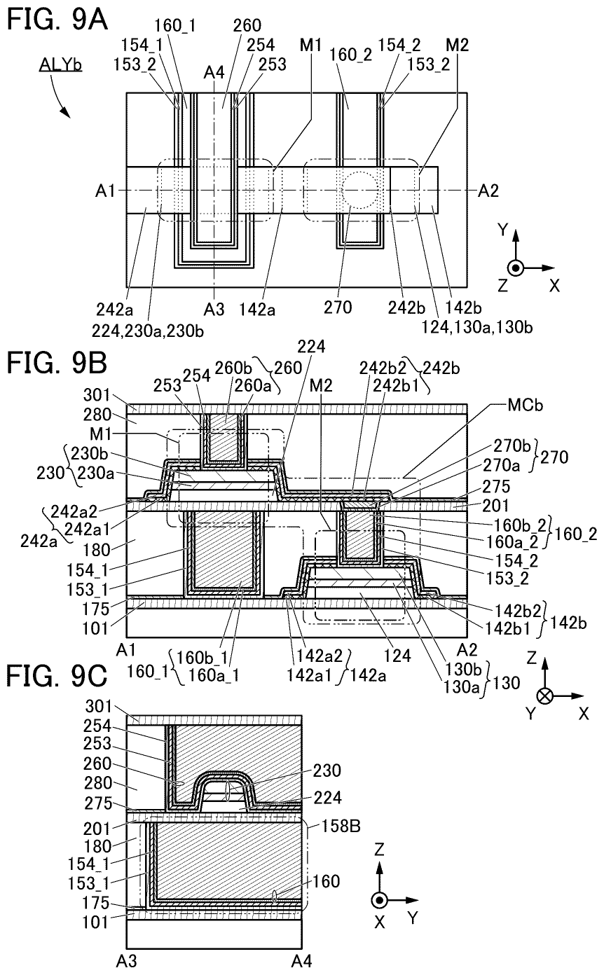

FIG. 9A to FIG. 9C are a schematic plan view and cross-sectional views of the memory layer ALYb including the transistor M1 and the transistor M2 in the semiconductor device DEV in FIG. 3. FIG. 9A is a schematic plan view of the memory layer ALYb. FIG. 9B and FIG. 9C are schematic cross-sectional views of the memory layer ALYb. Here, FIG. 9B is a cross-sectional view of a portion along dashed-dotted line A1-A2 illustrated in FIG. 9A, and is a cross-sectional view of the transistor M1 in the channel length direction. FIG. 9C is a schematic cross-sectional view of a portion along dashed-dotted line A3-A4 illustrated in FIG. 9A, and is a schematic cross-sectional view of the transistor M1 in the channel width direction. Note that some components are omitted in the top view of FIG. 9A for clarity of the drawing.

In FIG. 9B and FIG. 9C, a memory layer different from the memory layer ALYb is provided below the insulator 101 (not illustrated).

The semiconductor device DEV includes the insulator 101 above a substrate (not illustrated).

The memory layer ALYb includes the insulator 124 in part of a region over the insulator 101, an oxide 130a over the insulator 124, and an oxide 130b over the oxide 130a. The memory layer ALYb includes the conductor 142a (a conductor 142al and a conductor 142a2) and the conductor 142b (a conductor 142b1 and a conductor 142b2) that are located over the insulator 101 and the oxide 130b and cover the side surfaces of each of the insulator 124, the oxide 130a, and the oxide 130b. The memory layer ALYb includes the insulator 175 over the insulator 101, the conductor 142a, and the conductor 142b, and the insulator 180 over the insulator 175.

The memory layer ALYb includes the insulator 153_2 over the oxide 130b, the insulator 154_2 over the insulator 153_2, and the conductor 160_2 (a conductor 160a_2 and a conductor 160b_2) over the insulator 154_2. The memory layer ALYb includes the insulator 153_1 located in a region overlapping with the insulator 101 and not overlapping with the conductor 142a or the conductor 142b, the insulator 154_1 over the insulator 153_1, and the conductor 160_1 (a conductor 160a_1 and a conductor 160b_1) over the insulator 154_1.

In particular, the transistor M2 is provided to be embedded in the insulator 180.

In the region where the transistor M2 is formed, an opening reaching the oxide 130b is provided in the insulator 180 and the insulator 175. That is, the opening includes a region overlapping with the oxide 130b. It can also be said that the insulator 175 includes an opening overlapping with the opening included in the insulator 180. That is, the opening includes the opening included in the insulator 180 and the opening included in the insulator 175.

The insulator 153_2, the insulator 154_2, and the conductor 160_2 are provided in the opening. That is, the conductor 160_2 includes a region overlapping with the oxide 130b with the insulator 153_2 and the insulator 154_2 therebetween. The conductor 160_2, the insulator 153_2, and the insulator 154_2 are provided between the conductor 142a and the conductor 142b in the channel length direction of the transistor M2. The insulator 154_2 includes a region in contact with a side surface of the conductor 160_2 and a region in contact with the bottom surface of the conductor 160_2.

In a region where the conductor functioning as the back gate of the transistor M1 is formed, an opening reaching the insulator 101 is provided in the insulator 180 and the insulator 175. It can be said that the insulator 175 includes an opening overlapping with the opening included in the insulator 180. That is, the opening includes the opening included in the insulator 180 and the opening included in the insulator 175.

The insulator 153_1, the insulator 154_1, and the conductor 160_1 are provided in the opening. The insulator 153_1 includes a region in contact with a side surface of the opening and a region in contact with the insulator 101. The insulator 154_1 includes a region over and in contact with the insulator 153_1, and the conductor 160_1 includes a region over and in contact with the insulator 154_1.

The memory layer ALYb includes the insulator 201 over the insulator 180, the insulator 153_1, the insulator 154_1, the conductor 160_1, the insulator 153_2, the insulator 154_2, and the conductor 160_2. An opening is provided in the insulator 201 in a region overlapping with the conductor 160_2. The memory layer ALYb includes the conductor 270 (a conductor 270a and a conductor 270b) over the conductor 160_1 corresponding to a bottom portion of the opening and the insulator 201 corresponding to a side surface of the opening.

The memory layer ALYb includes the insulator 224 in part of a region over the insulator 201, an oxide 230a over the insulator 224, and an oxide 230b over the oxide 230a. The memory layer ALYb includes the conductor 242a (a conductor 242al and a conductor 242a2) and the conductor 242b (a conductor 242b1 and a conductor 242b2) that are located over the insulator 201 and the oxide 230b and cover the side surfaces of each of the insulator 224, the oxide 230a, and the oxide 230b. The memory layer ALYb includes the insulator 275 over the insulator 201, the conductor 242a, and the conductor 242b, and the insulator 280 over the insulator 275.

The memory layer ALYb includes the insulator 253 over the oxide 230b, the insulator 254 over the insulator 253, and the conductor 260 (a conductor 260a and a conductor 260b) over the insulator 254. The insulator 253 is located in a region overlapping with the insulator 201 and not overlapping with the conductor 242a or the conductor 242b.

In particular, the transistor M1 is provided to be embedded in the insulator 280.

In the region where the transistor M1 is formed, an opening reaching the oxide 230b is provided in the insulator 280 and the insulator 275. That is, the opening includes a region overlapping with the oxide 230b. It can also be said that the insulator 275 includes an opening overlapping with the opening included in the insulator 280. That is, the opening includes the opening included in the insulator 280 and the opening included in the insulator 275.

The insulator 253, the insulator 254, and the conductor 260 are placed in the opening. That is, the conductor 260 includes a region overlapping with the oxide 230b with the insulator 253 and the insulator 254 therebetween. The conductor 260, the insulator 253, and the insulator 254 are provided between the conductor 242a and the conductor 242b in the channel length direction of the transistor M1. The insulator 254 includes a region in contact with a side surface of the conductor 260 and a region in contact with the bottom surface of the conductor 260. Note that as illustrated in FIG. 9C, in a region of the opening that does not overlap with the oxide 230, the insulator 253, the insulator 254, and the conductor 260 are provided in this order over the top surface of the insulator 201.

The semiconductor device DEV includes the insulator 301 over the insulator 280, the insulator 253, the insulator 254, and the conductor 260.

The oxide 130 preferably includes the oxide 130a provided over the insulator 124 and the oxide 130b provided over the oxide 130a. Including the oxide 130a under the oxide 130b makes it possible to inhibit diffusion of impurities into the oxide 130b from components formed below the oxide 130a. Similarly, the oxide 230 preferably includes the oxide 230a provided over the insulator 224 and the oxide 230b provided over the oxide 230a. Including the oxide 230a under the oxide 230b makes it possible to inhibit diffusion of impurities into the oxide 230b from components formed below the oxide 230a.

In this specification and the like, the oxide 130a and the oxide 130b are collectively referred to as the oxide 130 in some cases. Similarly, in this specification and the like, the oxide 230a and the oxide 230b are collectively referred to as the oxide 230 in some cases.

Although the oxide 230 (or the oxide 130) has a structure in which two layers of the oxide 230a and the oxide 230b (or the oxide 130a and the oxide 130b) are stacked in the transistor M1 (or the transistor M2), the present invention is not limited thereto. For example, the oxide 230 (or the oxide 130) may be provided as a single layer of the oxide 230b (or the oxide 130b) or to have a stacked-layer structure of three or more layers; alternatively, the oxide 230a and the oxide 230b (or the oxide 130a and the oxide 130b) may each have a stacked-layer structure.

In FIG. 9A to FIG. 9C, the transistor M1 includes the oxide 230 functioning as a semiconductor layer, the conductor 260 functioning as a first gate (also referred to as a gate, a top gate, or a front gate) electrode, the conductor 160_1 functioning as a second gate (also referred to as a back gate) electrode, the conductor 242a functioning as one of a source electrode and a drain electrode, and the conductor 242b functioning as the other of the source electrode and the drain electrode. The insulator 253 and the insulator 254 functioning as a first gate insulator are also included. The insulator 201 and the insulator 224 functioning as a second gate insulator are also included. Note that the gate insulator is also referred to as a gate insulating layer or a gate insulating film in some cases. At least part of a region of the oxide 230 overlapping with the conductor 260 functions as a channel formation region.

In the transistor M1, the first gate electrode and the first gate insulating film are provided in the opening formed in the insulator 280 and the insulator 275. That is, the conductor 260, the insulator 254, and the insulator 253 are provided in the opening.

Similarly, in FIG. 9A to FIG. 9C, the transistor M2 includes the oxide 130 functioning as a semiconductor layer, the conductor 160_2 functioning as a first gate electrode, the conductor 142a functioning as one of a source electrode and a drain electrode, and the conductor 142b functioning as the other of the source electrode and the drain electrode. The insulator 153_2 and the insulator 154_2 functioning as a first gate insulator are also included. The insulator 101 and the insulator 124 located below the semiconductor 130 are also included. Note that the gate insulator is also referred to as a gate insulating layer or a gate insulating film in some cases. At least part of a region of the oxide 130 overlapping with the conductor 160_2 functions as a channel formation region.

In the transistor M2, the first gate electrode and the first gate insulating film are provided in the opening formed in the insulator 180 and the insulator 175. That is, the conductor 160_2, the insulator 154_2, and the insulator 153_2 are provided in the opening.

An opening reaching the conductor 160_2 is provided in a region of the insulator 201 that overlaps with the conductor 160_2. The conductor 270 is provided in the opening. The conductor 270 functions as a wiring or a plug.

The memory layer ALYb including the transistor M1 and the transistor M2, which is described in this embodiment, can be used for a memory device. In that case, the conductor 242a (or the conductor 242b) of the transistor M2 is electrically connected to a sense amplifier in some cases, and the conductor 242a (or the conductor 242b) functions as a read bit line.

### <<Example 1 of Method for Manufacturing Semiconductor Device>>

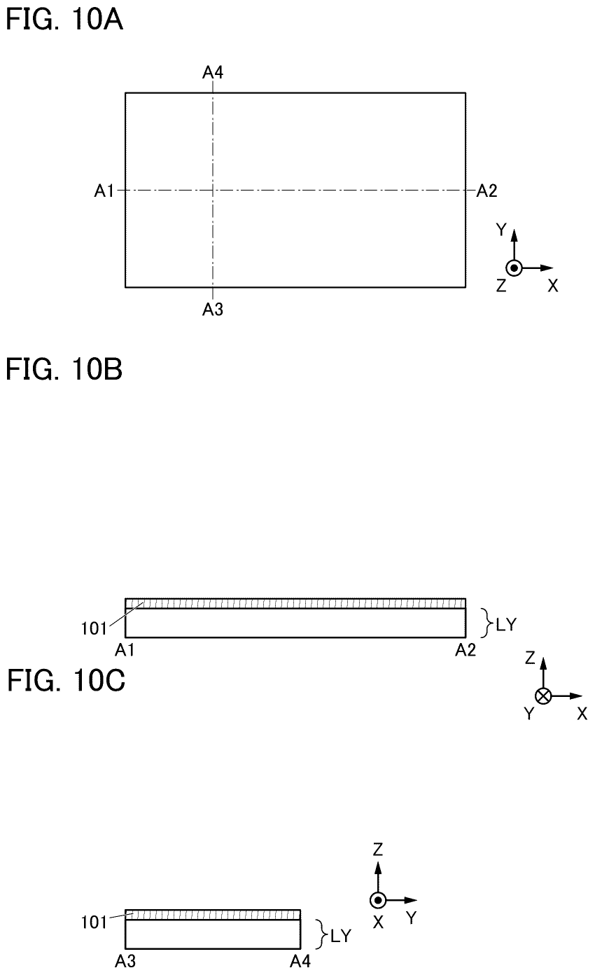

Next, an example of a method for manufacturing the memory layer ALYb of the semiconductor device DEV illustrated in FIG. 9A to FIG. 9C is described. Note that FIG. 10A to FIG. 23C are used for describing the example of the manufacturing method.

In each of FIG. 10A to FIG. 23C, A illustrates a schematic plan view. Moreover, B of each drawing is a schematic cross-sectional view corresponding to a portion along the dashed-dotted line A1-A2 illustrated in A of each drawing, and is also a schematic cross-sectional view of the transistor M1 in the channel length direction. Furthermore, C of each drawing is a schematic cross-sectional view corresponding to a portion along the dashed-dotted line A3-A4 illustrated in A of each drawing, and is also a schematic cross-sectional view of the transistor M1 in the channel width direction. Note that for clarity of the drawing, some components are not illustrated in the schematic plan view of A of each drawing.

Hereinafter, an insulating material for forming an insulator, a conductive material for forming a conductor, or a semiconductor material for forming a semiconductor can be deposited by a deposition method such as a sputtering method, a CVD method, an MBE (Molecular Beam Epitaxy) method, a PLD method, or an ALD method as appropriate.

First, a substrate (not illustrated) is prepared, and a layer LY that includes a driver circuit and the memory layer ALYa and is located below the memory layer ALYb is formed over the substrate (see FIG. 10A to FIG. 10C).

Next, the insulator 101 is deposited over the layer LY (see FIG. 10A to FIG. 10C). An insulator containing an oxide of one or both of aluminum and hafnium can be used for the insulator 101. Note that as the insulator containing an oxide of one or both of aluminum and hafnium, aluminum oxide, hafnium oxide, an oxide containing aluminum and hafnium (hafnium aluminate), or the like is preferably used. Alternatively, hafnium-zirconium oxide is preferably used. The insulator containing an oxide of one or both of aluminum and hafnium has a barrier property against oxygen, hydrogen, and water. When the insulator 101 has a barrier property against hydrogen and water, hydrogen and water contained in components provided around the transistor M1 and the transistor M2 are inhibited from diffusing into the transistor M1 and the transistor M2 through the insulator 101, and generation of oxygen vacancies in the oxide 130 (or the oxide 230) can be inhibited.

The insulator 101 can be deposited by a deposition method such as a sputtering method, a CVD method, an MBE method, a PLD method, or an ALD method. In this embodiment, as the insulator 101, hafnium oxide is deposited by an ALD method. It is particularly preferable to use a method for forming hafnium oxide with a reduced hydrogen concentration.

Note that a high-k material with a high dielectric constant may be used as the insulating material used for the insulator 101. Examples of the high-k material with a high dielectric constant include a metal oxide containing one kind or two or more kinds selected from aluminum, gallium, yttrium, zirconium, tungsten, titanium, tantalum, nickel, germanium, and magnesium in addition to the above-described hafnium oxide. Alternatively, aluminum oxide, hafnium oxide, and an oxide containing aluminum and hafnium (hafnium aluminate), which are insulators each containing an oxide of one or both of aluminum and hafnium, may be used for the insulator 101. Alternatively, a material that is usable for the insulator 153_1 or the insulator 154_1 described later may be used for the insulator 101. The insulator 101 may have a stacked-layer structure including two or more selected from the above-described materials.

Subsequently, heat treatment is preferably performed for one or more purposes selected from the following: improving the film quality of the insulator 101, removing impurities such as hydrogen and water from the insulator 101, and supplying oxygen to the insulator 101. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas may be approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent, for example, entry of moisture or the like into the insulator 101 as much as possible.

In this embodiment, as the heat treatment, treatment is performed at 400° C. for one hour with a flow rate ratio of a nitrogen gas to an oxygen gas of 4:1 after the deposition of the insulator 101. Through the heat treatment, impurities such as water and hydrogen contained in the insulator 101 can be removed. In the case where an oxide containing hafnium is used for the insulator 101, the insulator 101 is partly crystallized by the heat treatment in some cases. The heat treatment can also be performed after the deposition of the insulator 124, for example.

The transistor M1 is to be formed over the insulator 101 in a later step. Therefore, planarization treatment such as a CMP method is preferably performed on the insulator 101.

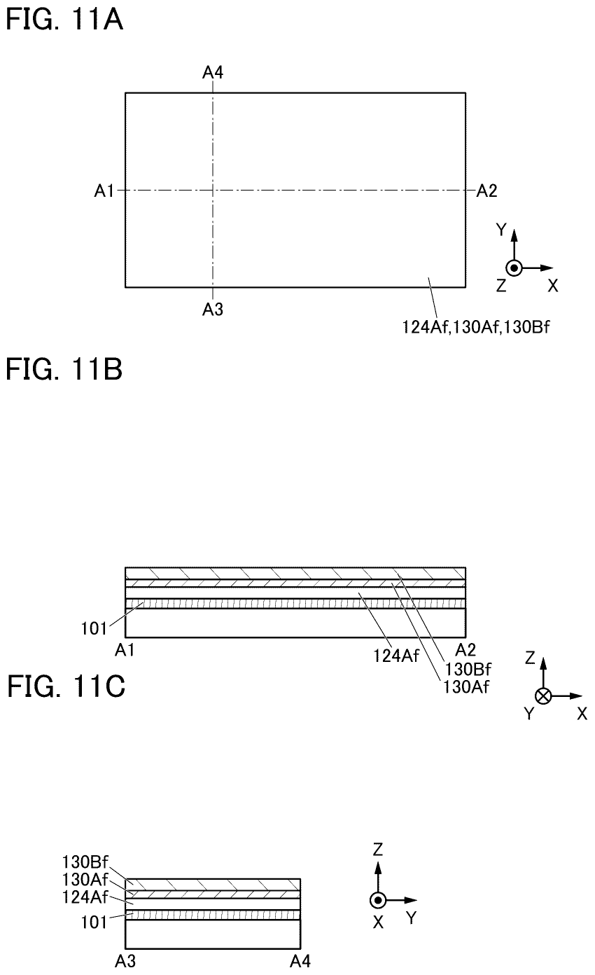

Next, an insulating film 124Af is formed over the insulator 101 (see FIG. 11A to FIG. 11C). The insulating film 124Af can be formed by a deposition method such as a sputtering method, a CVD method, an MBE method, a PLD method, or an ALD method. In this embodiment, as the insulating film 124Af, silicon oxide is deposited by a sputtering method. By using a sputtering method that does not need to use a molecule containing hydrogen as a deposition gas, the hydrogen concentration in the insulating film 124Af can be reduced. The hydrogen concentration in the insulating film 124Af is preferably reduced in this manner because the insulating film 124Af is in contact with the oxide 130a in a later step.

Other than silicon oxide, an insulating material such as silicon oxynitride may be used for the insulating film 124Af, for example.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

Next, an oxide film 130Af and an oxide film 130Bf are formed sequentially over the insulating film 124Af (see FIG. 11A to FIG. 11C). Note that the oxide film 130Af and the oxide film 130Bf are preferably formed successively without being exposed to an atmospheric environment. Through the formation without exposure to an atmospheric environment, impurities such as moisture from an atmospheric environment can be prevented from being attached onto the oxide film 130Af and the oxide film 130Bf, so that the vicinity of an interface between the oxide film 130Af and the oxide film 130Bf can be kept clean.

The oxide film 130Af and the oxide film 130Bf can be formed by a sputtering method, a CVD method, an MBE method, a PLD method, or an ALD method. In this embodiment, the oxide film 130Af and the oxide film 130Bf are formed by a sputtering method.

For example, in the case where the oxide film 130Af and the oxide film 130Bf are formed by a sputtering method, oxygen or a mixed gas of oxygen and a noble gas is used as a sputtering gas. Increasing the proportion of oxygen contained in the sputtering gas can increase the amount of excess oxygen in the formed oxide films. In the case where the oxide films are formed by a sputtering method, the above In-M-Zn oxide target or the like can be used.

In particular, when the oxide film 130Af is formed, part of oxygen contained in the sputtering gas is supplied to the insulator 124 in some cases. Thus, the proportion of oxygen contained in the sputtering gas is higher than or equal to 70%, preferably higher than or equal to 80%, further preferably 100%.

In the case where the oxide film 130Bf is formed by a sputtering method and the proportion of oxygen contained in the sputtering gas for deposition is higher than 30% and lower than or equal to 100%, preferably higher than or equal to 70% and lower than or equal to 100%, an oxygen-excess oxide semiconductor is formed. A transistor including an oxygen-excess oxide semiconductor for its channel formation region can have relatively high reliability. Note that one embodiment of the present invention is not limited thereto. In the case where the oxide film 130Bf is formed by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor for its channel formation region can have relatively high field-effect mobility. Furthermore, when the deposition is performed while the substrate is being heated, the crystallinity of the oxide film can be improved.

In this embodiment, for example, the oxide film 130Af is formed by a sputtering method using an oxide target with In:Ga:Zn=1:3:4 [atomic ratio]. The oxide film 130Bf is formed by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 130a and the oxide 130b by selecting the deposition conditions and the atomic ratios as appropriate.

Note that the insulating film 124Af, the oxide film 130Af, and the oxide film 130Bf are preferably formed by a sputtering method without exposure to the air. For example, a multi-chamber deposition apparatus is used. As a result, entry of hydrogen into the insulating film 124Af, the oxide film 130Af, and the oxide film 130Bf in intervals between deposition steps can be inhibited.

Note that the oxide film 130Af and the oxide film 130Bf may be formed by an ALD method. An ALD method is a deposition method that provides high controllability of a film thickness and small variation in a film thickness. Thus, when the oxide film 130Af and the oxide film 130Bf are formed by an ALD method, the oxide film 130Af and the oxide film 130Bf each having a uniform thickness can be formed. When a PEALD method is used, the oxide film 130Af and the oxide film 130Bf can be formed at a lower temperature than that in the case of using a thermal ALD method.

Next, heat treatment is preferably performed. The heat treatment can be performed in a temperature range where the oxide film 130Af and the oxide film 130Bf do not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas may be approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the oxide film 130Af, the oxide film 130Bf, and the like as much as possible.

In this embodiment, the heat treatment is performed at 400° C. for one hour with a flow rate ratio of a nitrogen gas to an oxygen gas being 4:1. Through such heat treatment using an oxygen gas, an impurity such as carbon, water, and hydrogen in the oxide film 130Af and the oxide film 130Bf can be reduced. The reduction of an impurity in the films improves the crystallinity of the oxide film 130Bf, thereby offering a dense structure with higher density. Thus, crystalline regions in the oxide film 130Af and the oxide film 130Bf are expanded, so that in-plane variations of the crystalline regions in the oxide film 130Af and the oxide film 130Bf can be reduced. Accordingly, an in-plane variation of electrical characteristics of the transistors M2 can be reduced.

By performing the heat treatment, hydrogen in the insulating film 124Af, the oxide film 130Af, and the oxide film 130Bf moves into the insulator 101 and is absorbed by the insulator 101. In other words, hydrogen in the insulating film 124Af, the oxide film 130Af, and the oxide film 130Bf diffuses into the insulator 101. Accordingly, the hydrogen concentration in the insulator 101 increases, while the hydrogen concentrations in the insulating film 124Af, the oxide film 130Af, and the oxide film 130Bf decrease.

In particular, the insulating film 124Af functions as a gate insulator of the transistor M2, and the oxide film 130Af and the oxide film 130Bf function as the channel formation region of the transistor M2. Thus, the transistor M2 preferably includes the insulating film 124Af, the oxide film 130Af, and the oxide film 130Bf with reduced hydrogen concentrations because favorable reliability can be obtained.

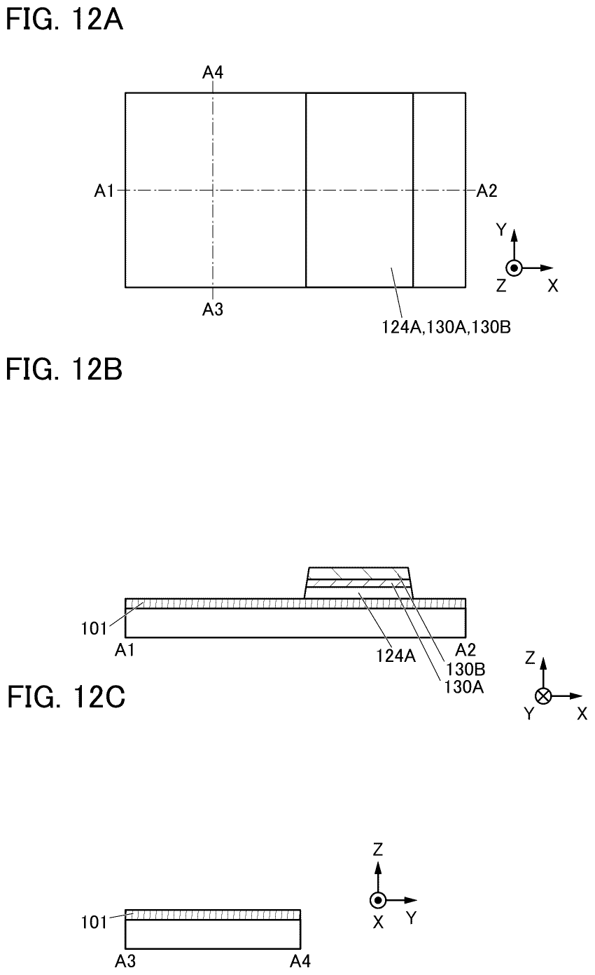

Next, the insulating film 124Af, the oxide film 130Af, and the oxide film 130Bf are processed into a band-like shape by a lithography method to form an insulating layer 124A, an oxide layer 130A, and an oxide layer 130B (see FIG. 12A to FIG. 12C). Here, the insulating layer 124A, the oxide layer 130A, and the oxide layer 130B are formed to extend in a direction parallel to the dashed-dotted line A3-A4 (the channel width direction of the transistor M2 or the Y direction illustrated in FIG. 12A). A dry etching method or a wet etching method can be used for the processing. Processing by a dry etching method is suitable for microfabrication. The insulating film 124Af, the oxide film 130Af, and the oxide film 130Bf may be processed under different conditions. The insulating film 124Af, the oxide film 130Af, and the oxide film 130Bf may be processed into a shape different from a band-like shape.

Note that in the lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask may be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a photomask is not necessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case where a hard mask is used, a hard mask with a desired shape can be formed in the following manner: an insulating film or a conductive film that is a hard mask material is formed over the oxide film 130Bf, a resist mask is formed thereover, and then the hard mask material is etched. The etching of the oxide film 130Bf and the like may be performed after removing the resist mask or with the resist mask remaining. In the latter case, the resist mask sometimes disappears during the etching. The hard mask may be removed by etching after the etching of the oxide film 130Bf and the like. Meanwhile, the hard mask is not necessarily removed when the hard mask material does not affect later steps or can be utilized in later steps.

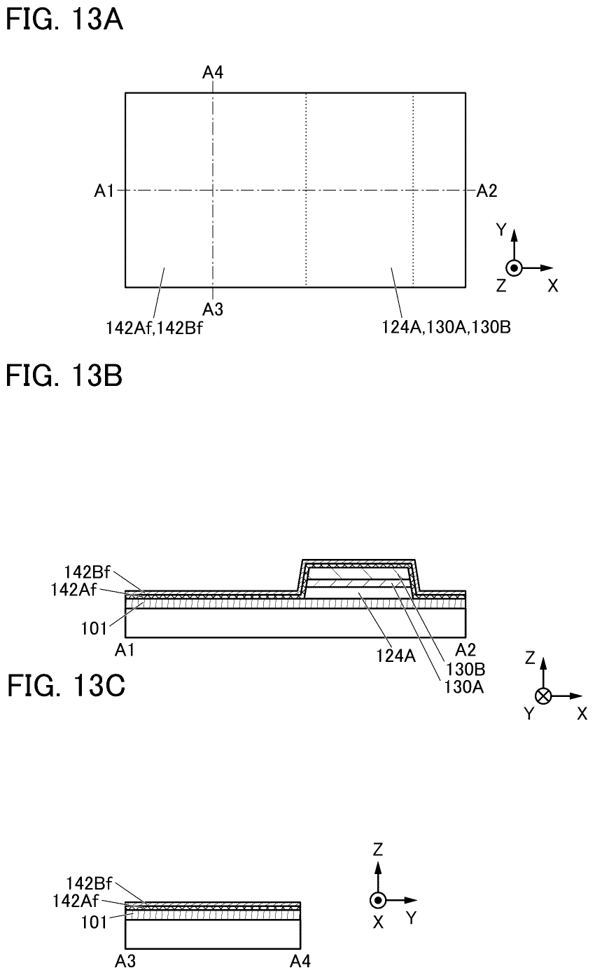

Next, a conductive film 142Af and a conductive film 142Bf are formed sequentially over the insulator 101 and the oxide layer 130B (see FIG. 13A to FIG. 13C). The conductive film 142Af and the conductive film 142Bf can be formed by a deposition method such as a sputtering method, a CVD method, an MBE method, a PLD method, or an ALD method. For example, tantalum nitride is deposited as the conductive film 142Af by a sputtering method and tungsten is deposited as the conductive film 142Bf. Note that heat treatment may be performed before the formation of the conductive film 142Af. This heat treatment may be performed under reduced pressure, and the conductive film 142Af may be successively formed without exposure to the air. Such treatment can remove moisture and hydrogen adsorbed onto the surface of the oxide layer 130B, and further can reduce the moisture concentration and the hydrogen concentration in the oxide layer 130A and the oxide layer 130B. The heat treatment is preferably performed at a temperature higher than or equal to 100° C. and lower than or equal to 400° C. In this embodiment, the heat treatment is performed at 200° C.

Note that for the conductive film 142Af, a conductive material such as a nitride containing tantalum, a nitride containing titanium, a nitride containing molybdenum, a nitride containing tungsten, a nitride containing tantalum and aluminum, or a nitride containing titanium and aluminum may be used other than tantalum nitride, for example. For another example, a conductive material such as ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

For the conductive film 142Bf, other than tungsten, a conductive material, e.g., a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like, may be used. For example, a conductive material such as titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel may be used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

Materials that are usable for both the conductive film 142Af and the conductive film 142Bf may be used for the conductive film 142Af and the conductive film 142Bf. Alternatively, the same material may be used for the conductive film 142Af and the conductive film 142Bf. That is, the conductor 142al and the conductor 142a2 may be one conductor in the memory cell MC. Similarly, the conductor 142b1 and the conductor 142b2 may be one conductor.

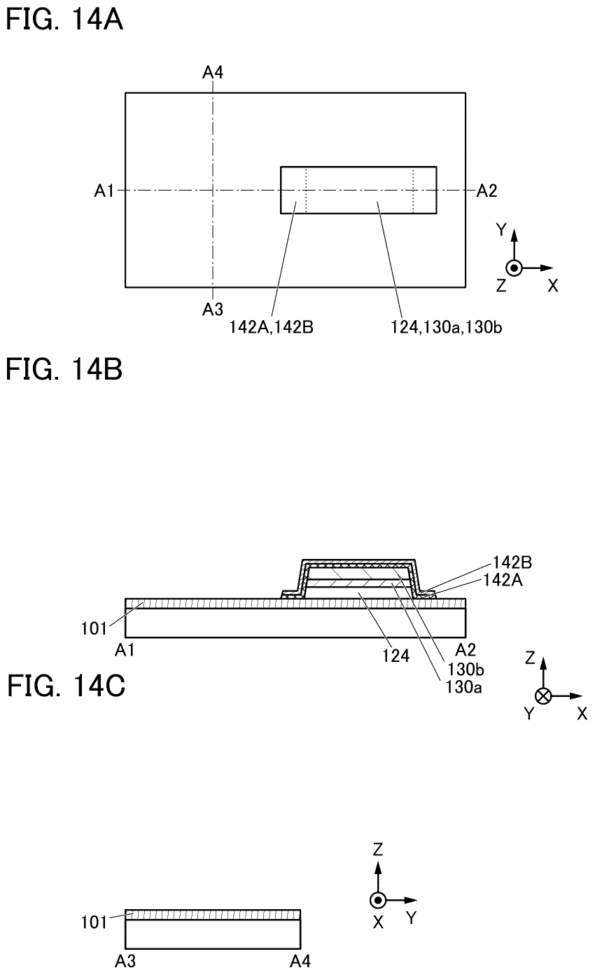

Next, the insulating layer 124A, the oxide layer 130A, the oxide layer 130B, the conductive film 142Af, and the conductive film 142Bf are processed by a lithography method to form the insulator 124, the oxide 130a, and the oxide 130b that have an island shape and a conductive layer 142A and a conductive layer 142B that have an island shape (see FIG. 14A to FIG. 14C). For example, the insulating layer 124A, the oxide layer 130A, the oxide layer 130B, the conductive film 142Af, and the conductive film 142Bf are processed to form the insulator 124, the oxide 130a, and the oxide 130b that have an island shape and the conductive layer 142A and the conductive layer 142B that extend in a direction parallel to the dashed-dotted line A1-A2 (the channel length direction of the transistor M2 or the X direction illustrated in FIG. 14A); and then, the conductive layer 142A and the conductive layer 142B are processed to form the conductive layer 142A and the conductive layer 142B that have an island shape.

Note that the insulating layer 124A, the oxide layer 130A, the oxide layer 130B, the conductive film 142Af, and the conductive film 142Bf may be processed under different conditions.

Furthermore, as illustrated in FIG. 14B, the side surfaces of the insulator 124, the oxide 130a, the oxide 130b, the conductive layer 142A, and the conductive layer 142B may have tapered shapes. Each of the insulator 124, the oxide 130a, the oxide 130b, the conductive layer 142A, and the conductive layer 142B may have a taper angle greater than or equal to 60° and less than 90°. With such tapered shapes of the side surfaces, the coverage with the insulator 175 and the like can be improved in a later step, so that defects such as a void can be reduced.

Not being limited to the above, the side surfaces of the insulator 124, the oxide 130a, the oxide 130b, the conductive layer 142A, and the conductive layer 142B may substantially perpendicular to the top surface of the insulator 101. With such a structure, a plurality of transistors M2 can be provided with high density in a small area.

A by-product generated in the above etching process is sometimes formed in a layered manner on the side surfaces of the insulator 124, the oxide 130a, the oxide 130b, the conductive layer 142A, and the conductive layer 142B. In that case, the layered by-product is formed between the insulator 175 and the insulator 124, the oxide 130a, the oxide 130b, the conductive layer 142A, and the conductive layer 142B. Hence, the layered by-product formed in contact with the top surface of the insulator 101 is preferably removed.

Note that the insulator 124, the oxide 130a, the oxide 130b, the conductive layer 142A, and the conductive layer 142B are not limited to have the shapes illustrated in FIG. 14A to FIG. 14C and may be processed into other shapes.

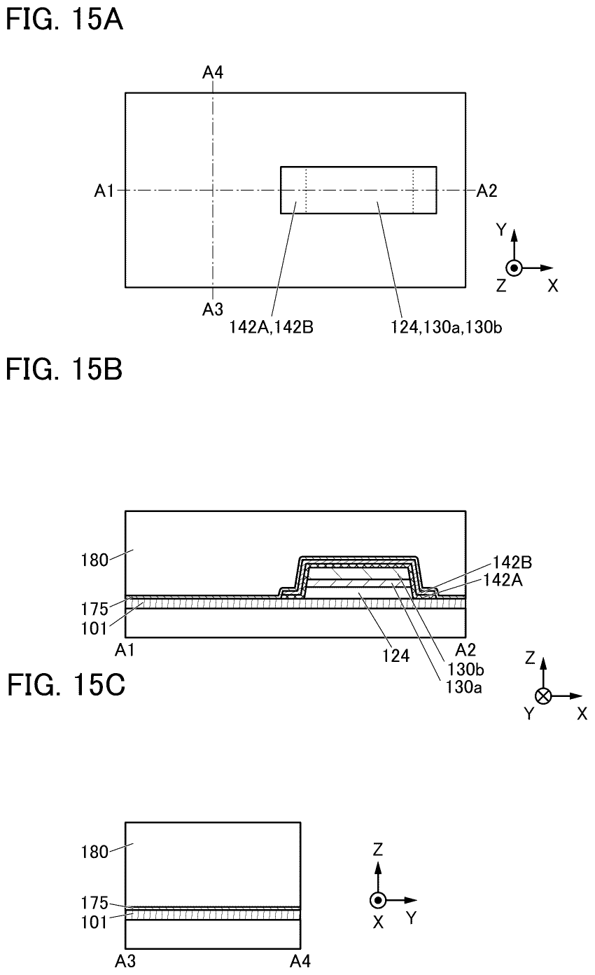

Next, the insulator 175 is deposited to cover the insulator 124, the oxide 130a, the oxide 130b, the conductive layer 142A, and the conductive layer 142B (see FIG. 15A to FIG. 15C). Here, it is preferable that the insulator 175 be in contact with the top surface of the insulator 101 and the side surface of the insulator 124. The insulator 175 can be deposited by a deposition method such as a sputtering method, a CVD method, an MBE method, a PLD method, or an ALD method. The insulator 175 is preferably formed using an insulating film having a function of inhibiting passage of oxygen. For example, silicon nitride may be deposited as the insulator 175 by an ALD method. Alternatively, as the insulator 175, aluminum oxide may be deposited by a sputtering method, and silicon nitride may be deposited thereover by a PEALD method. When the insulator 275 has such a stacked-layer structure, the function of inhibiting diffusion of impurities such as water or hydrogen and oxygen is improved in some cases.

In that manner, the oxide 130a, the oxide 130b, the conductive layer 142A, and the conductive layer 142B can be covered with the insulator 175, which has a function of inhibiting diffusion of oxygen. This can reduce direct diffusion of oxygen from the insulator 180 or the like formed later into the insulator 124, the oxide 130a, the oxide 130b, the conductive layer 142A, and the conductive layer 142B in a later step.

Next, an insulating film to be the insulator 180 is formed over the insulator 175 (see FIG. 15A to FIG. 15C). The insulating film can be formed by a deposition method such as a sputtering method, a CVD method, an MBE method, a PLD method, or an ALD method. A silicon oxide film may be formed by a sputtering method as the insulating film, for example. When the insulating film is formed by a sputtering method in an oxygen-containing atmosphere, the insulator 180 containing excess oxygen can be formed. By using a sputtering method that does not need to use a molecule containing hydrogen as a deposition gas, the hydrogen concentration in the insulator 180 can be reduced. Note that heat treatment may be performed before the formation of the insulating film. The heat treatment may be performed under reduced pressure, and the insulating film may be successively formed without exposure to the air. Such treatment can remove moisture and hydrogen adsorbed onto the surface of the insulator 175 and the like, and further can reduce the moisture concentration and the hydrogen concentration in the oxide 130a, the oxide 130b, and the insulator 124. For the heat treatment, the above heat treatment conditions can be used.

For the insulating film to be the insulator 180, a material with a low permittivity is preferably used. Specific examples of the material with a low permittivity include silicon oxynitride, silicon nitride oxide, and silicon nitride, in addition to silicon oxide. Other examples of the material with a low permittivity include silicon oxide to which fluorine is added, silicon oxide to which carbon is added, silicon oxide to which carbon and nitrogen are added, and porous silicon oxide.

Next, the insulating film to be the insulator 180 is subjected to planarization treatment such as a CMP method, so that the insulator 180 with a flat top surface is formed (see FIG. 15A to FIG. 15C). Note that, for example, silicon nitride may be deposited over the insulator 180 by a sputtering method and CMP treatment may be performed on the silicon nitride until the insulator 180 is reached.

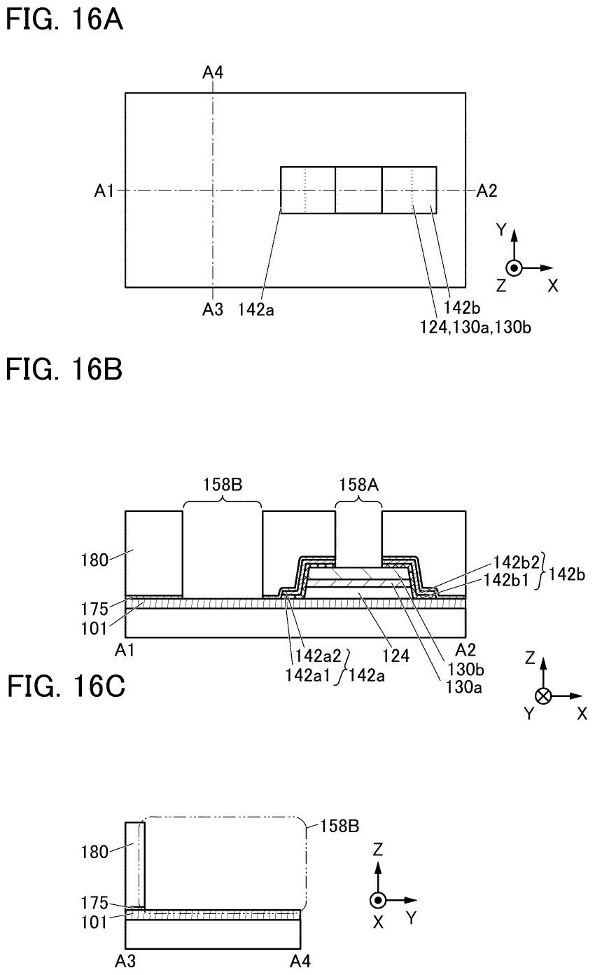

Next, in a region where the conductor 160_2 and the oxide 130 overlap with each other, part of the insulator 180, part of the insulator 175, part of the conductive layer 142A, and part of the conductive layer 142B are processed to form an opening 158A reaching the oxide 130b. By the formation of the opening 158A, the conductor 142al and the conductor 142b1 can be formed from the conductive layer 142A, and the conductor 142a2 and the conductor 142b2 can be formed from the conductive layer 142B (see FIG. 16A to FIG. 16C).

Each of the part of the insulator 180, the part of the insulator 175, the part of the conductive layer 142A, and the part of the conductive layer 142B can be processed by a dry etching method or a wet etching method. Processing by a dry etching method is suitable for microfabrication. The processing may be performed under different conditions. For example, the part of the insulator 180 may be processed by a dry etching method, the part of the insulator 175 may be processed by a wet etching method, and the part of the conductor 142A and the part of the conductive layer 142B may be processed by a dry etching method.

As illustrated in FIG. 16B, the opening 158A is preferably formed to extend in a direction parallel to the dashed-dotted line A3-A4 (the channel width direction of the transistor M2 or the Y direction illustrated in FIG. 16A). By forming the opening 158A in that manner, the conductor 160_2 to be formed later can be provided to extend in the above-described direction, so that the conductor 160_2 can function as a wiring.

The width of the opening 158A is preferably small because the channel length of the transistor M2 reflects the width. For example, the width of the opening 158A is preferably less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm. In order to process the opening 158A minutely, a lithography method using an electron beam or short-wavelength light such as EUV light is preferably used.

In the case where the opening 158A is processed minutely, the part of the insulator 180, the part of the insulator 175, the part of the conductive layer 142B, and the part of the conductive layer 142A are preferably processed by anisotropic etching. Processing by a dry etching method is particularly preferable because it is suitable for microfabrication. The processing may be performed under different conditions.

When the insulator 180, the insulator 175, the conductive layer 142B, and the conductive layer 142A are processed by anisotropic etching, side surfaces of the conductor 142a and the conductor 142b that face each other can be formed to be substantially perpendicular to the top surface of the oxide 130b. Such a structure can inhibit formation of what is called an Loff region in a region of the oxide 130 in the vicinity of an end portion of the conductor 142a and a region of the oxide 130 in the vicinity of an end portion of the conductor 142b. Accordingly, the frequency characteristics of the transistor M2 can be improved, and the operation speed of the semiconductor device of one embodiment of the present invention can be improved.

However, without limitation to the above, the side surfaces of the insulator 180, the insulator 175, and the conductor 142a, and the conductor 142b have tapered shapes in some cases. The taper angle of the insulator 180 is larger than that of the conductor 142a or the conductor 142b in some cases. An upper portion of the oxide 130b is sometimes removed when the opening 158A is formed.

By the etching process, impurities may be attached onto the side surface of the oxide 130a, the top surface and the side surface of the oxide 130b, the side surface of the conductor 142a, the side surface of the conductor 142b, the side surface of the insulator 180, and the like; alternatively, the impurities may be diffused thereinto. A step of removing such impurities may be performed. In addition, a damaged region might be formed on the surface of the oxide 130b by the above dry etching. Such a damaged region may be removed. The impurities result from components contained in the insulator 180, the insulator 175, the conductive layer 142B, and the conductive layer 142A; components contained in a member of an apparatus used to form the opening; and components contained in a gas or a liquid used for etching, for instance. Examples of the impurities include hafnium, aluminum, silicon, tantalum, fluorine, and chlorine.

In particular, impurities such as aluminum or silicon might reduce the crystallinity of the oxide 130b. Thus, it is preferable that impurities such as aluminum or silicon be removed from the surface of the oxide 130b and the vicinity thereof. The concentration of the impurities is preferably reduced. For example, the concentration of aluminum atoms at the surface of the oxide 130b and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, and yet further preferably lower than 0.3 atomic %.

Note that the density of the crystal structure is reduced in the low-crystallinity region of the oxide 130b owing to impurities such as aluminum or silicon; thus, a large amount of VoH (Vo refers to oxygen vacancies and VoH refers to defects generated by entry of hydrogen into Vo) is formed, and the transistor tends to be normally on (in a state where a channel is present when a voltage of 0 V is applied between the gate electrode and the source electrode and current flows through the transistor). Hence, the low-crystallinity region of the oxide 130b is preferably reduced or removed.

Accordingly, the oxide 130b preferably has a layered CAAC (C-Axis Aligned Crystalline) structure. In particular, the CAAC structure preferably reaches a lower end portion of a drain in the oxide 130b. Here, in the transistor M2, the conductor 142a or the conductor 142b, and its vicinity function as a drain. In other words, the oxide 130b in the vicinity of the lower end portion of the conductor 142a (conductor 142b) preferably has a CAAC structure. In that manner, the low-crystallinity region of the oxide 130b is removed and the CAAC structure is formed also in the end portion of the drain, which significantly affects the drain withstand voltage, so that a variation in electrical characteristics of the transistors M2 can be further suppressed. In addition, the reliability of the transistor M2 can be improved.

In order to remove impurities and the like attached to the surface of the oxide 130b in the above etching process, cleaning treatment is performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the opening deeper.

In the wet cleaning, an aqueous solution in which one or more selected from ammonia water, oxalic acid, phosphoric acid, and hydrofluoric acid are diluted with carbonated water or pure water can be used. Alternatively, the wet cleaning may be performed using pure water or carbonated water. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution may be adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm. For the ultrasonic cleaning, a frequency higher than or equal to 200 kHz is preferable, and a frequency higher than or equal to 900 kHz is further preferable. Damage to the oxide 130b and the like can be reduced with this frequency.

The cleaning treatment may be performed a plurality of times, and the cleaning solution may be changed in every cleaning treatment. For example, the first cleaning treatment may use diluted hydrofluoric acid or diluted ammonia water, and the second cleaning treatment may use pure water or carbonated water.

As the cleaning treatment in this embodiment, wet cleaning using diluted ammonia water is performed. The cleaning treatment can remove impurities that are attached onto the surfaces of the oxide 130a, the oxide 130b, and the like or diffused into the oxide 130a, the oxide 130b, and the like. Furthermore, the crystallinity of the oxide 130b can be increased.

After the etching or the cleaning treatment, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 130a and the oxide 130b to reduce oxygen vacancies. In addition, the crystallinity of the oxide 130b can be improved by such heat treatment. The heat treatment may be performed under reduced pressure. Alternatively, the heat treatment may be performed in an oxygen atmosphere, and then another heat treatment may be successively performed in a nitrogen atmosphere without exposure to the air.

Next, part of the insulator 180 and part of the insulator 175 in a region where the insulator 124, the oxide 130, the conductor 142a, and the conductor 142b do not overlap with each other are processed to form an opening 158B reaching the insulator 101 (see FIG. 16A to FIG. 16C).

The opening 158B can be formed by a dry etching method or a wet etching method as in the formation of the opening 158A. For example, the part of the insulator 180 may be processed by a dry etching method, and the part of the insulator 175 may be processed by a wet etching method.

The opening 158B is preferably formed to extend in a direction parallel to the dashed-dotted line A3-A4 in FIG. 16A (the channel width direction of the transistor M2 or the Y direction illustrated in FIG. 16A). By forming the opening 158B in that manner, the conductor 160_1 to be formed later can be provided to extend in the above-described direction, so that the conductor 160_1 can function as a wiring.

Note that the opening 158A and the opening 158B may be formed at a time or separately. For example, one of the opening 158A and the opening 158B may be formed first and the other may be formed later. Note that the opening 158A is preferably formed so that the oxide 130b is exposed at the bottom portion of the opening 158A, and the opening 158B is preferably formed so that the insulator 101 is exposed at the bottom portion of the opening 158B. Therefore, the opening 158A and the opening 158B are preferably formed by processing methods under different conditions.

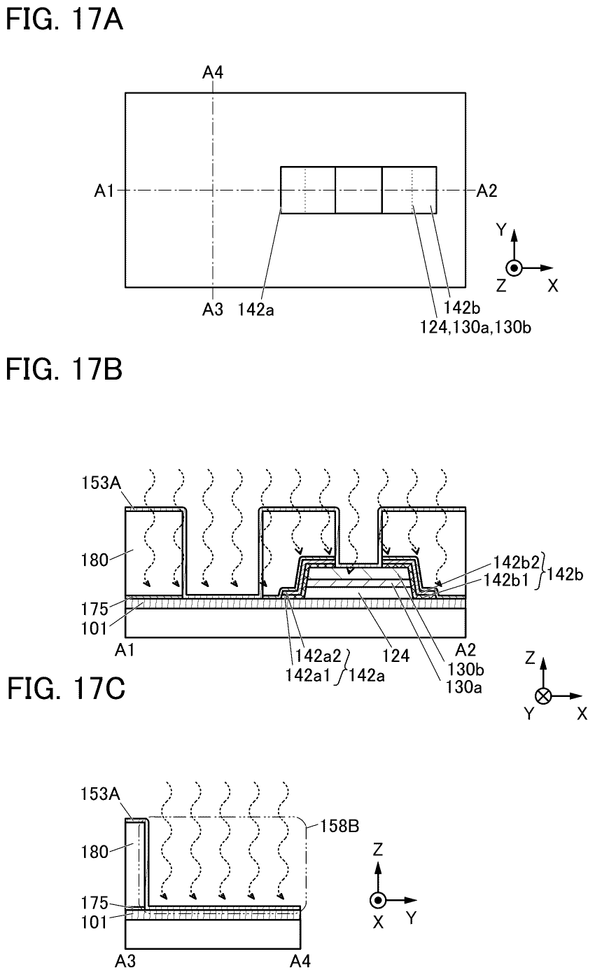

Next, an insulating film 153A is formed (see FIG. 17A to FIG. 17C). The insulating film 153A is an insulating film to be the insulator 153_1 and the insulator 153_2 in a later process. The insulating film 153A can be formed by a deposition method such as a sputtering method, a CVD method, an MBE method, a PLD method, or an ALD method. The insulating film 153A is preferably formed by an ALD method. As described above, it is preferable to form the insulating film 153A to have a small thickness, and an unevenness of the thickness needs to be reduced. Since an ALD method is a deposition method in which a precursor and a reactant (e.g., oxidizer) are alternately introduced and the film thickness can be adjusted with the number of repetition times of the cycle, accurate control of the film thickness is possible. Furthermore, as illustrated in FIG. 17B and FIG. 17C, the insulating film 153A needs to be formed on the bottom portion and the side surfaces of each of the opening 158A and the opening 158B with good coverage. In the opening 158A, it is preferable that the insulating film 153A be formed on the top surface and the side surface of the oxide 130 with good coverage. In addition, in the opening 158B, it is preferable that the insulating film 153A be formed on the top surface of the insulator 101 and the side surface of the insulator 180 with good coverage. By an ALD method, atomic layers can be formed one by one on the bottom surface and the side surface of each of the opening 158A and the opening 158B, whereby the insulating film 153A can be formed in each of the openings with good coverage.

When the insulating film 153A is formed by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the oxide 130b can be reduced.

In this embodiment, hafnium oxide is deposited as the insulating film 153A by a thermal ALD method.

Alternatively, a high-k material with a high dielectric constant may be used as an insulating material used for the insulating film 153A. Examples of the high-k material with a high dielectric constant include a metal oxide containing one kind or two or more kinds selected from aluminum, gallium, yttrium, zirconium, tungsten, titanium, tantalum, nickel, germanium, and magnesium in addition to the above-described hafnium oxide. Alternatively, any of aluminum oxide, hafnium oxide, and an oxide containing aluminum and hafnium (hafnium aluminate), which are insulators each contain an oxide of one or both of aluminum and hafnium, may be used for the insulating film 153A.

An insulating material such as silicon oxide, silicon oxynitride, or silicon nitride oxide can be used for the insulating film 153A. Alternatively, an insulating material such as silicon oxide to which fluorine is added or silicon oxide to which carbon is added can be used for the insulating film 153A. Alternatively, silicon oxide to which carbon and nitrogen are added can be used for the insulating film 153A. Alternatively, porous silicon oxide can be used for the insulating film 153A. In particular, silicon oxide and silicon oxynitride, which are thermally stable, are preferable. Alternatively, the insulating film 153A may have a stacked-layer structure including two or more selected from the above-described materials.

Next, it is preferable to perform microwave treatment in an oxygen-containing atmosphere (see FIG. 17A to FIG. 17C). Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz. Note that in the case where the insulating film 153A has a stacked-layer structure, the microwave treatment may be performed at the time when the insulating film 153A is partially formed. For example, in the case where the insulating film 153A includes a silicon oxide film or a silicon oxynitride film, the microwave treatment may be performed at the time when the silicon oxide film or the silicon oxynitride film is formed.

Here, dotted-line arrows in FIG. 17B and FIG. 17C indicate high-frequency waves such as microwaves or RF, oxygen plasma, oxygen radicals, or the like. The microwave treatment is preferably performed with a microwave treatment apparatus including a power source for generating high-density plasma using microwaves, for example. Here, the frequency of the microwave treatment apparatus is set to greater than or equal to 300 MHz and less than or equal to 300 GHz, preferably greater than or equal to 2.4 GHz and less than or equal to 2.5 GHz, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 130b efficiently. By the effect of the plasma, the microwave, or the like, VoH included in the region of the oxide 130 that does not overlap with the conductor 142a or the conductor 142b can be divided and hydrogen can be removed from the region. That is, VoH contained in the region can be reduced. As a result, oxygen vacancies and VoH in the region can be reduced to lower the carrier concentration. In addition, oxygen radicals generated by the oxygen plasma can be supplied to oxygen vacancies formed in the region, thereby further reducing oxygen vacancies in the region and lowering the carrier concentration.

As illustrated in FIG. 17B and FIG. 17C, the conductor 142a and the conductor 142b block the effect of high-frequency waves such as microwaves or RF, oxygen plasma, or the like, and thus such an effect does not take on the region of the oxide 130b overlapping with the conductor 142a or the region of the oxide 130b overlapping with the conductor 142b. Hence, a reduction in VoH and supply of an excess amount of oxygen do not occur in the region in the microwave treatment, preventing a decrease in carrier concentration.

The insulating film 153A having a barrier property against oxygen is provided in contact with the side surfaces of the conductor 142a and the conductor 142b. Thus, formation of oxide films on the side surfaces of the conductor 142a and conductor 142b due to the microwave treatment can be inhibited.

As a result, the film quality of the insulator 153_2 can be improved, leading to higher reliability of the transistor M2.

In the above manner, oxygen vacancies and VoH can be selectively removed from the region of the oxide 130 not overlapping with the conductor 142a or the conductor 142b, whereby the region can be an i-type or substantially i-type region. Furthermore, supply of excess oxygen to the region of the oxide 130 overlapping with the conductor 142a and the region of the oxide 130 overlapping with the conductor 142b, which function as the source region and the drain region, can be inhibited and the conductivity can be maintained. Therefore, a change in the electrical characteristics of the transistor M2 can be inhibited, and thus a variation in the electrical characteristics of the transistors M2 in the substrate plane can be inhibited.

In the microwave treatment, thermal energy is directly transmitted to the oxide 130b in some cases owing to an electromagnetic interaction between the microwaves and molecules in the oxide 130b. The oxide 130b may be heated by this thermal energy. Such heat treatment is sometimes referred to as microwave annealing. When microwave treatment is performed in an atmosphere containing oxygen, an effect equivalent to that of oxygen annealing is sometimes obtained. In the case where hydrogen is contained in the oxide 130b, the thermal energy may be transmitted to the hydrogen in the oxide 130b and the hydrogen activated by the energy may be released from the oxide 130b.

Note that microwave treatment may be performed before the formation of the insulating film 153A without the microwave treatment performed after the formation of the insulating film 153A.

After the microwave treatment after the formation of the insulating film 153A, heat treatment may be performed with a reduced pressure being maintained. Such treatment enables hydrogen in the insulating film 153A, the oxide 130b, and the oxide 130a to be removed efficiently. Part of hydrogen is gettered by the conductor 142a and the conductor 142b in some cases. Alternatively, the step of performing microwave treatment and then performing heat treatment with the reduced pressure being maintained may be repeated a plurality of cycles. The repetition of the heat treatment enables hydrogen in the insulating film 153A, the oxide 130b, and the oxide 130a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 130b and the like are adequately heated by the microwave annealing.

Furthermore, the microwave treatment improves the film quality of the insulating film 153A, thereby inhibiting diffusion of impurities such an hydrogen and water. Accordingly, impurities such as hydrogen and water can be inhibited from diffusing into the oxide 130b, the oxide 130a, and the like through the insulator 153_2 in a later process such as formation of a conductive film to be the conductor 160_1 and the conductor 160_2 or later treatment such as heat treatment.

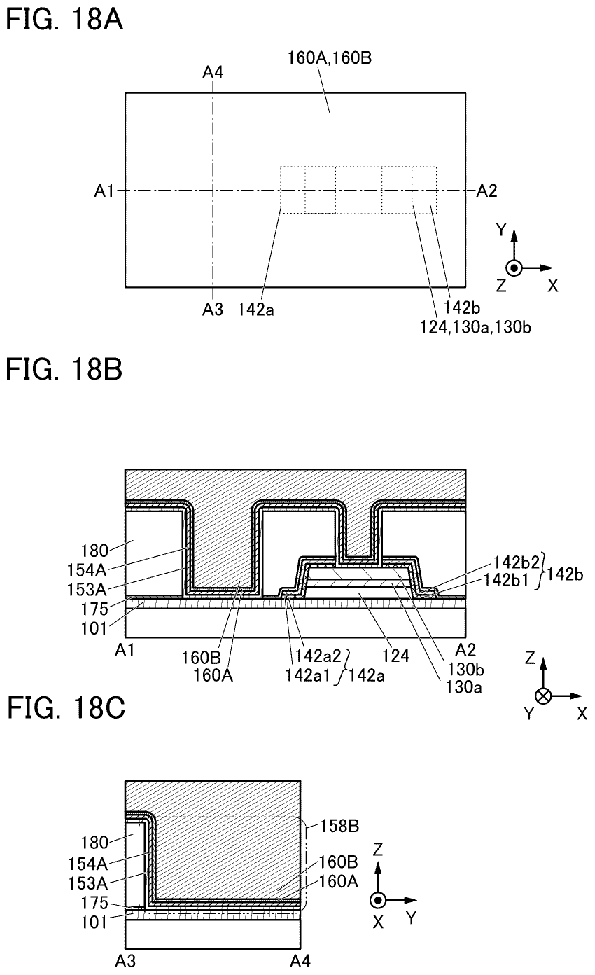

Next, an insulating film 154A to be the insulator 154_1 and the insulator 154_2 is formed (see FIG. 18A to FIG. 18C). The insulating film 154A can be formed by a deposition method such as a sputtering method, a CVD method, an MBE method, a PLD method, or an ALD method. Like the insulating film 153A, the insulating film 154A is preferably formed by an ALD method. By an ALD method, the insulating film 154A can be formed to have a small thickness and good coverage. In this embodiment, as the insulating film 154A, silicon nitride is deposited by a PEALD method.

Note that an insulating material that is usable for the insulating film 153A may be used for the insulating film 154A.

The same material as the insulating film 153A may be used for the insulating film 154A. That is, in the memory cell MC, the insulator 153_2 and the insulator 154_2 may be one insulator. Similarly, the insulator 153_1 and the insulator 154_1 may be one insulator.

Next, a conductive film 160A to be the conductor 160a_1 and the conductor 160a_2 and a conductive film 160B to be the conductor 160b_2 and the conductor 160b_2 are formed sequentially (see FIG. 18A to FIG. 18C). The conductive film 160A and the conductive film 160B can be formed by a deposition method such as a sputtering method, a CVD method, an MBE method, a PLD method, or an ALD method. In this embodiment, titanium nitride is deposited as the conductive film 160A by an ALD method, and tungsten is deposited as the conductive film 160B by a CVD method.

Note that for the conductive film 160A, a conductive material such as tantalum, tantalum nitride, titanium, ruthenium, or ruthenium oxide may be used other than titanium nitride. Alternatively, a stacked-layer structure including two or more selected from the above-described materials may be used for the conductive film 160A. For the conductive film 160B, a conductive material such as copper or aluminum may be used other than tungsten. Alternatively, a stacked-layer structure including two or more selected from the above-described materials may be used for the conductive film 160B.

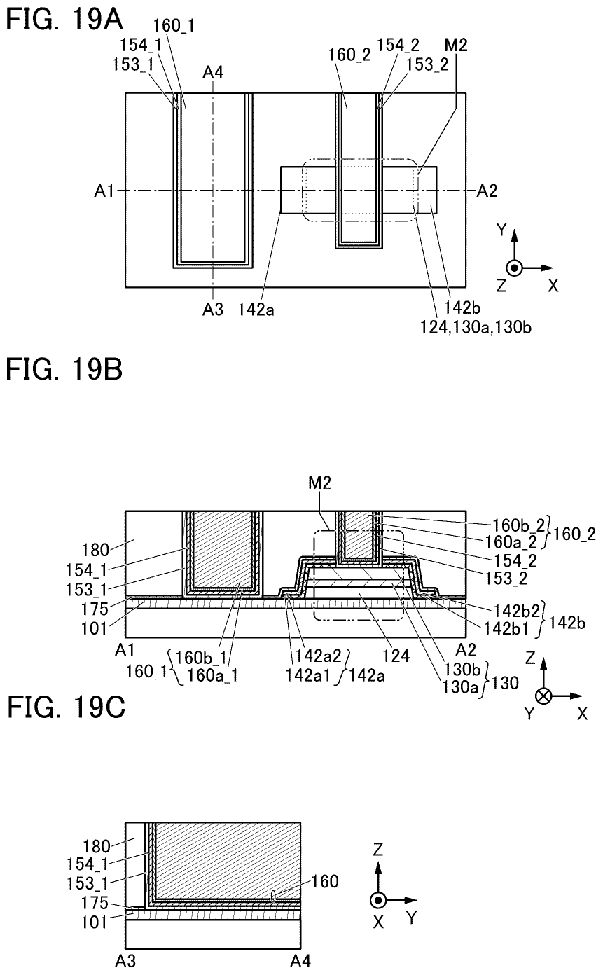

Next, the insulating film 153A, the insulating film 154A, the conductive film 160A, and the conductive film 160B are polished by planarization treatment such as a CMP method until the insulator 180 is exposed. That is, portions of the insulating film 153A, the insulating film 154A, the conductive film 160A, and the conductive film 160B, which are above the insulator 180, the opening 158A, and the opening 158B, are removed. Thus, the insulator 153_2, the insulator 154_2, and the conductor 160_2 (the conductor 160a_2 and the conductor 160b_2) are formed in the opening 158A, and the insulator 153_1, the insulator 154_1, and the conductor 160_1 (the conductor 160a_1 and the conductor 160b_1) are formed in the opening 158B (see FIG. 19A to FIG. 19C).

Accordingly, the insulator 153_2 is provided in contact with the bottom portion and the side surface of the opening 158A overlapping with the oxide 130b. The conductor 160_2 is placed to fill the opening 158A with the insulator 153_2 and the insulator 154_2 therebetween. In that manner, the transistor M2 is formed.

The insulator 153_1 is provided in contact with the bottom portion and the side surface of the opening 158B overlapping with the oxide 230 of the transistor M1. The conductor 160_1 is provided to fill the opening 158B with the insulator 153_1 and the insulator 154_1 therebetween.

Then, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 180. After the heat treatment, the insulator 201 may be successively formed without exposure to the air.

Next, the insulator 201 is deposited over the insulator 180, the insulator 153_1, the insulator 154_1, the conductor 160_1, the insulator 153_2, the insulator 154_2, and the conductor 160_2. For the formation method of the insulator 201, the formation method of the insulator 101 is referred to, for example. Thus, a material that is usable for the insulator 101 can be used for the insulator 201.

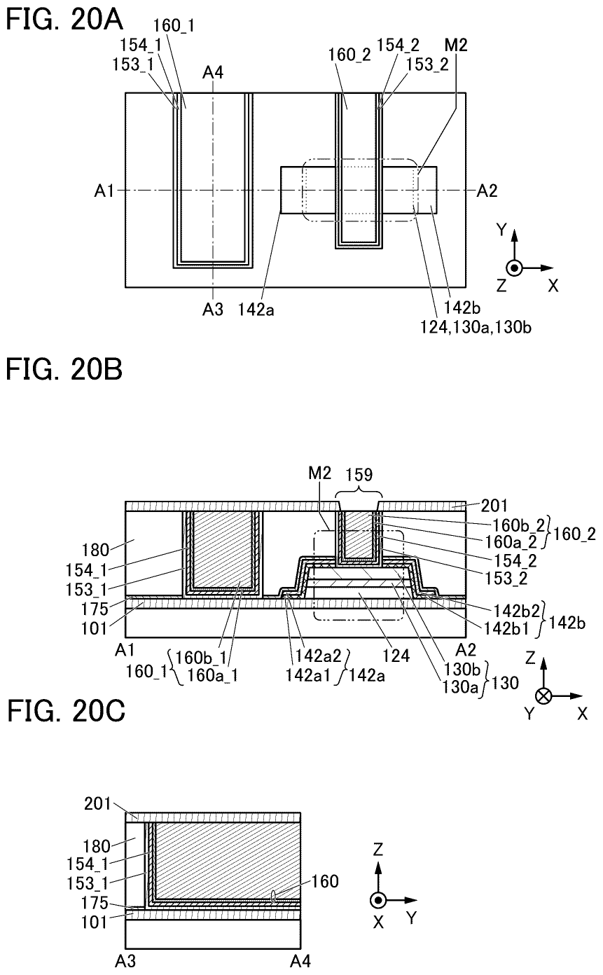

Next, part of the insulator 201 in a region overlapping with part of the conductor 160_2 is processed to form an opening 159 (see FIG. 20A to FIG. 20C). Note that a dry etching method or a wet etching method can be used for the processing of the part of the insulator 201. Processing by a dry etching method is suitable for microfabrication. Alternatively, a processing method by which the opening 158A and the opening 158B are formed may be employed as the formation method of the opening 159.

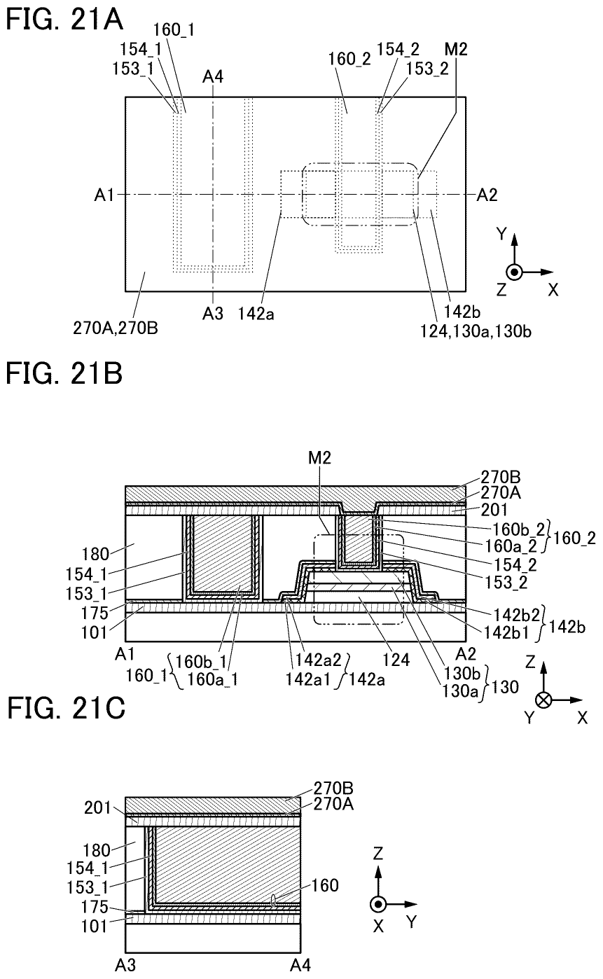

Next, a conductive film 270A to be the conductor 270a and a conductive film 270B to be the conductor 270b are formed sequentially (see FIG. 21A to FIG. 21C). The conductive film 270A and the conductive film 270B can be formed by a deposition method such as a sputtering method, a CVD method, an MBE method, a PLD method, or an ALD method. In particular, the conductive film 270A is preferably formed on the bottom surface and the side surface of the opening 159 with good coverage. Thus, the conductive film 270A is preferably formed by an ALD method, for example. The conductive film 270B is preferably formed by a CVD method, for example.

Note that a material that is usable for the conductive film 160A can be used for the conductive film 270A. A material that is usable for the conductive film 160B can be used for the conductive film 270B.

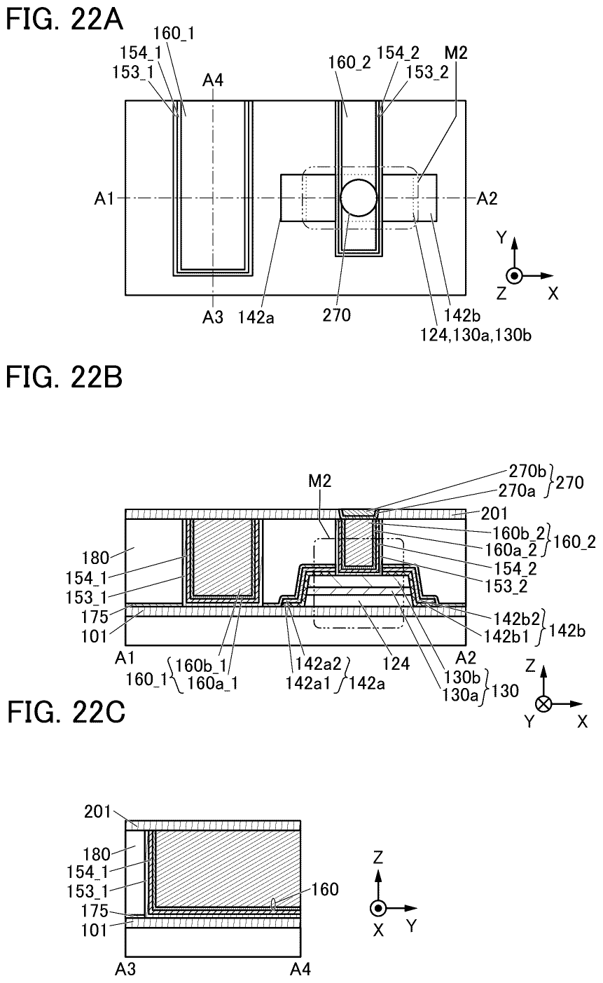

Next, the conductive film 270A and the conductive film 270B are polished by planarization treatment such as a CMP method until the insulator 201 is exposed. That is, portions of the conductive film 270A and the conductive film 270B, which are above the insulator 201 and the opening 159, are removed. Thus, the conductor 270 (the conductor 270a and the conductor 270b) is formed in the opening 159 (see FIG. 22A to FIG. 22C).

Next, as in the manufacturing method illustrated in FIG. 11A to FIG. 22C, the transistor M1 is formed over the insulator 201 (see FIG. 23A to FIG. 23C).

Specifically, a stack of the insulator 224, the oxide 230a, and the oxide 230b is formed in a region overlapping with part of the conductor 160_1 over the insulator 201; and the conductor 242a (the conductor 242al and the conductor 242a2) and the conductor 242b (the conductor 242b1 and the conductor 242b2) are formed so as to be located over the insulator 201 and the oxide 230b and to cover the side surfaces of each of the insulator 224, the oxide 230a, and the oxide 230b. In particular, the conductor 242b is also formed over the conductor 270 provided in the opening 159.

The insulator 275 and the insulator 280 are formed sequentially over the insulator 201, the conductor 242a, and the conductor 242b.

A region where the conductor 260 and the oxide 230 overlap with each other includes an opening reaching the oxide 230b, which is formed by processing part of the insulator 280, part of the insulator 275, part of the film to be the conductive layer 242a, and part of the film to be the conductive layer 242b. The insulator 253, the insulator 254, and the conductor 260 are formed sequentially in the opening.

Note that for the insulator 224, the above description of the insulator 124 is referred to. For the oxide 230, the above description of the oxide 130 is referred to. For the conductor 242a and the conductor 242b, the above description of the conductor 142a and the conductor 142b is referred to. For the insulator 275, the above description of the insulator 175 is referred to. For the insulator 280, the above description of the insulator 180 is referred to. For the insulator 253, the above description of the insulator 153_1 and the insulator 153_2 is referred to. For the insulator 254, the above description of the insulator 154_1 and the insulator 154_2 is referred to. For the conductor 260, the above description of the conductor 160_1 and the conductor 160_2 is referred to.

Next, the insulator 301 is deposited over the insulator 280, the insulator 253, the insulator 254, and the conductor 260 (see FIG. 9A to FIG. 9C). The insulator 301 can be deposited by a deposition method such as a sputtering method, a CVD method, an MBE method, a PLD method, or an ALD method. For example, hafnium oxide with a reduced hydrogen concentration is preferably deposited as the insulator 301 by an ALD method, like in the cases of the insulator 101 and the insulator 201.

Note that for another material and another formation method of the insulator 301, the description of the insulator 101 is referred to.

In the above manner, the semiconductor device illustrated in FIG. 3, which is provided with the memory layer ALYa including the memory cell MCa, the memory layer ALYb including the memory cell MCb, and the memory layer ALYc including the memory cell MCc, can be manufactured. As illustrated in FIG. 9A to FIG. 23C, with the use of the method for manufacturing the semiconductor device described in this embodiment, the back gate electrode of the transistor M1 and the gate electrode of the transistor M2 can be formed in the same process. This can reduce the number of manufacturing steps of the semiconductor device DEV including the transistor M1 and the transistor M2.

In the semiconductor device illustrated in FIG. 3, which includes the memory cell MCa, the memory cell MCb, or the memory cell MCc, the area occupied by the memory cell can be small. In other words, the recording density of the semiconductor device can be increased.

Note that the method for manufacturing a semiconductor device of one embodiment of the present invention is not limited to that illustrated in FIG. 9A to FIG. 23C. The materials and steps in the method for manufacturing a semiconductor device may be changed depending on circumstances.

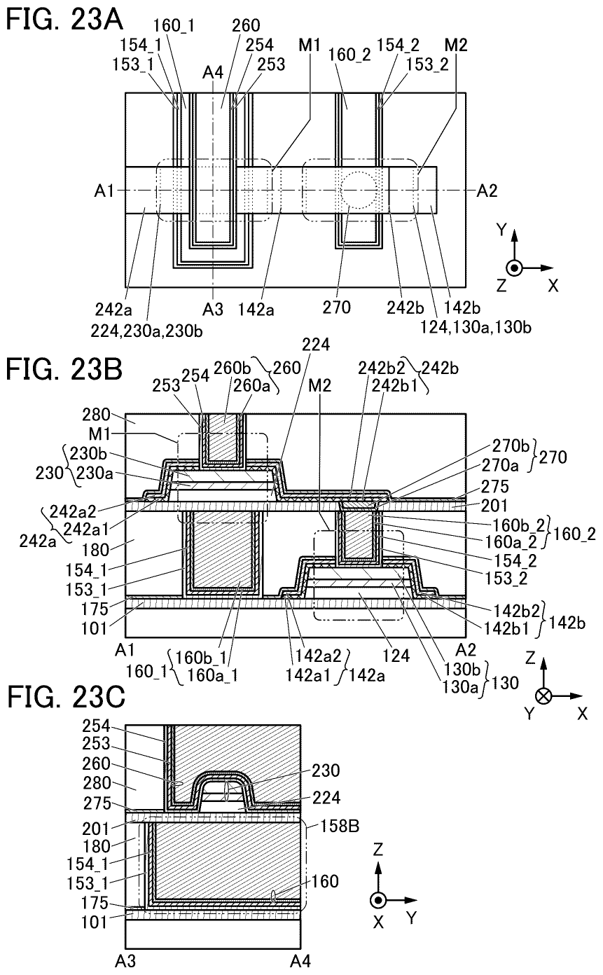

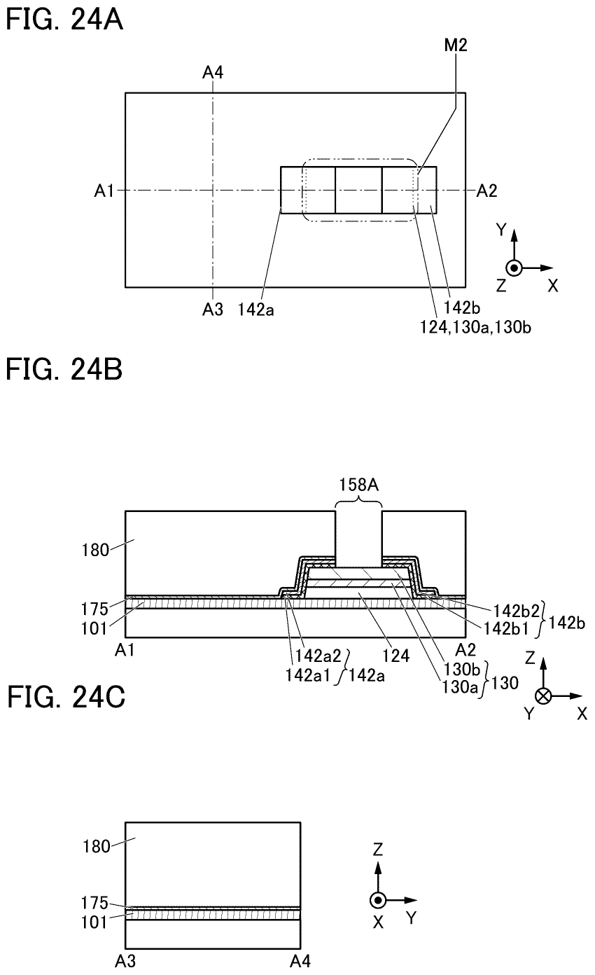

For example, after the insulator 180 is formed in FIG. 15A to FIG. 15C, the semiconductor device may be manufactured by the manufacturing process illustrated in FIG. 24A to FIG. 28C.

After the insulator 180 is formed in FIG. 15A to FIG. 15C, part of the insulator 180, part of the insulator 175, part of the conductive layer 142A, and part of the conductive layer 142B in a region overlapping with the oxide 130 are processed, whereby the opening 158A reaching the oxide 130b is formed. By the formation of the opening 158A, the conductor 142al and the conductor 142b1 can be formed from the conductive layer 142A, and the conductor 142a2 and the conductor 142b2 can be formed from the conductive layer 142B (see FIG. 24A to FIG. 24C). For the specific process, the description of FIG. 16A to FIG. 16C is referred to.

After the formation of the opening 158A, microwave treatment is preferably performed in an oxygen-containing atmosphere, as in FIG. 17A to FIG. 17C.

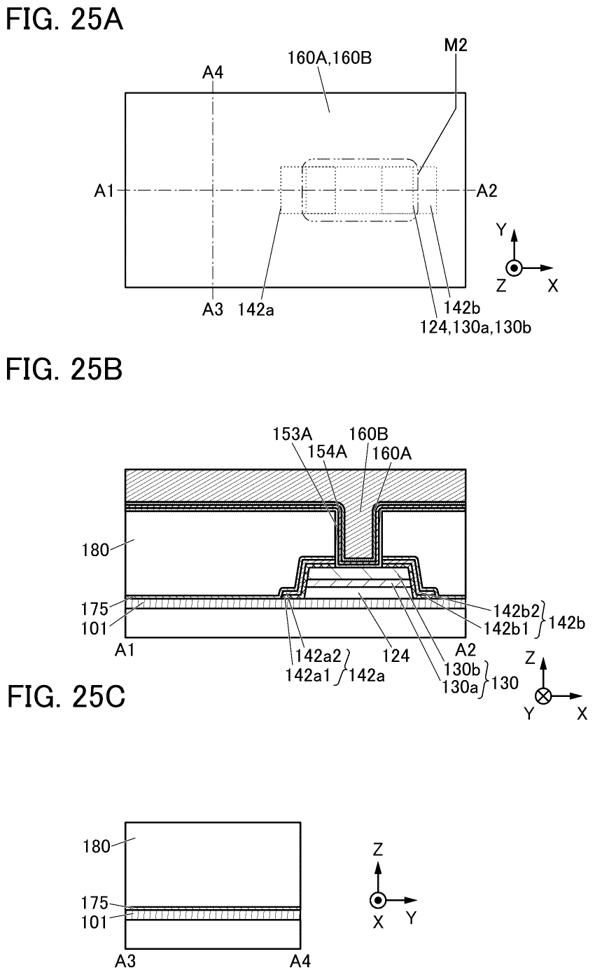

Next, the insulating film 153A, the insulating film 154A, the conductive film 160A, and the conductive film 160B are formed sequentially over the insulator 180 and the oxide 130 (see FIG. 25A to FIG. 25C). For the specific process, the description of FIG. 18A to FIG. 18C is referred to.

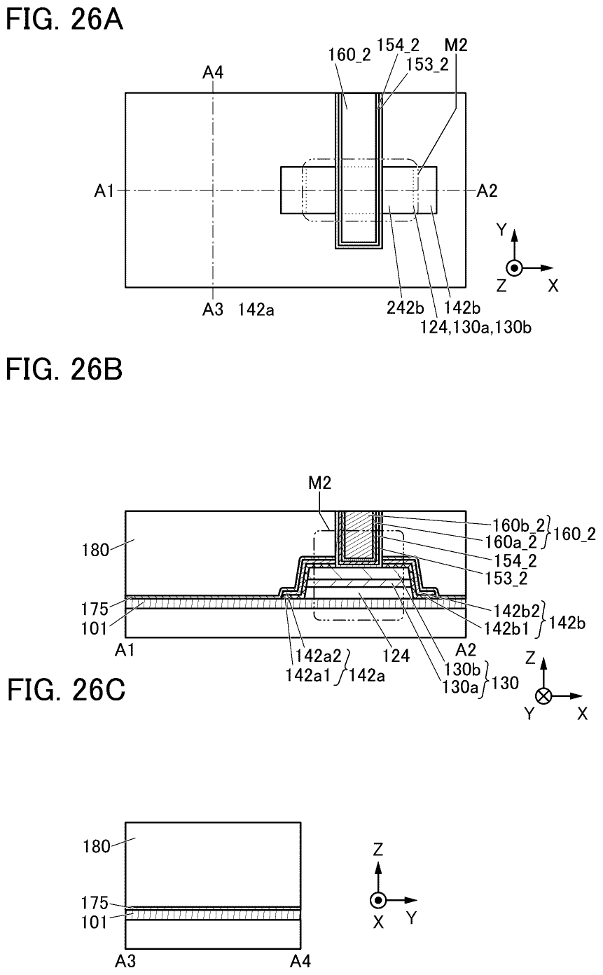

After that, the insulating film 153A, the insulating film 154A, the conductive film 160A, and the conductive film 160B are polished by planarization treatment such as a CMP method until the insulator 180 is exposed. Thus, the insulator 153_2, the insulator 154_2, and the conductor 160_2 (the conductor 160a_2 and the conductor 160b_2) are formed in the opening 158A (see FIG. 26A to FIG. 26C). For the specific process, the description of FIG. 19A to FIG. 19C is referred to. Thus, the gate of the transistor M2 is formed.

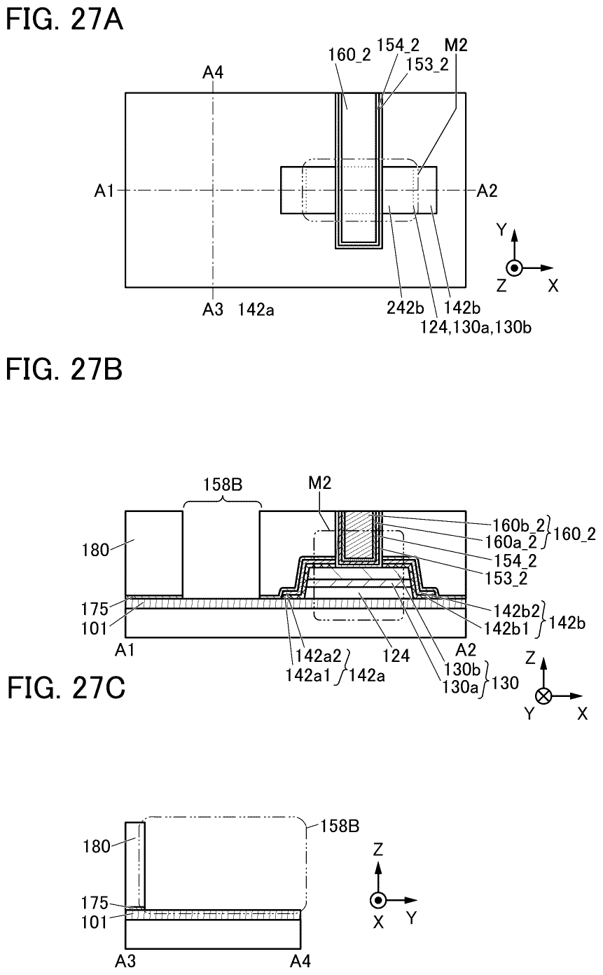

In FIG. 26A to FIG. 26C, after the insulator 153_2, the insulator 154_2, and the conductor 160_2 (the conductor 160a_2 and the conductor 160b_2) are formed, part of the insulator 180 and part of the insulator 175 in a region where the conductor 142a or the conductor 142b and the oxide 130 do not overlap with each other are processed to form the opening 158B reaching the insulator 101 (see FIG. 27A to FIG. 27C). For the specific process, the description of FIG. 16A to FIG. 16C can be referred to.

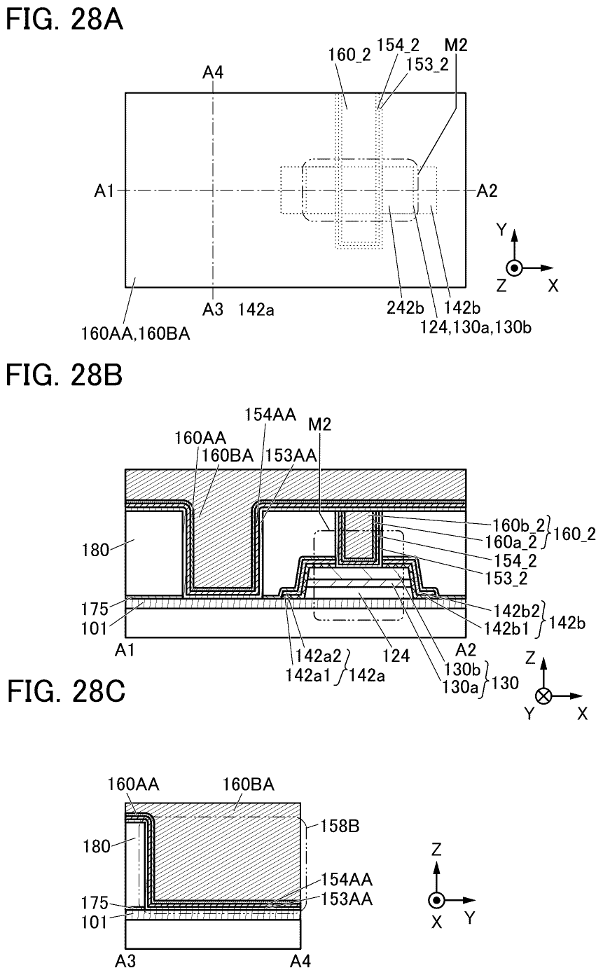

Next, an insulating film 153AA, an insulating film 154AA, a conductive film 160AA, and a conductive film 160BA are formed sequentially over the insulator 180, the insulator 153_2, the insulator 154_2, and the conductor 160_2 (see FIG. 28A to FIG. 28C). For example, a material that is usable for the insulating film 153A can be used for the insulating film 153AA. A material that is usable for the insulating film 154A can be used for the insulating film 154AA, for example. A material that is usable for the conductive film 160A can be used for the conductive film 160AA, for example. A material that is usable for the conductive film 160B can be used for the conductive film 160BA, for example. For the specific process, the description of FIG. 18A to FIG. 18C is referred to.

After that, the insulating film 153AA, the insulating film 154AA, the conductive film 160AA, and the conductive film 160BA are polished by planarization treatment such as a CMP method until the insulator 180 is exposed. Thus, the insulator 153_1, the insulator 154_1, and the conductor 160_1 (the conductor 160a_1 and the conductor 160b_1) are formed in the opening 158B. By being subjected to the planarization treatment, the semiconductor device illustrated in FIG. 28A to FIG. 28C has substantially the same structure as that illustrated in FIG. 19A to FIG. 19C. Note that for the specific process of the planarization treatment, the description of FIG. 19A to FIG. 19C can be referred to.

As described above, after the insulator 180 is formed in FIG. 15A to FIG. 15C, the manufacturing process illustrated in FIG. 24A to FIG. 28C are performed and then the manufacturing process illustrated in FIG. 20A to FIG. 23C are performed, whereby the semiconductor device of one embodiment of the present invention can be manufactured. The following formation order (not illustrated) may be employed in the method for manufacturing the semiconductor device of one embodiment of the present invention: the opening 158B is formed in advance; the insulator 153_1, the insulator 154_1, and the conductor 160_1 (the conductor 160a_1 and the conductor 160b_1) are formed in the opening 158B; after that, the opening 158A is formed; and then the insulator 153_2, the insulator 154_2, and the conductor 160_2 (the conductor 160a_2 and the conductor 160b_2) are formed in the opening 158A.

### Modification Example 1 of Semiconductor Device

A structure example of the semiconductor device DEV of one embodiment of the present invention, which is different from the circuit structure illustrated in FIG. 1, is described below.

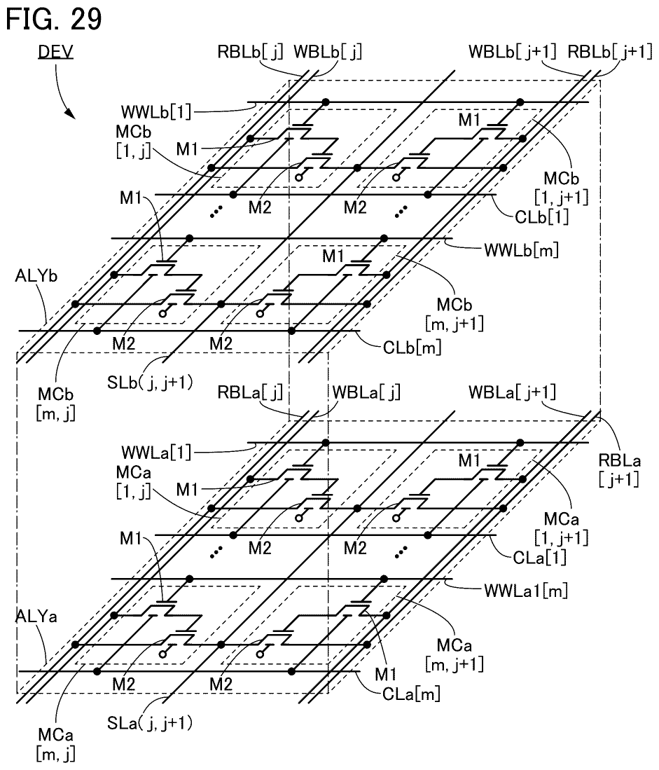

FIG. 29 is a modification example of the semiconductor device DEV illustrated in FIG. 1. Specifically, the semiconductor device DEV illustrated in FIG. 29 is different from the semiconductor device DEV illustrated in FIG. 1 in that, for example, the memory cell MCa[1,j] to the memory cell MCa[m,j] of the j-th column (here, j is an integer greater than or equal to 1 and less than or equal to n-1) and the memory cell MCa[1,j+1] to the memory cell MCa[m,j+1] of the j+1-th column are electrically connected to one wiring SLa (j,j+1) in the memory layer ALYa. In a similar manner, the semiconductor device DEV illustrated in FIG. 29 is different from the semiconductor device DEV illustrated in FIG. 1 also in that the memory cell MCb[1,j] to the memory cell MCb[m,j] of the j-th column (here, j is an integer greater than or equal to 1 and less than or equal to n-1) and the memory cell MCb[1,j+1] to the memory cell MCb[m,j+1] of the j+1-th column are electrically connected to one wiring SLb (j,j+1) in the memory layer ALYb.

Note that the wiring SLa (j,j+1) is a wiring obtained by combining the wiring SLa[j] and the wiring SLa[j+1] (both are not illustrated) included in the semiconductor device DEV illustrated in FIG. 1, for example. Similarly, the wiring SLb (j,j+1) is a wiring obtained by combining the wiring SLb[j] and the wiring SLb[j+1] (both are not illustrated) included in the semiconductor device DEV illustrated in FIG. 1, for example.

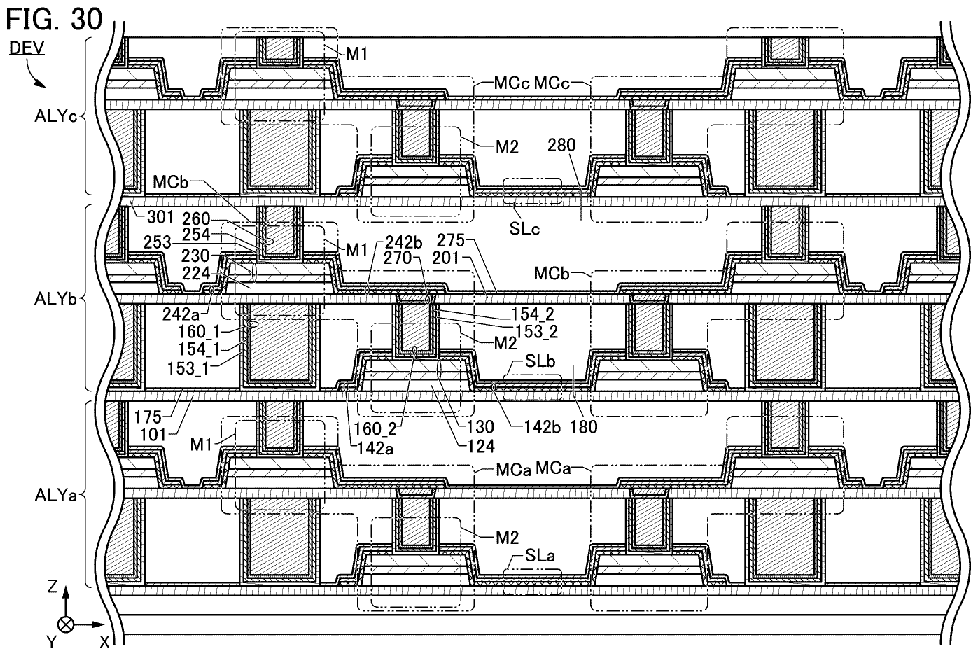

FIG. 30 illustrates an example of a schematic cross-sectional view of the semiconductor device DEV in FIG. 29. In the memory layer ALYa illustrated in FIG. 30, the conductors 142b of the transistors M2 included in adjacent memory cells MCa are integrally provided. The conductor 142b of the memory layer ALYa is also formed in the Y direction (the channel width direction of the transistor M1 and the transistor M2) illustrated in FIG. 30, whereby the wiring SLa is extended. Similarly, in the memory layer ALYb, the conductors 142b of the transistors M2 included in adjacent memory cells MCb are integrally provided. The conductor 142b of the memory layer ALYb is also formed in the Y direction illustrated in FIG. 30, whereby the wiring SLb is extended. Similarly, in the memory layer ALYc, the conductors 142b of the transistors M2 included in adjacent memory cells MCc are integrally provided. The conductor 142b of the memory layer ALYc is also formed in the Y direction illustrated in FIG. 30, whereby a wiring SLc is extended.

As described above, owing to the combination of a plurality of wirings into one wiring, the number of wirings extended in each of the memory layer ALYa and the memory layer ALYb in the semiconductor device DEV in FIG. 29 can be smaller than that in the semiconductor device DEV in FIG. 1. Furthermore, the area of the reduced wirings can be used as part of the memory cell MC, and thus the recording density of each of the memory layer ALYa and the memory layer ALYb can be increased in some cases.

Note that although the semiconductor device DEV in FIG. 29 is described above as a modification example of the semiconductor device DEV in FIG. 1, the semiconductor device DEV in FIG. 1 may be changed to be different from the structure of the semiconductor device DEV in FIG. 29.

For example, in the memory layer ALYa, WBLa[j] and WBLa[j+1] may be combined into one write bit line (not illustrated). In that case, in order to prevent the same data from being written to the memory cell MCa[i,j] of the j-th column (here, i is an integer greater than or equal to 1 and less than or equal to m) and the memory cell MCa[i,j+1] of the j+1-th column at the same time, it is preferable that different write word lines be electrically connected to the gate of the transistor M1 of the memory cell MCa[i,j] and the gate of the transistor M1 of the memory cell MCa[i,j+1]. Note that the same applies to the memory layer ALYb.

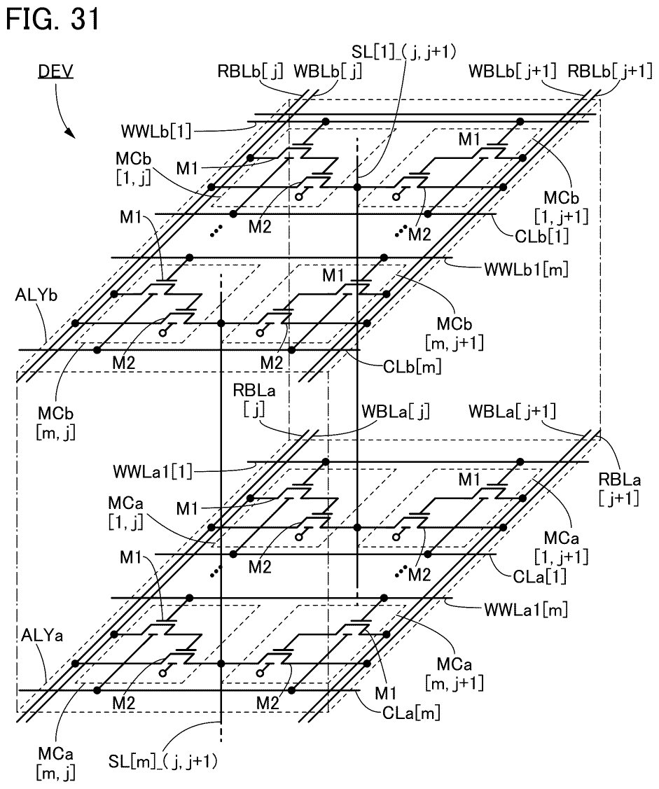

For example, the circuit structure of the semiconductor device DEV in FIG. 1 may be changed to that of the semiconductor device DEV illustrated in FIG. 31. The semiconductor device DEV illustrated in FIG. 31 has a circuit structure further modified from that of the semiconductor device in FIG. 29, in which the wirings SL and the memory cells MC included in the memory layers are electrically connected to each other.

Specifically, the second terminal of the transistor M2 included in each of the memory cell MCa[1,j] and the memory cell MCa[1,j+1] in the memory layer ALYa and the second terminal of the transistor M2 included in each of the memory cell MCb[1,j] and the memory cell MCb[1,j+1] in the memory layer ALYb are electrically connected to a wiring SL[1]_(j,j+1). The second terminal of the transistor M2 included in each of the memory cell MCa[m,j] and the memory cell MCa[m,j+1] in the memory layer ALYa and the second terminal of the transistor M2 included in each of the memory cell MCb[m,j] and the memory cell MCb[m,j+1] in the memory layer ALYb are electrically connected to a wiring SL[m]_(j,j+1).

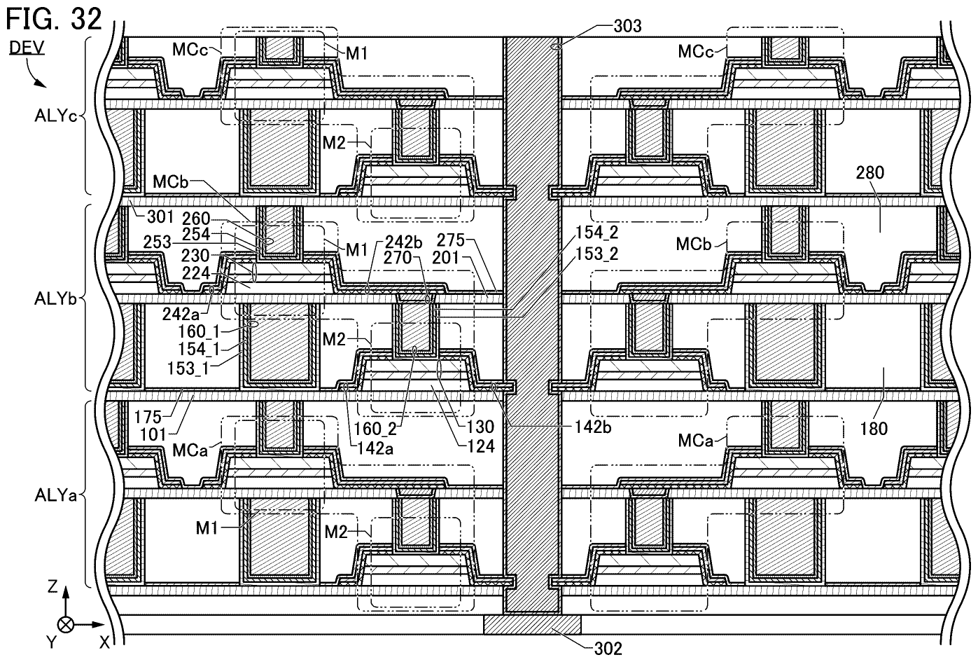

FIG. 32 illustrates an example of a schematic cross-sectional view of the semiconductor device DEV in FIG. 31. In the semiconductor device DEV illustrated in FIG. 32, an opening is provided in a region overlapping with a region between adjacent memory cells MCa in the memory layer ALYa, a region between adjacent memory cells MCb in the memory layer ALYb, and a region between adjacent memory cells MCc in the memory layer ALYc, and a conductor 303 is embedded in the opening.

The conductor 303 corresponds to one wiring SL in FIG. 31. A material that is usable for the conductor 160_1 can be used for the conductor 303, for example.

As illustrated in FIG. 32, the conductor 242b corresponding to the second terminal of the transistor M2 included in each of the memory cell MCa, the memory cell MCb, and the memory cell MCc is preferably provided to be in the opening. The conductor 242b is provided to be in the opening and the opening is filled with the conductor 303, whereby electrical continuity between the conductor 242b and the conductor 303 can be established relatively easily.

Furthermore, the conductor 303 may be provided to be electrically connected to a conductor 302 provided below the memory layer ALYa, as illustrated in FIG. 32. A driver circuit for driving the memory layer ALYa to the memory layer ALYc may be provided below the conductor 302 such that the driver circuit is electrically connected to the conductor 303 through the conductor 302 (not illustrated).

### Modification Example 2 of Semiconductor Device

A circuit structure example of the semiconductor device DEV of one embodiment of the present invention, which is different from those in FIG. 1 and FIG. 31, is described below.

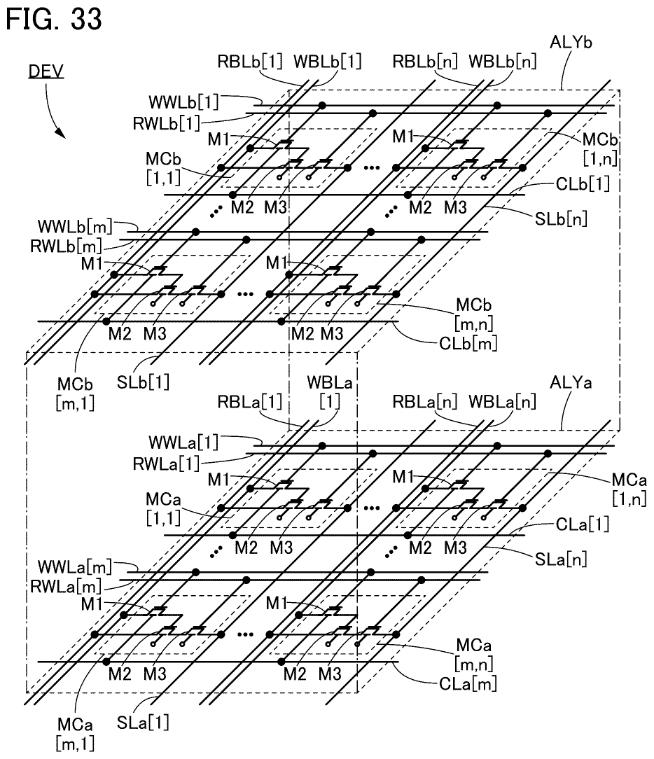

FIG. 33 illustrates a modification example of the semiconductor device DEV illustrated in FIG. 1. Specifically, the semiconductor device DEV illustrated in FIG. 33 is different from the semiconductor device DEV illustrated in FIG. 1 in that the memory cell MCa[1,1] to the memory cell MCa[m,n] each include a transistor M3 in the memory layer ALYa, for example. Similarly, the semiconductor device DEV illustrated in FIG. 33 is different from the semiconductor device DEV illustrated in FIG. 1 in that the memory cell MCb[1,1] to the memory cell MCb[m,n] each include the transistor M3 in the memory layer ALYb, for example.

As the transistor M3, a transistor that is usable as the transistor M1 or the transistor M2 can be used, for example.

In each of the memory cell MCa[1,1] to the memory cell MCa[m,n] of the memory layer ALYa, the second terminal of the transistor M2 is electrically connected to a first terminal of the transistor M3. In each of the memory cell MCb[1,1] to the memory cell MCb[m,n] of the memory layer ALYb, the second terminal of the transistor M2 is electrically connected to the first terminal of the transistor M3.

In each of the memory cell MCa[1,1] to the memory cell MCa[1,n] arranged in the first row of the memory layer ALYa, the gate of the transistor M3 is electrically connected to a wiring RWLa[1]. In each of the memory cell MCa[m, 1] to the memory cell MCa[m,n] arranged in the m-th row of the memory layer ALYa, the gate of the transistor M3 is electrically connected to a wiring RWLa[m]. In each of the memory cell MCb[1,1] to the memory cell MCb[1,n] arranged in the first row of the memory layer ALYb, the gate of the transistor M3 is electrically connected to a wiring RWLb[1]. In each of the memory cell MCb[m, 1] to the memory cell MCb[m,n] arranged in the m-th row of the memory layer ALYb, the gate of the transistor M3 is electrically connected to a wiring RWLb[m].

In each of the memory cell MCa[1,1] to the memory cell MCa[m, 1] arranged in the first column of the memory layer ALYa, a second terminal of the transistor M3 is electrically connected to the wiring SLa[1]. In each of the memory cell MCa[1,n] to the memory cell MCa[m,n] arranged in the n-th column of the memory layer ALYa, the second terminal of the transistor M3 is electrically connected to the wiring SLa[n]. In each of the memory cell MCb[1,1] to the memory cell MCb[m,1] arranged in the first column of the memory layer ALYb, the second terminal of the transistor M3 is electrically connected to the wiring SLb[1]. In each of the memory cell MCb[1,n] to the memory cell MCb[m,n] arranged in the n-th column of the memory layer ALYb, the second terminal of the transistor M3 is electrically connected to the wiring SLb[n].

The wiring RWLa[1] to a wiring RWLa[n] function as read word lines for the memory cell MCa[1,1] to the memory cell MCa[m,n] included in the memory layer ALYa. Similarly, the wiring RWLb[1] to a wiring RWLb[n] function as read word lines for the memory cell MCb[1,1] to the memory cell MCb[m,n] included in the memory layer ALYb. That is, the wiring RWLa[1] to the wiring RWLa[n] and the wiring RWLb[1] to the wiring RWLb[n] function as wirings that transmit selection signals to the memory cells MC on which reading is to be performed. Note that the wiring RWLa[1] to the wiring RWLa[n] and the wiring RWLb[1] to the wiring RWLb[n] may function as wirings that supply a constant potential depending on circumstances.

Next, data writing and data reading to/from the memory cell MC in the semiconductor device DEV illustrated in FIG. 33 are described. Here, as an example, data writing to the memory cell MCa[1,1] in the memory layer ALYa of the semiconductor device DEV and data reading from the memory cell MCa[1,1] are described.

To write data to the memory cell MCa[1,1] of the semiconductor device DEV illustrated in FIG. 33, first, a low-level potential is supplied to each of the wiring RWLa[1] to the wiring RWLa[m] to turn off the transistors M3 included in the memory cell MCa[1,1] to the memory cell MCa[m,n], for example. Next, a high-level potential is supplied to the wiring WWLa[1] to turn on the transistor M1 included in the memory cell MCa[1,1], and a low-level potential is supplied to the wiring WWLa[2] to the wiring WWLa[m] to turn off the transistors M1 included in the memory cells MCa of the second row to the m-th row. Then, data for writing is transmitted to the wiring WBLa[1], and a potential corresponding to the data is written to the gate of the transistor M2 of the memory cell MCa[1,1]. After the data writing to the gate of the transistor M2 of the memory cell MCa[1,1], a low-level potential is supplied to the wiring WWLa[1] to turn off the transistor M1 included in the memory cell MCa[1,1].

To read data from the memory cell MCa[1,1] of the semiconductor device DEV illustrated in FIG. 33, first, the wiring WBLa[1] is precharged to a predetermined potential, and after the precharging, the wiring WBLa[1] is brought into a floating state, for example. Next, a constant potential is supplied to the wiring SLa[1]. After that, a high-level potential is supplied to the wiring RWLa[1] to turn on the transistor M3 included in the memory cell MCa[1,1]. Thus, current flows between the wiring SLa[1] and the wiring WBLa[1] through the transistor M2 and the transistor M3. In particular, since the wiring RWLa[1] is in a floating state, the potential of the wiring RWLa[1] converges to a level corresponding to the potential (gate-source voltage) of each of the wiring SLa[1] and the gate of the transistor M2. After that, the potential of the wiring RBLa[1] is read by the read circuit, whereby the data written to the memory cell MCa[1,1] can be read.

Note that although the data written to the memory cell MCa[1,1] is read from the level of the potential of the wiring WBLa[1] in the example described above, the data reading operation is not limited thereto. For example, in the case where the transistor M3 operates in a saturation region, the data written to the memory cell MCa[1,1] can also be read by applying different potentials to the wiring SLa[1] and the wiring WBLa[1] and measuring the amount of current flowing through the transistor M3. In the case where the transistor M3 operates in a saturation region and the source-drain voltage of the transistor M3 is determined, the amount of current flowing through the transistor M3 depends on the potential of the gate of the transistor M3; thus, the data written to the memory cell MCa[1,1] can be read from the amount of current flowing through the transistor M3.

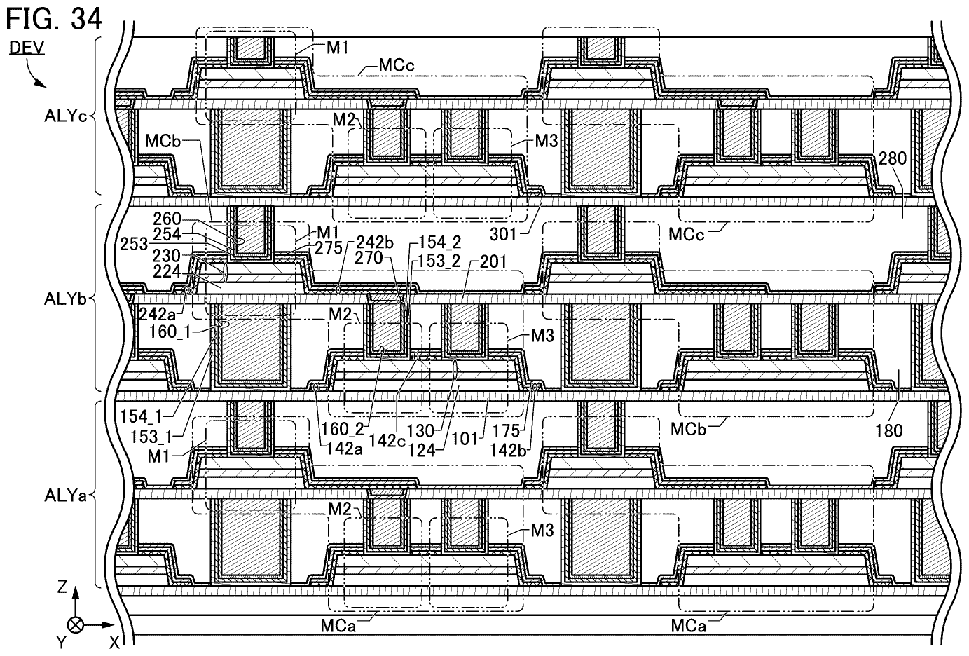

FIG. 34 illustrates an example of a schematic cross-sectional view of the semiconductor device DEV in FIG. 33. In each of the memory cell MCa to the memory cell MCc in the semiconductor device DEV illustrated in FIG. 34, the transistor M2 and the transistor M3 are formed over one island-shaped insulator 124. Specifically, for example, in the semiconductor device DEV in FIG. 34, two first gate insulating films and two first gate electrodes are formed over the oxide 130. In the semiconductor device DEV in FIG. 34, the oxide 130 is formed over the insulator 124, the insulator 153_2 and the insulator 154_2 to be the first gate insulating films are formed sequentially over the oxide 130, and the conductor 160_2 to be the first gate electrode is formed over the insulator 154_2.

The conductor 142a, the conductor 142b, and a conductor 142c are formed over the oxide 130 so as to be separated by the two first gate electrodes (two first gate insulating films). In particular, the conductor 142c is located between the two first gate electrodes (between the two first gate insulating films).

The conductor 142c is preferably formed through a process similar to that for the conductor 142a and the conductor 142b. Therefore, a material similar to that for the conductor 142a and the conductor 142b can be used for the conductor 142c.

Note that for a method for manufacturing the semiconductor device DEV in FIG. 34, the description of FIG. 10A to FIG. 23C is referred to.

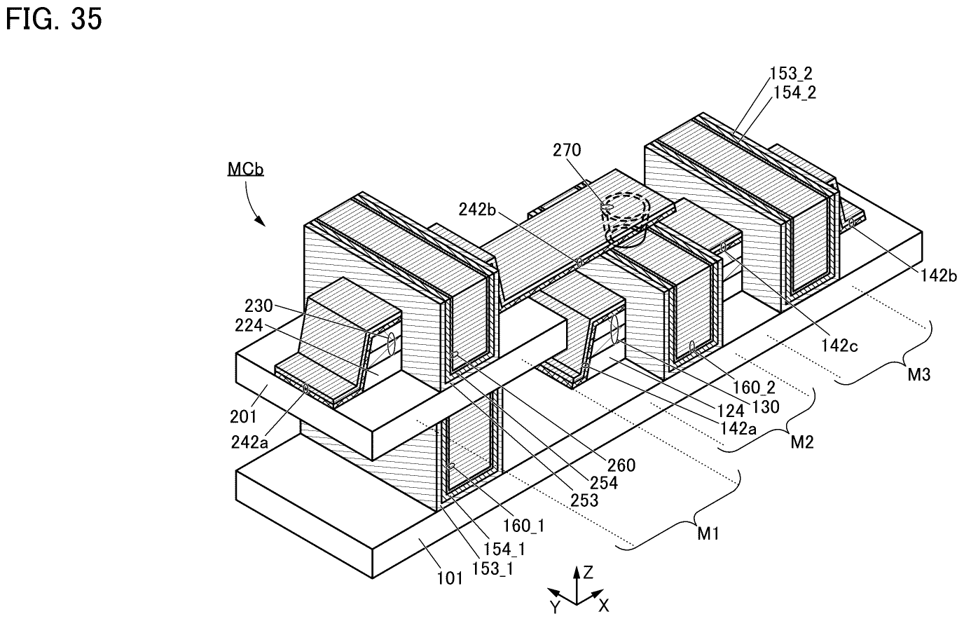

FIG. 35 is a schematic perspective view illustrating a structure example of the memory cell MCb of the semiconductor device DEV in FIG. 34. Note that in FIG. 34, hatching of the insulator 101 and the insulator 201 is omitted intentionally, and part of the insulator 201, the insulator 180, the insulator 280, the insulator 175, and the insulator 275 are not illustrated for easily viewing of the stacked-layer structure of the memory layer ALYb. As illustrated in FIG. 35, the conductor 160_2 of the transistor M3 is extended along the channel width direction of the transistor M3 (the Y direction) like in the case of the transistor M2.

As described above, two transistors can be provided by providing two gate electrodes over a stack of one insulator 124 and one oxide 130. In addition, a plurality of transistors may be provided over the stack by providing three or more gate electrodes.

Note that this embodiment can be combined with any of the other embodiments described in this specification as appropriate.

### Embodiment 2

In this embodiment, another structure example of the semiconductor device described in the above embodiment is described.

### <Circuit Structure Example 2 of Semiconductor Device>

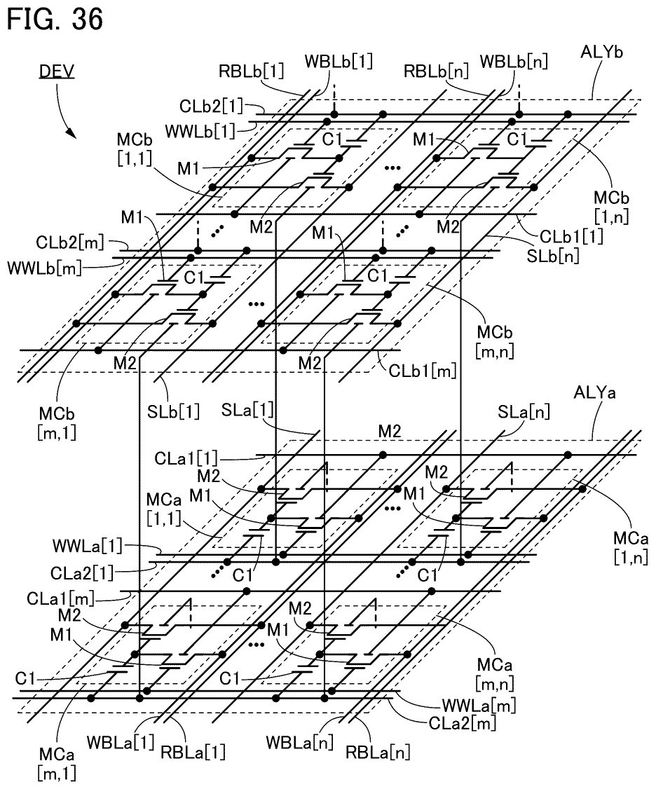

FIG. 36 is a circuit diagram illustrating a modification example of the semiconductor device DEV illustrated in FIG. 1. The semiconductor device DEV illustrated in FIG. 36 is different from the semiconductor device DEV illustrated in FIG. 1 in that a capacitor C1 is included in the memory cell MC. Furthermore, the semiconductor device DEV illustrated in FIG. 36 is different from the semiconductor device DEV illustrated in FIG. 1 also in that a wiring CLa1[1] to a wiring CLa1[m] are extended instead of the wiring CLa[1] to the wiring CLa[m] and that a wiring CLa2[1] to a wiring CLa2[m] are additionally extended in the memory layer ALYa. Similarly, the semiconductor device DEV illustrated in FIG. 36 is different from the semiconductor device DEV illustrated in FIG. 1 also in that a wiring CLb1[1] to a wiring CLb1[m] are extended instead of the wiring CLb[1] to the wiring CLb[m] and that a wiring CLb2[1] to a wiring CLb2[m] are additionally extended in the memory layer ALYb.

Note that for portions in the structure of the semiconductor device DEV in FIG. 36, which are common to the structure of the semiconductor device DEV in FIG. 1, the description of the semiconductor device DEV in FIG. 1 is referred to.

The memory cell MC illustrated in FIG. 36 is an example of a memory cell called a gain cell, like the memory cell MC in FIG. 1, and includes the transistor M1, the transistor M2, and the capacitor C1. Note that the structure of the memory cell MC illustrated in FIG. 36 is also referred to as a NOSRAM (registered trademark) in some cases.

Next, circuit structures of the memory cell MCa[1,1] to the memory cell MCa[m,n] (m is an integer of 1 or more, and n is an integer of 1 or more) and the memory cell MCb[1,1] to the memory cell MCb[m,n] are described.

In each of the memory cell MCa[1,1] to a memory cell MCa[m,n] and the memory cell MCb[1,1] to the memory cell MCb[m,n], the first terminal of the transistor M1 is electrically connected to the gate of the transistor M2 and a first terminal of the capacitor C1.

In each of the memory cell MCa[1,1] to the memory cell MCa[1,n] arranged in the first row of the matrix of the memory layer ALYa, a second terminal of the capacitor C1 is electrically connected to the wiring CLa2[1], and the back gate of the transistor M1 is electrically connected to the wiring CLa1[1]. In each of the memory cell MCa[m, 1] to the memory cell MCa[m,n] arranged in the m-th row of the matrix of the memory layer ALYa, the second terminal of the capacitor C1 is electrically connected to the wiring CLa2[m], and the back gate of the transistor M1 is electrically connected to the wiring CLa1[m]. In each of the memory cell MCb[1,1] to the memory cell MCb[1,n] arranged in the first row of the matrix of the memory layer ALYb, the second terminal of the capacitor C1 is electrically connected to the wiring CLb2[1], and the back gate of the transistor M1 is electrically connected to the wiring CLb1[1]. In each of the memory cell MCb[m, 1] to the memory cell MCb[m,n] arranged in the m-th row of the matrix of the memory layer ALYb, the second terminal of the capacitor C1 is electrically connected to the wiring CLb2[m], and the back gate of the transistor M1 is electrically connected to the wiring CLb1[m].

In each of the memory cell MCb[1,1] to the memory cell MCb[1,n] arranged in the first row of the matrix of the memory layer ALYb, the back gate of the transistor M2 is electrically connected to the wiring CLa2[1] extended in the memory layer ALYa. In each of the memory cell MCb[m, 1] to the memory cell MCb[m,n] arranged in the m-th row of the matrix of the memory layer ALYb, the back gate of the transistor M2 is electrically connected to the wiring CLa2[m] extended in the memory layer ALYa.

In each of the memory cell MCa[1,1] to the memory cell MCa[1,n] arranged in the first row of the matrix of the memory layer ALYa, the back gate of the transistor M2 is electrically connected to a wiring extended in a memory layer below the memory layer ALYa. Note that the wiring can be a wiring having a function similar to that of the wiring CLa2[1] in the memory layer ALYa or the wiring CLb2[1] in the memory layer ALYb, for example. Similarly, in each of the memory cell MCa[m,1] to the memory cell MCa[m,n] arranged in the m-th row of the matrix of the memory layer ALYa, the back gate of the transistor M2 is electrically connected to a wiring extended in the memory layer below the memory layer ALYa. Note that the wiring can be a wiring having a function similar to that of the wiring CLa2[m] in the memory layer ALYa or the wiring CLb2[m] in the memory layer ALYb, for example.

The wiring CLb2[1] extended in the first row of the matrix of the memory layer ALYb is preferably electrically connected to the back gate of the transistor M2 included in the memory cell MC of a memory layer located above the memory layer ALYb. Similarly, the wiring CLb2[m] extended in the m-th row of the matrix of the memory layer ALYb is preferably electrically connected to the back gate of the transistor M2 included in the memory cell MC of the memory layer located above the memory layer ALYb.

In FIG. 36, the wiring CLa2[1] to the wiring CLa2[m] function as write word lines or read word lines for the memory cell MCa[1,1] to the memory cell MCa[m,n], for example. That is, the wiring CLa2[1] to the wiring CLa2[m] function as wirings that transmit selection signals (which may be currents or variable potentials (including pulse voltages)) for selecting the memory cells MCa on which writing or reading is to be performed. Note that the wiring CLa2[1] to the wiring CLa2[m] may function as wirings for supplying a constant potential depending on circumstances.

The wiring CLa2[1] to the wiring CLa2[m] also function as wirings for supplying a potential to the back gate of the transistor M2 in each of the memory cell MCb[1,1] to the memory cell MCb[m,n] included in the memory layer ALYb, for example.

Similarly, the wiring CLb2[1] to the wiring CLb2[m] function as write word lines or read word lines for the memory cell MCb[1,1] to the memory cell MCb[m,n], for example. That is, the wiring CLb2[1] to the wiring CLb2[m] function as wirings that transmit selection signals (which may be currents or variable potentials (including pulse voltages)) for selecting the memory cells MCb on which writing or reading is to be performed. Note that the wiring CLb2[1] to the wiring CLb2[m] may function as wirings for supplying a constant potential depending on circumstances.

The wiring CLb2[1] to the wiring CLb2[m] also function as wirings that supply a potential to the back gates of the transistors M2 of the memory cells MC included in the memory layer above the memory layer ALYb, for example.

Next, data writing to the memory cell MC in the semiconductor device DEV illustrated in FIG. 36 and data reading from the memory cell MC are described. Here, as an example, data writing to the memory cell MCb[1,1] in the memory layer ALYb of the semiconductor device DEV and data reading from the memory cell MCb[1,1] are described.

To write data to the memory cell MCb[1,1] in the semiconductor device DEV illustrated in FIG. 36, first, a first potential (e.g., a ground potential) is supplied to the wiring CLb1[1], for example. Next, a high-level potential is supplied to the wiring WWLb[1] to turn on the transistor M1 included in the memory cell MCb[1,1], and a low-level potential is supplied to the wiring WWLb[2] to the wiring WWLb[m] to turn off the transistors M1 included in the memory cells MCb of the second row to the m-th row. Then, data for writing is transmitted to the wiring WBLb[1], and a potential corresponding to the data is written to the first terminal of the capacitor C1 of the memory cell MCb[1,1]. After the data writing to the first terminal of the capacitor C1 of the memory cell MCb[1,1], a low-level potential is supplied to the wiring WWLb[1] to turn off the transistor M1 included in the memory cell MCb[1,1]. After that, a second potential (e.g., a negative potential) is supplied to the wiring CLb1[1] to reduce the potential of the first terminal of the capacitor C1 of the memory cell MCb[1,1] owing to the peripheral capacitive coupling of the capacitor C1 of the memory cell MCb[1,1]. Note that at that time, it is preferable that the transistor M2 be turned off when the potential of the first terminal of the capacitor C1 in the memory cell MCb[1,1] is reduced.

To read data from the memory cell MCb[1,1] of the semiconductor device DEV illustrated in FIG. 36, first, the second potential supplied to the wiring CLb1[1] is raised to the first potential, for example. At that time, the potential of the first terminal of the capacitor C1 of the memory cell MCb[1,1] increases owing to the peripheral capacitive coupling of the capacitor C1 of the memory cell MCb[1,1] to become a potential corresponding to the data at the time of writing. Then, a constant potential is supplied to the wiring SLb[1], whereby a read signal (a potential or a current) corresponding to the potential of the gate of the transistor M2 (the first terminal of the capacitor C1) is transmitted from the wiring SLb[1] to the wiring RBLb[1] through the transistor M2. After that, the read signal transmitted to the wiring RBLb[1] is read by the read circuit, whereby the data written to the memory cell MCb[1,1] can be read.

As described above, the wiring CLa2[1] functions as a write word line or a read word line for the memory cell MCa[1,1] of the memory layer ALYa. Note that since the wiring CLa2[1] is electrically connected to the back gates of the transistors M2 of the memory cell MCb[1,1] to the memory cell MCb[1,n] located in the first row of the memory layer ALYb, the potential supplied to the wiring CLa2[1] is preferably within a potential range in which the transistor M2 operates appropriately. Specifically, when writing or reading is performed on the memory cell MCb[1,1] of the memory layer ALYb, for example, the potential supplied to the wiring CLa2[1] preferably varies within the range where the transistor M2 can have a threshold voltage such that the transistor M2 cannot be normally on (a state where a channel is present when 0 V is applied between the gate electrode and the source electrode and a current flows through the transistor).

Note that data writing or data reading to/from another memory cell MC can be performed by an operation similar to that described above.

Note that the circuit structure of the semiconductor device of one embodiment of the present invention is not limited to the structure in FIG. 36. The circuit structure of the semiconductor device may be changed depending on circumstances.

### <Cross-Sectional Structure Example 2 of Semiconductor Device>

Next, a structure example of the semiconductor device DEV is described.

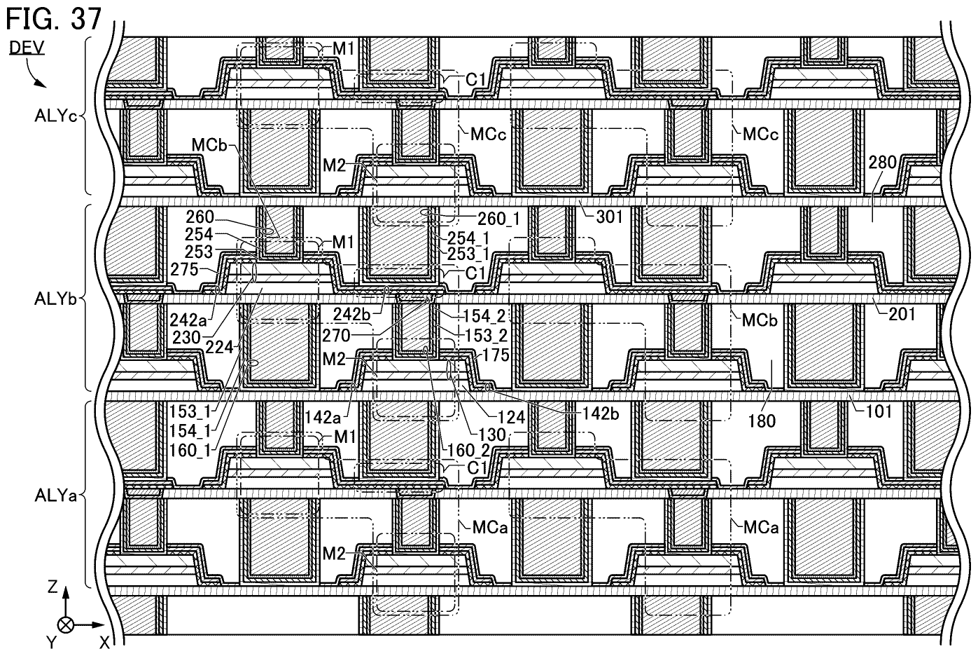

FIG. 37 is a schematic cross-sectional view illustrating the structure example of the semiconductor device DEV in FIG. 36 of one embodiment of the present invention. In FIG. 37, the semiconductor device DEV includes not only the memory layer ALYa and the memory layer ALYb but also the memory layer ALYc.

FIG. 38 is a schematic perspective view illustrating the structure example of the memory cell MCb of the semiconductor device DEV in FIG. 37. Note that in FIG. 38, part of the insulator 201, part of a conductor 260_1, part of an insulator 253_1, part of an insulator 254_1, the insulator 180, the insulator 280, the insulator 175, and the insulator 275 that are described later are not illustrated for easily viewing of the stacked-layer structure of the memory layer ALYa and the memory layer ALYb.

Note that for portions in the structure of the semiconductor device DEV in FIG. 37 and FIG. 38, which are common to the structure of the semiconductor device DEV in FIG. 3 and FIG. 4, the description of the semiconductor device DEV in FIG. 3 is referred to.

The X direction shown in FIG. 37 is parallel to the channel length directions of the transistor M1 and the transistor M2, the Y direction is perpendicular to the X direction, and the Z direction is perpendicular to the X direction and the Y direction. The X direction, the Y direction, and the Z direction shown in FIG. 37 form right-handed systems. Note that arrows indicating the X direction, the Y direction, and the Z direction in FIG. 37 are also shown in FIG. 38 to FIG. 42 and FIG. 44.

In order to briefly describe the structure example of the semiconductor device DEV, first, attention is focused on the memory layer ALYb in FIG. 37.

In the semiconductor device DEV in FIG. 37, an opening reaching the conductor 242b and the insulator 201 is provided in a region of the insulator 280 that overlaps with the conductor 242b and does not overlap with the insulator 224 or the oxide 230. The insulator 253_1 is formed over the insulator 280 corresponding to a side surface of the opening and over the conductor 242b and the insulator 201 corresponding to a bottom portion of the opening. The insulator 254_1 is formed over the insulator 253_1, and the conductor 260_1 is formed over the insulator 254_1.

In the semiconductor device DEV in FIG. 37, the capacitor C1 of the memory cell MCb in FIG. 36 includes the conductor 242b, the conductor 260_1, the insulator 253_1, and the insulator 254_1. Specifically, a region of the conductor 242b that overlaps with the conductor 260_1 corresponds to the first terminal of the capacitor C1 of the memory cell MCb in FIG. 36. The conductor 260_1 corresponds to the second terminal of the capacitor C1 in the memory cell MCb in FIG. 36. The insulator 253_1 and the insulator 254_1 sandwiched between the conductor 242b and the conductor 260_1 function as dielectrics in the capacitor C1.

Furthermore, the conductor 260_1 also functions as the back gate electrode of the transistor M2 included in the memory cell MCc of the memory layer ALYc.

That is, the conductor 260_1 can be a conductor corresponding to any one of the wiring CLb2[1] to the wiring CLb2[m] illustrated in FIG. 36.

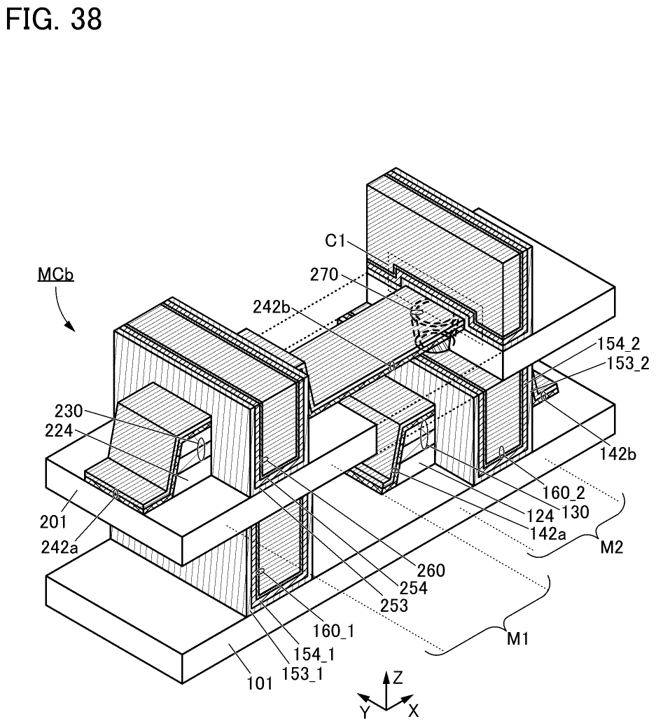

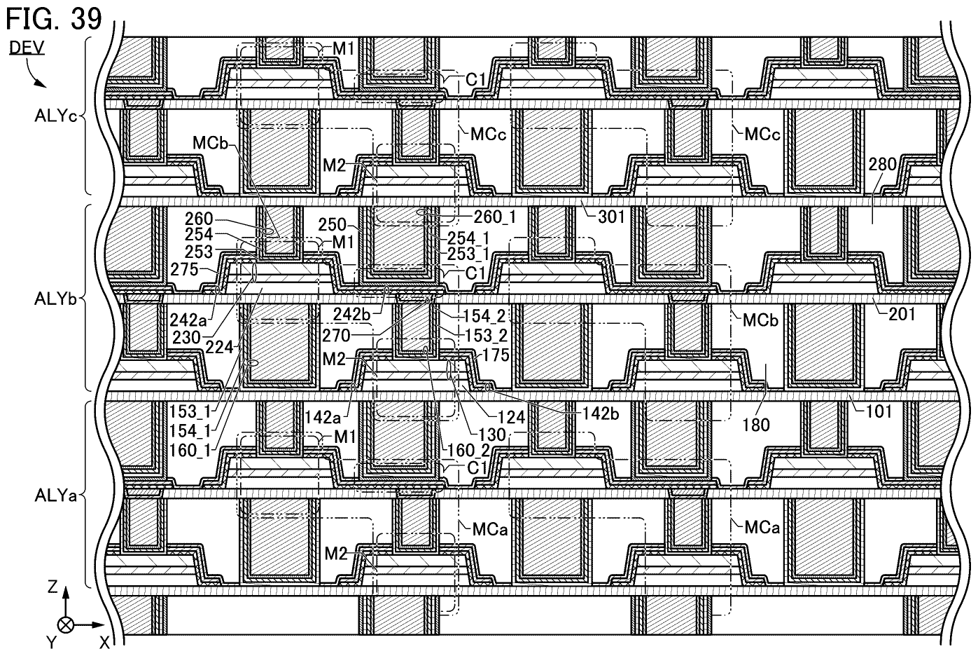

The structure of the semiconductor device DEV in FIG. 37 may be changed depending on circumstances. For example, the insulator 253_1 is formed on the side surface and the bottom portion of the opening in which the back gate electrode of the transistor M2 or the second terminal of the capacitor C1 is formed in the semiconductor device DEV in FIG. 37; however, as illustrated in FIG. 39, a conductor 250 may be formed on the side surface and the bottom portion of the opening in the semiconductor device DEV of one embodiment of the present invention.

The conductor 250 is located over the conductor 242b at the bottom portion of the opening. Accordingly, the conductor 250 is electrically connected to the conductor 242b. That is, the conductor 250 corresponds to the first terminal of the capacitor C1 in FIG. 36.

The conductor 250 is also formed on the side surface of the opening. Accordingly, the electrode area of the first terminal of the capacitor C1 can be larger than the electrode area of the first terminal of the capacitor C1 in the semiconductor device DEV in FIG. 37. Thus, the capacitance value of the capacitor C1 in the semiconductor device DEV in FIG. 39 can be higher than that of the capacitor C1 in the semiconductor device DEV in FIG. 37. Therefore, the potential can be retained for a long time in the memory cell MC included in the semiconductor device DEV in FIG. 39.

A material that is usable for the conductor 160_1 can be used for conductor 250, for example.

In the case of manufacturing the semiconductor device DEV in FIG. 39, the opening in which the gate electrode of the transistor M1 is formed and the opening in which the first terminal and the second terminal of the capacitor C1 are formed are preferably formed not at the same time but in different steps. For example, the opening in which the gate electrode of the transistor M1 is formed is formed first, and the insulator 253, the insulator 254, and the conductor 260 are formed in the opening. After that, the opening in which the first terminal and the second terminal of the capacitor C1 is formed, whereby the conductor 250, the insulator 253_1, the insulator 254_1, and the conductor 260_1 are formed.

### Example 2 of Method for Manufacturing Semiconductor Device

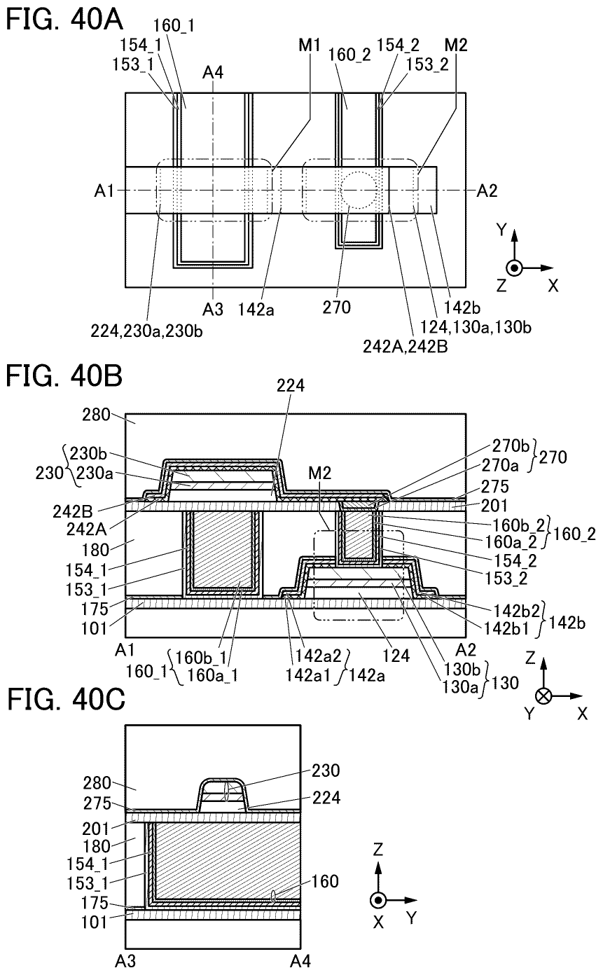

Next, an example of a method for manufacturing the memory layer ALYb of the semiconductor device DEV illustrated in FIG. 37 is described. Note that FIG. 40A to FIG. 42C are used for describing the example of the manufacturing method.

For the formation of the back gate electrodes of the transistor M2 and the transistor M1, the manufacturing method illustrated in FIG. 10A to FIG. 22C is referred to.

Then, with reference to the manufacturing method illustrated in FIG. 10A to FIG. 15C, the insulator 224, the oxide 230a, the oxide 230b, a conductive layer 242A, a conductive layer 242B, the insulator 275, and the insulator 280 are formed over the insulator 201 (see FIG. 40A to FIG. 40C).

Note that the insulator 224 and the oxide 230 are formed in a region overlapping with part of the conductor 160_1.

The conductive layer 242A is a conductive film to be the conductor 242al and the conductor 242b1. Thus, a material that is usable for the conductive layer 142A can be used for the conductive layer 242A. The conductive layer 242B is a conductive film to be the conductor 242a2 and the conductor 242b2. Thus, a material that is usable for the conductive layer 142B can be used for the conductive layer 242B.

Next, in a region where the conductor 260 and the oxide 230 overlap with each other, part of the insulator 280, part of the insulator 275, part of the conductive layer 242A, and part of the conductive layer 242B are processed to form an opening 258A reaching the oxide 230b. By the formation of the opening 258A, the conductor 242al and the conductor 242b1 can be formed from the conductive layer 242A, and the conductor 242a2 and the conductor 242b2 can be formed from the conductive layer 242B (see FIG. 41A to FIG. 41C).

For processing of the part of the insulator 280, the part of the insulator 275, the part of the conductive layer 242A, and the part of the conductive layer 242B, the processing method described with reference to FIG. 16A to FIG. 16C is referred to.

Similarly, in a region overlapping with the conductor 242b and not overlapping with the insulator 224 or the oxide 230, part of the insulator 280 and part of the insulator 275 are processed to form an opening 258B reaching the conductor 242b and the insulator 201 (see FIG. 41A to FIG. 41C).

For processing of the part of the insulator 280 and the part of the insulator 275, the processing method described with reference to FIG. 16A to FIG. 16C is referred to.

In particular, the opening 258B is preferably formed to extend in a direction parallel to the dashed-dotted line A3-A4 in FIG. 41A (the channel width direction of the transistor M1 or the Y direction shown in FIG. 41A). By forming the opening 258B in that manner, the conductor 260_1 to be formed later can be provided to extend in the above-described direction, so that the conductor 260_1 can function as a wiring.

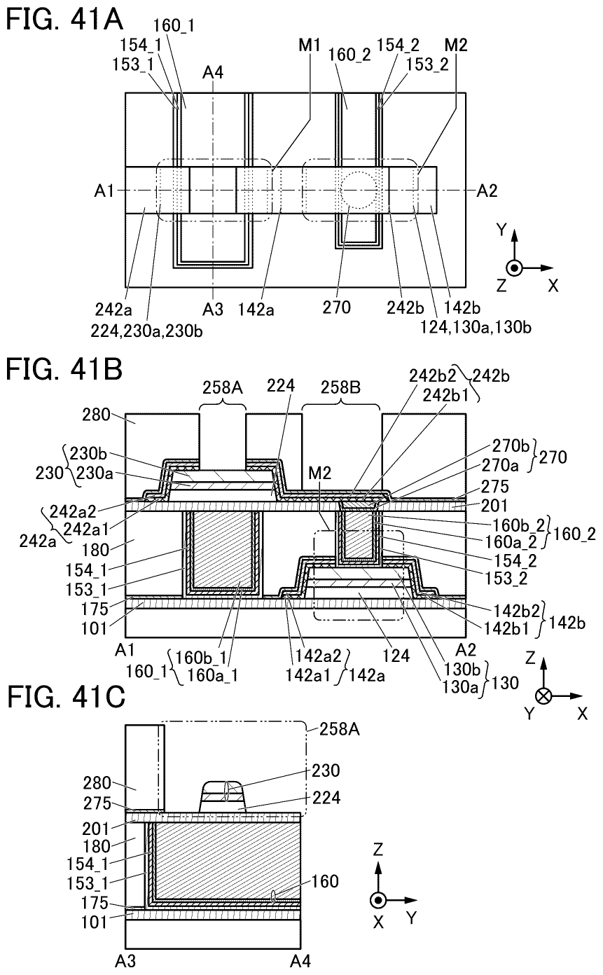

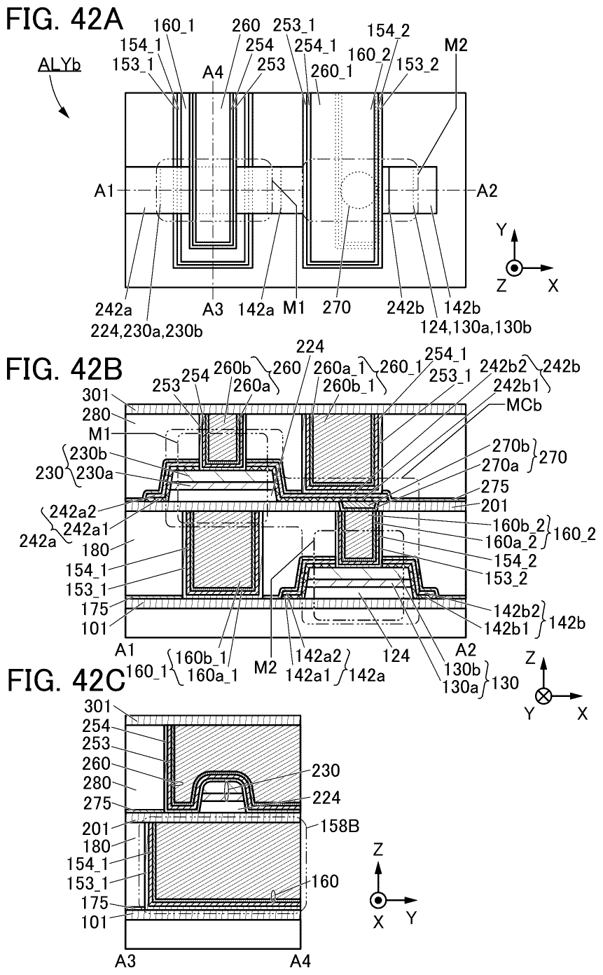

Next, with reference to the manufacturing method illustrated in FIG. 17A to FIG. 19C, the insulator 253, the insulator 254, and the conductor 260 are formed in the opening 258A. Similarly, the insulator 253_1, the insulator 254_1, and the conductor 260_1 (a conductor 260a_1 and a conductor 260b_1) are formed in the opening 258B (see FIG. 42A to FIG. 42C).

Note that each of the insulator 253_1, the insulator 254_1, and the conductor 260_1 may be formed at the same time as or in different steps from the insulator 253, the insulator 254, and the conductor 260.

A material that is usable for the insulator 153_1 can be used for the insulator 253_1. A material that is usable for the insulator 154_1 can be used for the insulator 254_1. A material that is usable for the conductor 160_1 can be used for the conductor 260_1.

Next, the insulator 301 is formed over the insulator 280, the insulator 253, the insulator 254, the conductor 260, the insulator 253_1, the insulator 254_1, and the conductor 260_1 (see FIG. 42A to FIG. 42C). For the formation of the insulator 301, the method for forming the insulator 301 described in Embodiment 1 is referred to.

In the above manner, the semiconductor device including the memory layer ALYa including the memory cell MCa and the memory layer ALYb including the memory cell MCb illustrated in FIG. 36 can be manufactured. As illustrated in FIG. 40A to FIG. 42C, the gate electrode of the transistor M1 and the second terminal of the capacitor C1 can be formed in the same process by using the method for manufacturing the semiconductor device described in this embodiment. Thus, the number of manufacturing steps of the semiconductor device including the transistor M1, the transistor M2, and the capacitor C1 can be reduced.

### Modification Example 3 of Semiconductor Device

A structure example of the semiconductor device DEV of one embodiment of the present invention, which is different from the circuit structure illustrated in FIG. 36, is described below.

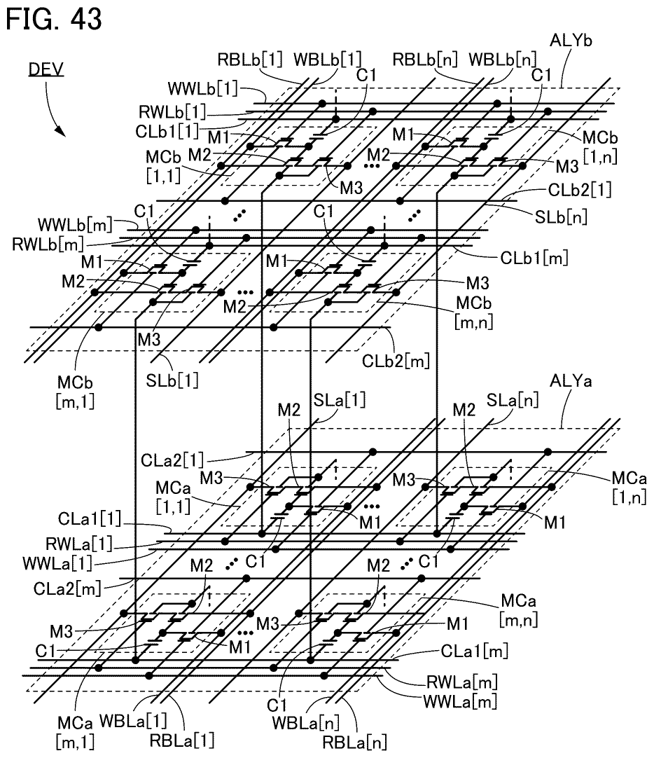

FIG. 43 illustrates a modification example of the semiconductor device DEV illustrated in FIG. 36. Specifically, the semiconductor device DEV illustrated in FIG. 43 is different from the semiconductor device DEV illustrated in FIG. 36 in that the transistor M3 is included in the memory cell MC, for example. The semiconductor device DEV illustrated in FIG. 43 is different from the semiconductor device DEV illustrated in FIG. 36 in that the wiring RWLa[1] to the wiring RWLa[m] are extended in the memory layer ALYa and that the wiring RWLb[1] to the wiring RWLb[m] are extended in the memory layer ALYb.

As the transistor M3, a transistor that is usable as the transistor M1 or the transistor M2 can be used, for example.

In each of the memory cell MCa[1,1] to the memory cell MCa[m,n] of the memory layer ALYa, the second terminal of the transistor M2 is electrically connected to the first terminal of the transistor M3. In each of the memory cell MCb[1,1] to the memory cell MCb[m,n] of the memory layer ALYb, the second terminal of the transistor M2 is electrically connected to the first terminal of the transistor M3.

In each of the memory cell MCa[1,1] to the memory cell MCa[1,n] arranged in the first row of the memory layer ALYa, the gate of the transistor M3 is electrically connected to the wiring RWLa[1]. In each of the memory cell MCa[m, 1] to the memory cell MCa[m,n] arranged in the m-th row of the memory layer ALYa, the gate of the transistor M3 is electrically connected to the wiring RWLa[m]. In each of the memory cell MCb[1,1] to the memory cell MCb[1,n] arranged in the first row of the memory layer ALYb, the gate of the transistor M3 is electrically connected to the wiring RWLb[1]. In each of the memory cell MCb[m, 1] to the memory cell MCb[m,n] arranged in the m-th row of the memory layer ALYb, the gate of the transistor M3 is electrically connected to the wiring RWLb[m].

In each of the memory cell MCa[1,1] to the memory cell MCa[m, 1] arranged in the first column of the memory layer ALYa, the second terminal of the transistor M3 is electrically connected to the wiring SLa[1]. In each of the memory cell MCa[1,n] to the memory cell MCa[m,n] arranged in the n-th column of the memory layer ALYa, the second terminal of the transistor M3 is electrically connected to the wiring SLa[n]. In each of the memory cell MCb[1,1] to the memory cell MCb[m,1] arranged in the first column of the memory layer ALYb, the second terminal of the transistor M3 is electrically connected to the wiring SLb[1]. In each of the memory cell MCb[1,n] to the memory cell MCb[m,n] arranged in the n-th column of the memory layer ALYb, the second terminal of the transistor M3 is electrically connected to the wiring SLb[n].

In each of the memory cell MCb[1,1] to the memory cell MCb[1,n] arranged in the first row of the matrix of the memory layer ALYb, the back gate of the transistor M3 is electrically connected to the back gate of the transistor M2 and the wiring CLa1[1] in the memory layer ALYa. In each of the memory cell MCb[m, 1] to the memory cell MCb[m,n] arranged in the m-th row of the matrix of the memory layer ALYb, the back gate of the transistor M3 is electrically connected to the back gate of the transistor M2 and the wiring CLa1[m] in the memory layer ALYa.

In each of the memory cell MCa[1,1] to the memory cell MCa[1,n] arranged in the first row of the matrix of the memory layer ALYa, the back gate of the transistor M3 is electrically connected to the back gate of the transistor M2 and a wiring extended in a memory layer below the memory layer ALYa. Note that the wiring can be a wiring having a function similar to that of the wiring CLa2[1] in the memory layer ALYa or the wiring CLb2[1] in the memory layer ALYb, for example. Similarly, in each of the memory cell MCa[m,1] to the memory cell MCa[m,n] arranged in the m-th row of the matrix of the memory layer ALYa, the back gate of the transistor M3 is electrically connected to the back gate of the transistor M2 and a wiring extended in the memory layer below the memory layer ALYa. Note that the wiring can be a wiring having a function similar to that of the wiring CLa2[m] in the memory layer ALYa or the wiring CLb2[m] in the memory layer ALYb, for example.

The wiring CLb2[1] extended in the first row of the matrix of the memory layers ALYb is preferably electrically connected to the back gates of the transistor M2 and the transistor M3 included in the memory cell MC of a memory layer located above the memory layer ALYb. Similarly, the wiring CLb2[m] extended in the m-th row of the matrix of the memory layers ALYb is preferably electrically connected to the back gates of the transistor M2 and the transistor M3 included in the memory cell MC of the memory layer located above the memory layer ALYb.

The wiring RWLa[1] to the wiring RWLa[n] function as read word lines for the memory cell MCa[1,1] to the memory cell MCa[m,n] included in the memory layer ALYa, for example. Similarly, the wiring RWLb[1] to the wiring RWLb[n] function as read word lines for the memory cell MCb[1,1] to the memory cell MCb[m,n] included in the memory layer ALYb. That is, the wiring RWLa[1] to the wiring RWLa[n] and the wiring RWLb[1] to the wiring RWLb[n] function as wirings that transmit selection signals to the memory cells MC on which reading is to be performed. Note that the wiring RWLa[1] to the wiring RWLa[n] and the wiring RWLb[1] to the wiring RWLb[n] may function as wirings that supply a constant potential depending on circumstances.

For data writing to the memory cell MC of the semiconductor device DEV illustrated in FIG. 43 and data reading from the memory cell MC, the description of data writing to the memory cell MC of the semiconductor device DEV and data reading from the memory cell MC illustrated in FIG. 33 described in “Modification example 2 of semiconductor device” in Embodiment 1 is referred to.

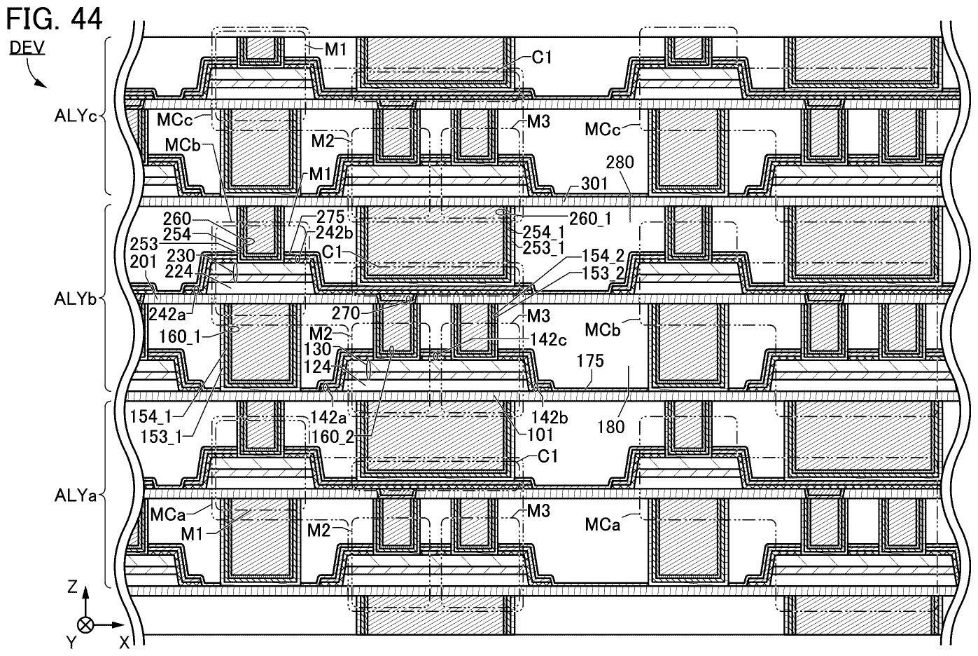

FIG. 44 illustrates an example of a schematic cross-sectional view of the semiconductor device DEV in FIG. 43. In the semiconductor device DEV in FIG. 43, the transistor M2 and the transistor M3 are formed over one island-shaped insulator 124, like in the semiconductor device DEV in FIG. 34. Specifically, for example, the oxide 130 is formed over the insulator 124, and two first gate insulating films and two first gate electrodes are formed over the oxide 130. The conductor 242b is formed to overlap with the oxide 130. An opening reaching the conductor 242b, which is formed by processing part of the insulator 280 and part of the insulator 275, is formed in a region overlapping with the oxide 130. The insulator 253_1, the insulator 254_1, and the conductor 260_1 are formed in the opening.

Note that for the insulator 253_1, the insulator 254_1, and the conductor 260_1, the description of the insulator 253_1, the insulator 254_1, and the conductor 260_1 illustrated in FIG. 37 is referred to.

Note that for a method for manufacturing the semiconductor device DEV in FIG. 44, the description of FIG. 40A to FIG. 42C is referred to.

As described above, two transistors can be provided by providing two gate electrodes over a stack of one insulator 124 and one oxide 130. In addition, a plurality of transistors may be provided over the stack by providing three or more gate electrodes.

Note that this embodiment can be combined with any of the other embodiments described in this specification as appropriate.

### Embodiment 3

In this embodiment, another structure example of the semiconductor device described in the above embodiment is described.

### <Circuit Structure Example 3 of Semiconductor Device>

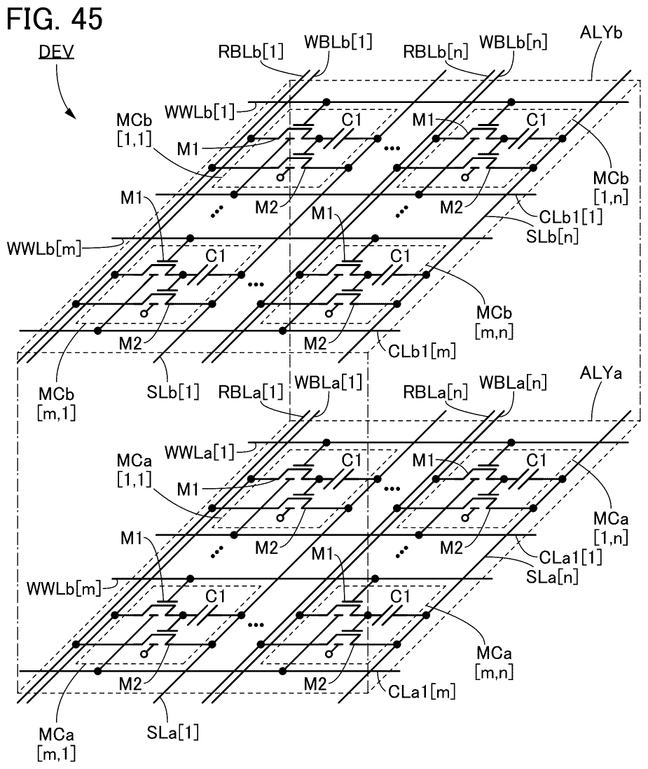

FIG. 45 is a circuit diagram illustrating a modification example of the semiconductor device DEV illustrated in FIG. 1. The semiconductor device DEV illustrated in FIG. 45 is different from the semiconductor device DEV illustrated in FIG. 1 in that the capacitor C1 is included in the memory cell MC. The semiconductor device DEV illustrated in FIG. 45 is different from the semiconductor device DEV illustrated in FIG. 36 in that the second terminal of the capacitor C1 is electrically connected to the wiring SLa in the memory layer ALYa. Similarly, the semiconductor device DEV illustrated in FIG. 45 is different from the semiconductor device DEV illustrated in FIG. 36 in that the second terminal of the capacitor C1 is electrically connected to the wiring SLb in the memory layer ALYb.

Note that for portions in the structure of the semiconductor device DEV in FIG. 45, which are common to the structure of the semiconductor device DEV in FIG. 1, the description of the semiconductor device DEV in FIG. 1 is referred to.

The memory cell MC illustrated in FIG. 45 is an example of a memory cell called a gain cell, like the memory cell MC in FIG. 1, and includes the transistor M1, the transistor M2, and the capacitor C1. Note that the structure of the memory cell MC illustrated in FIG. 45 is also referred to as a NOSRAM (registered trademark) in some cases.

Next, circuit structures of the memory cell MCa[1,1] to the memory cell MCa[m,n] (m is an integer of 1 or more, and n is an integer of 1 or more) and the memory cell MCb[1,1] to the memory cell MCb[m,n] are described.

In each of the memory cell MCa[1,1] to a memory cell MCa[m,n] and the memory cell MCb[1,1] to the memory cell MCb[m,n], the first terminal of the transistor M1 is electrically connected to the gate of the transistor M2 and the first terminal of the capacitor C1.

In each of the memory cell MCa[1,1] to the memory cell MCa[m, 1] arranged in the first column of the matrix of the memory layer ALYa, the second terminal of the capacitor C1 is electrically connected to the wiring SLa[1]. In each of the memory cell MCa[1,n] to the memory cell MCa[m,n] arranged in the n-th column of the matrix of the memory layer ALYa, the second terminal of the capacitor C1 is electrically connected to the wiring SLa[n]. In each of the memory cell MCb[1,1] to the memory cell MCb[m,1] arranged in the first column of the matrix of the memory layer ALYb, the second terminal of the capacitor C1 is electrically connected to the wiring SLb[1]. In each of the memory cell MCb[1,n] to the memory cell MCb[m,n] arranged in the n-th column of the matrix of the memory layer ALYb, the second terminal of the capacitor C1 is electrically connected to the wiring SLb[n].

Also in the above structure of the semiconductor device DEV in FIG. 45, data writing to the memory cell MC or data reading from the memory cell MC can be performed in a manner similar to that in the structure of the semiconductor device DEV in FIG. 1. Note that, for example, in the case where a writing operation or a reading operation is performed in the memory layer ALYa of the semiconductor device DEV in FIG. 45, a constant potential is preferably supplied to the wiring SLa[1] to the wiring SLa[n].

### <Cross-Sectional Structure Example 3 of Semiconductor Device>

Next, a structure example of the semiconductor device DEV in FIG. 45 is described.

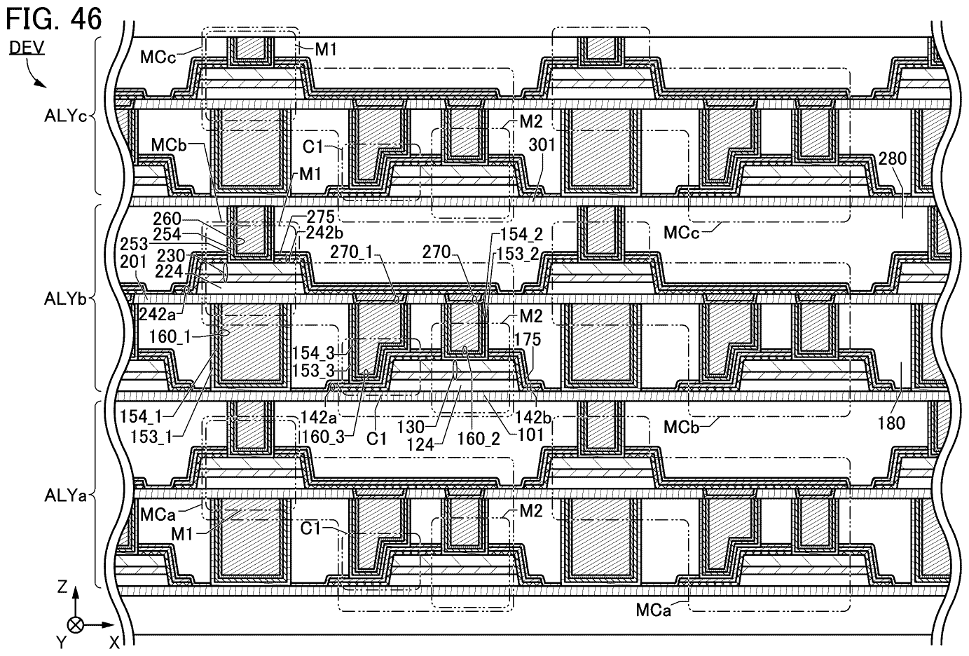

FIG. 46 is a schematic cross-sectional view illustrating the structure example of the semiconductor device DEV in FIG. 45 of one embodiment of the present invention. Note that the structure of the semiconductor device DEV in FIG. 46 is a modification example of the structure of the semiconductor device DEV in FIG. 3. Therefore, for portions in the structure of the semiconductor device DEV in FIG. 46, which are common to the structure of the semiconductor device DEV in FIG. 3, the description of the semiconductor device DEV in FIG. 3 is referred to.

The X direction shown in FIG. 46 is parallel to the channel length directions of the transistor M1 and the transistor M2, the Y direction is perpendicular to the X direction, and the Z direction is perpendicular to the X direction and the Y direction. The X direction, the Y direction, and the Z direction shown in FIG. 46 form right-handed systems. Note that arrows indicating the X direction, the Y direction, and the Z direction in FIG. 46 are also shown FIG. 47.

In order to briefly describe the structure example of the semiconductor device DEV, first, attention is focused on the memory layer ALYb in FIG. 46.

In the memory layer ALYb, an opening reaching the conductor 142a is provided in a region where the insulator 180, the insulator 175, and the conductor 142a overlap with each other. Note that FIG. 46 illustrates an example in which part of the insulator 124 and part of the oxide 130 overlap with the region. Thus, the opening includes an end portion of the insulator 124 and an end portion of the oxide 130.

The opening may be formed at the same time as or in different steps from the opening in which the back gate electrode of the transistor M1 is formed and the opening in which the gate electrode of the transistor M2 is formed, for example. For the formation method of the opening, the formation method illustrated in FIG. 16A to FIG. 16C, the formation method illustrated in FIG. 24A to FIG. 24C, or the formation method illustrated in FIG. 27A to FIG. 27C is referred to.

The insulator 153_3 is formed on a side surface and a bottom portion of the opening. The insulator 154_3 is formed over the insulator 153_3, and the conductor 160_3 is formed over the insulator 154_3.

The insulator 153_3, the insulator 154_3, and the conductor 160_3 can be formed at the same time as the insulator 153_1, the insulator 154_1, the conductor 160_1, the insulator 153_2, the insulator 154_2, and the conductor 160_2, for example. Note that for the formation method of the insulator 153_3, the insulator 154_3, and the conductor 160_3, the formation method illustrated in FIG. 17A to FIG. 19C is referred to.

Note that a material that is usable for the insulator 153_1 or the insulator 153_2 can be used for the insulator 153_3. A material that is usable for the insulator 154_1 or the insulator 154_2 can be used for the insulator 154_3. A material that is usable for the conductor 160_1 or the conductor 160_2 can be used for the conductor 160_3.

The conductor 160_3 is provided above the conductor 142a with the insulator 153_3 and the insulator 154_3 therebetween, whereby the capacitor C1 in which part of the conductor 142a and part of the conductor 160_3 serve as a pair of electrodes can be formed. In that case, the insulator 153_3 and the insulator 154_3 function as the dielectrics of the capacitor C1.

Furthermore, in that case, the conductor 142a functions as any one of the wiring SLb[1] to the wiring SLb[n]. Moreover, the conductor 142b functions as any one of the wiring RBLb[1] to the wiring RBLb[n].

The insulator 201 is formed over the insulator 180, the insulator 153_1, the insulator 154_1, the conductor 160_1, the insulator 153_2, the insulator 154_2, the conductor 160_2, the insulator 153_3, the insulator 154_3, and the conductor 160_3. A first opening is provided in the insulator 201 in a region overlapping with part of the conductor 160_2, and a second opening is provided in the insulator 201 in a region overlapping with part of the conductor 160_3. For the formation method of the first opening and the second opening, the formation method illustrated in FIG. 20A to FIG. 20C is referred to.

The conductor 270 is formed in the first opening. A conductor 270_1 is formed in the second opening.

The conductor 270 and the conductor 270_1 can be formed at the same time. For the formation method of the conductor 270 and the conductor 270_1, the formation method illustrated in FIG. 21A to FIG. 22C is referred to. The conductor 270 and the conductor 270_1 may be formed in different steps.

Note that a material that is usable for the conductor 270_1 can be used for the conductor 270.

The conductor 242b is formed over the conductor 270 and the conductor 270_1. For the formation method of the conductor 242b, the formation method illustrated in FIG. 23A to FIG. 23C is referred to.

With the use of the structure of the semiconductor device DEV in FIG. 46 in manufacturing the semiconductor device DEV in FIG. 45, the back gate electrode of the transistor M1, the gate electrode of the transistor M2, and the second terminal of the capacitor C1 can be formed in the same process. Therefore, the number of manufacturing steps of the semiconductor device DEV including the transistor M1, the transistor M2, and the capacitor C1 can be reduced.

In the semiconductor device illustrated in FIG. 46, which includes the memory cell MCa, the memory cell MCb, and the memory cell MCc, the area occupied by the memory cells can be small. In other words, the recording density of the semiconductor device can be increased.

Note that the structure of the semiconductor device of one embodiment of the present invention is not limited to the structure in FIG. 46. The circuit structure of the semiconductor device may be changed depending on circumstances.

For example, the structure of the semiconductor device in FIG. 46 may be changed to that of the semiconductor device DEV illustrated in FIG. 47. In the structure of the semiconductor device DEV in FIG. 47, the opening in which the first terminal of the capacitor C1 is provided is provided in a region where the insulator 124, the oxide 130, and the conductor 142a overlap with each other.

Note that for the method for manufacturing the semiconductor device DEV in FIG. 47, the description of the semiconductor device DEV in FIG. 46 is referred to.

When the memory layer ALYa, the memory layer ALYb, and the memory layer ALYc are formed as illustrated in FIG. 47, the area occupied by the memory cells MC can be reduced. Accordingly, the semiconductor device can be miniaturized or highly integrated, resulting in high recording density.

This embodiment can be combined as appropriate with any of the other embodiments and the like described in this specification.

### Embodiment 4

In this embodiment, a structure example of a memory device including the semiconductor device described in the above embodiment is described.

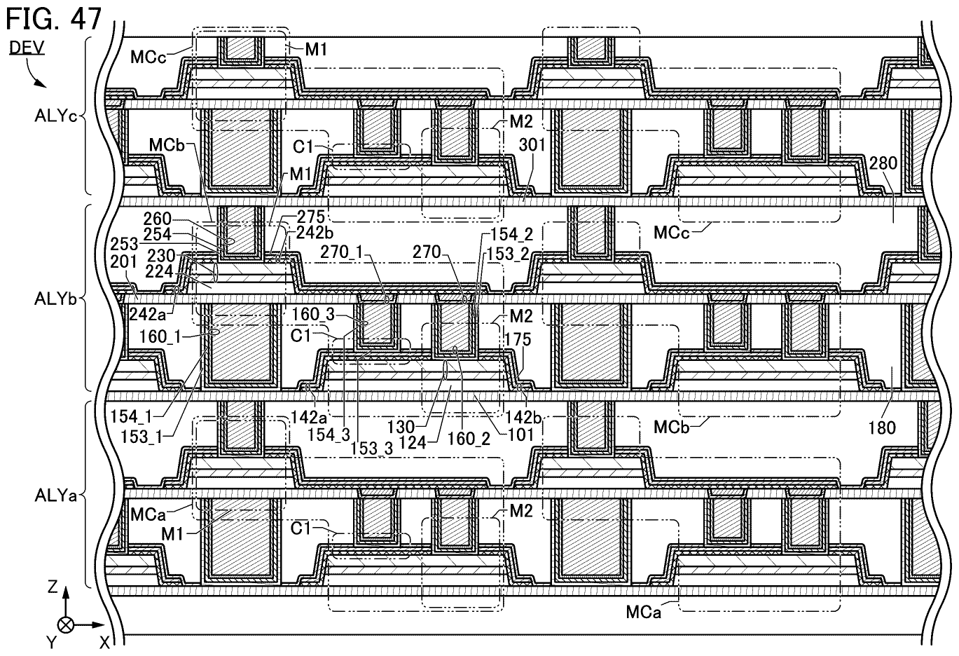

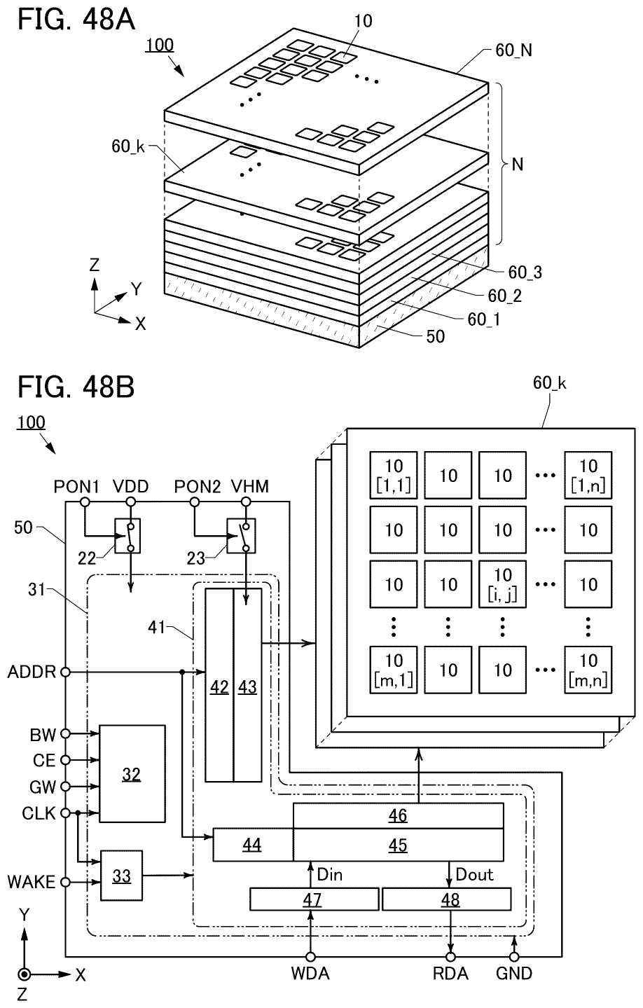

FIG. 48A is a schematic perspective view illustrating a structure example of a memory device 100. FIG. 48B is a block diagram illustrating the structure example of the memory device 100. The memory device 100 includes a driver circuit layer 50 and N (N is a integer of 1 or more) memory layers 60. One memory layer 60 includes a plurality of memory cells 10 arranged in a matrix of m rows and n columns. Note that FIG. 48B illustrates an example where a memory cell 10[1,1], a memory cell 10[m,1] (here, m is an integer of 1 or more), a memory cell 10[1,n] (here, n is an integer of 1 or more), a memory cell 10[m,n], and a memory cell 10 [i,j] (here, i is an integer greater than or equal to 1 and less than or equal to m, and j is an integer greater than or equal to 1 and less than or equal to n) are provided in a memory layer 60_k.

Note that the memory layer 60 corresponds to the memory layer ALYa or the memory layer ALYb described in Embodiment 1. The memory cell 10 corresponds to, for example, the memory cell MCa or the memory cell MCb described in Embodiment 1.

The N memory layers 60 are provided over the driver circuit layer 50. Provision of the N memory layers 60 over the driver circuit layer 50 can reduce the area occupied by the memory device 100. Furthermore, memory capacity per unit area can be increased.

In this embodiment and the like, the first memory layer 60 is denoted by a memory layer 60_1, the second memory layer 60 is denoted by a memory layer 60_2, and the third memory layer 60 is denoted by a memory layer 60_3. Furthermore, the k-th memory layer 60 (k is an integer greater than or equal to 1 and less than or equal to N) is denoted by a memory layer 60_k, and the N-th memory layer 60 is denoted by a memory layer 60_N. Note that in this embodiment and the like, the simple term “memory layer 60” is sometimes used in the case of describing a matter related to all the N memory layers 60 or showing a matter common to the N memory layers 60.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs a logical operation on the signal CE, the signal GW, and the signal BW to determine an operation mode (e.g., a writing operation or a reading operation) of the memory device 100. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed.

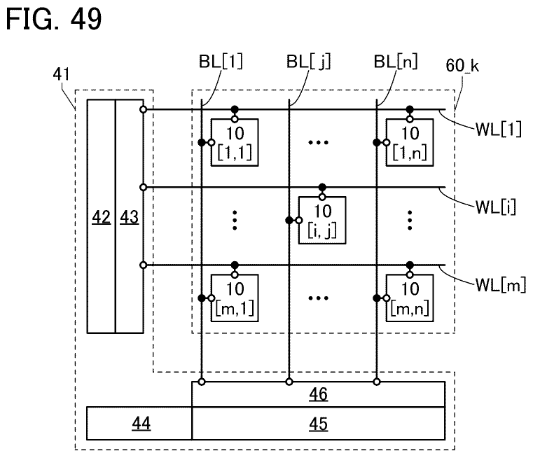

The row driver 43 has a function of selecting a write and read word line (e.g., any one of a wiring WL[1] to a wiring WL[m] illustrated in FIG. 49 described later) specified by the row decoder 42.

The column driver 45 has a function of writing data to the memory cells 10, a function of reading data from the memory cells 10, and a function of retaining the read data. The column driver 45 has a function of selecting write and read bit lines (e.g., a wiring BL[1] to a wiring BL[n] illustrated in FIG. 49 described later) specified by the column decoder 44.

The input circuit 47 has a function of retaining the signal WDA. Data retained by the input circuit 47 (the first data in the above embodiment) is output to the column driver 45. Data output from the input circuit 47 is data (Din) to be written to the memory cells 10. Data (Dout) read from the memory cells 10 by the column driver 45 is output to the output circuit 48. Note that in the above embodiment, the read data (Dout) is treated as arithmetic operation result data. The output circuit 48 has a function of retaining Dout. In addition, the output circuit 48 has a function of outputting Dout to the outside of the memory device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 100, a high power supply voltage is VDD and a low power supply voltage is GND (a ground potential). VHM is a high power supply voltage used to set a word line at a high level and is higher than VDD. The on state and the off state of the PSW 22 are switched by the signal PON1, and the on state and the off state of the PSW 23 is switched by the signal PON2. The number of power domains to which VDD is supplied is one in the peripheral circuit 31 in FIG. 48B but can be more than one. In that case, a power switch is provided for each power domain.

Next, electrical connection between the peripheral circuit 41 and the memory layer 60 is described.

FIG. 49 is a block diagram illustrating a structure example of the peripheral circuit 41 and the memory layer 60_k. In FIG. 49, the row decoder 42 and the row driver 43 are electrically connected to each of the wiring WL[1] to the wiring WL[m], and the column decoder 44, the column driver 45, and the sense amplifier 46 are electrically connected to each of the wiring BL[1] to the wiring BL[n].

Note that the wiring WL[1] to the wiring WL[m] are wirings corresponding to the wiring WWLa[1] to the wiring WWLa[m], the wiring RWLa[1] to the wiring RWLa[m], the wiring WWLb[1] to the wiring WWLb[m], and the wiring RWLb[1] to the wiring RWLb[m] described in Embodiment 1. That is, the wiring WL[1] to the wiring WL[m] function as word lines.

The wiring BL[1] to the wiring BL[n] are wirings corresponding to the wiring WBLa[1] to the wiring WBLa[n], the wiring RBLa[1] to the wiring RBLa[n], the wiring WBLb[1] to the wiring WBLb[n], and the wiring RBLb[1] to the wiring RBLb[n] described in Embodiment 1. That is, the wiring BL[1] to the wiring BL[n] function as bit lines.

The memory cell 10 [i,j] placed in the i-th row and the j-th column is electrically connected to the wiring WL [i] and the wiring BL [j].

As illustrated in FIG. 49, the memory layer 60_k is electrically connected to the peripheral circuit 41, whereby data writing to the memory layer 60_k and data reading from the memory layer 60_k can be performed.

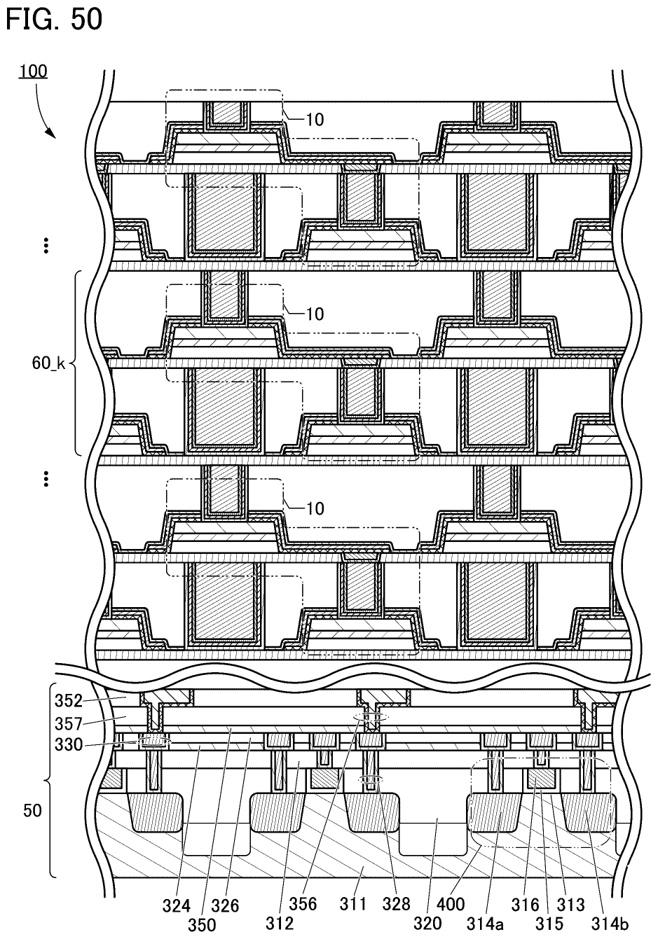

Next, FIG. 50 illustrates a cross-sectional structure example of the memory device 100 of one embodiment of the present invention. The memory device 100 illustrated in FIG. 50 includes a plurality of memory layers 60 (the memory layers ALYa or the memory layers ALYb in FIG. 3 described in Embodiment 1) above the driver circuit layer 50. The description of the memory layers 60 in this embodiment is omitted in order to reduce repeated description.

FIG. 50 also illustrates a transistor 400 included in the driver circuit layer 50 as an example. The transistor 400 is provided on a substrate 311 and includes a conductor 316 functioning as a gate, an insulator 315 functioning as a gate insulator, a semiconductor region 313 including part of the substrate 311, and low-resistance regions 314a and 314b functioning as a source region and a drain region. The transistor 400 may be a p-channel transistor or an n-channel transistor. As the substrate 311, a single crystal silicon substrate can be used, for example.

Here, in the transistor 400 illustrated in FIG. 50, the semiconductor region 313 (part of the substrate 311) where a channel is formed has a protruding shape. The conductor 316 is provided to cover a side surface and a top surface of the semiconductor region 313 with the insulator 315 therebetween. Note that a material for adjusting the work function may be used as the conductor 316. Such a transistor 400 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon On Insulator) substrate.

Note that the transistor 400 illustrated in FIG. 50 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, part of a conductor may function as a wiring and part of the conductor may function as a plug.

For example, an insulator 320, an insulator 312, an insulator 324, and an insulator 326 are stacked in this order over the transistor 400 as interlayer films. A conductor 328 or the like is embedded in the insulator 320 and the insulator 312. A conductor 330 or the like is embedded in the insulator 324 and the insulator 326. Note that the conductor 328 and the conductor 330 function as a contact plug or a wiring.

The insulators functioning as the interlayer films may also function as planarization films that cover an uneven shape thereunder. For example, the top surface of the insulator 312 may be planarized by planarization treatment using a chemical mechanical polishing (CMP) method or the like to improve planarity.

A wiring layer may be provided over the insulator 326 and the conductor 330. For example, in FIG. 50, an insulator 350, an insulator 357, and an insulator 352 are stacked sequentially over the insulator 326 and the conductor 330. A conductor 356 is formed in the insulator 350, the insulator 357, and the insulator 352. The conductor 356 functions as a contact plug or a wiring. For example, the transistor 400 is electrically connected to the wiring WL or the wiring BL through the conductor 356, the conductor 330, or the like.

This embodiment can be combined as appropriate with any of the other embodiments and the like described in this specification.

### Embodiment 5

In this embodiment, examples of a semiconductor wafer where the memory device or the like described in the above embodiment is formed and electronic components incorporating the memory device are described.

### <Semiconductor Wafer>

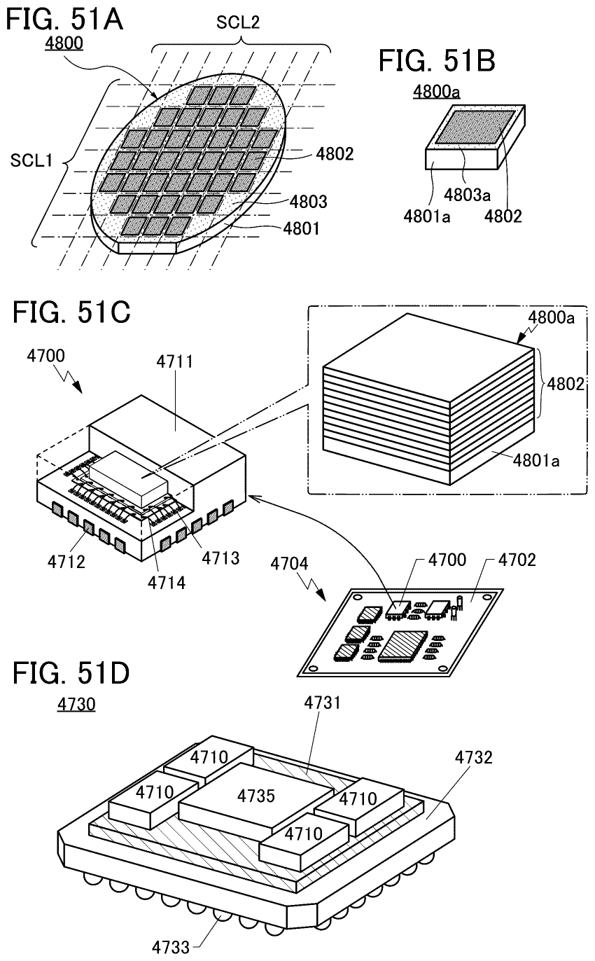

First, an example of a semiconductor wafer where a memory device or the like is formed is described with reference to FIG. 51A.

A semiconductor wafer 4800 illustrated in FIG. 51A includes a wafer 4801 and a plurality of circuit portions 4802 provided on the top surface of the wafer 4801. Note that a portion without the circuit portion 4802 on the top surface of the wafer 4801 is a spacing 4803 that is a region for dicing.

The semiconductor wafer 4800 can be fabricated by forming the plurality of circuit portions 4802 on the surface of the wafer 4801 by a pre-process. After that, a surface of the wafer 4801 opposite to the surface provided with the plurality of circuit portions 4802 may be ground to thin the wafer 4801. Through this process, warpage or the like of the wafer 4801 is reduced and the size of the component can be reduced.

A dicing process is performed as a next process. The dicing is performed along scribe lines SCL1 and scribe lines SCL2 (referred to as dicing lines or cutting lines in some cases) indicated by dashed-dotted lines. Note that to perform the dicing process easily, it is preferable that the spacing 4803 be provided so that the plurality of scribe lines SCL1 are parallel to each other, the plurality of scribe lines SCL2 are parallel to each other, and the scribe lines SCL1 are perpendicular to the scribe lines SCL2.

With the dicing process, a chip 4800a as illustrated in FIG. 51B can be cut out from the semiconductor wafer 4800. The chip 4800a includes a wafer 4801a, the circuit portion 4802, and a spacing 4803a. Note that it is preferable to make the spacing 4803a small as much as possible. In this case, the width of the spacing 4803 between adjacent circuit portions 4802 is substantially the same as a cutting allowance of the scribe line SCL1 or a cutting allowance of the scribe line SCL2.

Note that the shape of the element substrate of one embodiment of the present invention is not limited to the shape of the semiconductor wafer 4800 illustrated in FIG. 51A. The element substrate may be a rectangular semiconductor wafer, for example. The shape of the element substrate can be changed as appropriate, depending on a fabrication process of an element and an apparatus for fabricating the element.

### <Electronic Component>

FIG. 51C is a perspective view of an electronic component 4700 and a substrate (a mounting board 4704) on which the electronic component 4700 is mounted. The electronic component 4700 illustrated in FIG. 51C includes the chip 4800a in a mold 4711. Note that the chip 4800a illustrated in FIG. 51C is shown to have a structure where the circuit portions 4802 are stacked. That is, the memory device described in the above embodiment can be used for the circuit portion 4802. To illustrate the inside of the electronic component 4700, some portions are omitted in FIG. 51C. The electronic component 4700 includes a land 4712 outside the mold 4711. The land 4712 is electrically connected to an electrode pad 4713, and the electrode pad 4713 is electrically connected to the chip 4800a through a wire 4714. The electronic component 4700 is mounted on a printed circuit board 4702, for example. A plurality of such electronic components are combined and electrically connected to each other on the printed circuit board 4702, so that the mounting board 4704 is completed.

FIG. 51D is a perspective view of an electronic component 4730. The electronic component 4730 is an example of a SiP (System in Package) or an MCM (Multi Chip Module). In the electronic component 4730, an interposer 4731 is provided on a package substrate 4732 (a printed circuit board), and a semiconductor device 4735 and a plurality of semiconductor devices 4710 are provided on the interposer 4731.

The electronic component 4730 includes the semiconductor devices 4710. Examples of the semiconductor device 4710 include the memory device described in the above embodiment and a high bandwidth memory (HBM). In addition, an integrated circuit (a semiconductor device) such as a CPU, a GPU, an FPGA, or a memory device can be used as the semiconductor device 4735, for example.

As the package substrate 4732, a ceramic substrate, a plastic substrate, a glass epoxy substrate or the like can be used. As the interposer 4731, a silicon interposer, a resin interposer, or the like can be used.

The interposer 4731 includes a plurality of wirings and has a function of electrically connecting a plurality of integrated circuits with different terminal pitches. The plurality of wirings are provided in a single layer or multiple layers. In addition, the interposer 4731 has a function of electrically connecting an integrated circuit provided on the interposer 4731 to an electrode provided on the package substrate 4732. Accordingly, the interposer is sometimes referred to as a “redistribution substrate” or an “intermediate substrate”. Furthermore, a through electrode is provided in the interposer 4731 and the through electrode is used to electrically connect an integrated circuit and the package substrate 4732 in some cases. Moreover, for a silicon interposer, a TSV (Through Silicon Via) can also be used as the through electrode.

A silicon interposer is preferably used as the interposer 4731. A silicon interposer can be fabricated at lower cost than an integrated circuit because it is not necessary to provide an active element. Meanwhile, since wirings of a silicon interposer can be formed through a semiconductor process, formation of minute wirings, which is difficult for a resin interposer, is easy.

In order to achieve a wide memory bandwidth, many wirings need to be connected to HBM. Therefore, formation of minute and high-density wirings is required for an interposer on which HBM is mounted. For this reason, a silicon interposer is preferably used as the interposer on which HBM is mounted.

In a SiP, an MCM, or the like using a silicon interposer, a decrease in reliability due to a difference in the coefficient of expansion between an integrated circuit and the interposer is less likely to occur. Furthermore, a silicon interposer has high surface flatness, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on an interposer.

In addition, a heat sink (a radiator plate) may be provided to overlap with the electronic component 4730. In the case of providing a heat sink, the heights of integrated circuits provided on the interposer 4731 are preferably equal to each other. For example, in the electronic component 4730 described in this embodiment, the heights of the semiconductor devices 4710 and the semiconductor device 4735 are preferably equal to each other.

To mount the electronic component 4730 on another substrate, an electrode 4733 may be provided on a bottom portion of the package substrate 4732. FIG. 51D illustrates an example where the electrode 4733 is formed of a solder ball. Solder balls are provided in a matrix on the bottom portion of the package substrate 4732, so that BGA (Ball Grid Array) mounting can be achieved. Alternatively, the electrode 4733 may be formed of a conductive pin. When conductive pins are provided in a matrix on the bottom portion of the package substrate 4732, PGA (Pin Grid Array) mounting can be achieved.

The electronic component 4730 can be mounted on another substrate by various mounting methods other than BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be used.

Note that this embodiment can be combined with any of the other embodiments described in this specification as appropriate.

### Embodiment 6

In this embodiment, a CPU that can include the memory device of the above embodiment is described.

FIG. 52 is a block diagram illustrating a structure example of a CPU in part of which the memory device described in the above embodiment is used.

The CPU illustrated in FIG. 52 includes an ALU 1191 (ALU: Arithmetic Logic Unit), an ALU controller 1192, an instruction decoder 1193, an interrupt controller 1194, a timing controller 1195, a register 1196, a register controller 1197, a bus interface 1198 (Bus I/F), a rewritable ROM 1199, and a ROM interface 1189 (ROM I/F) over a substrate 1190. A semiconductor substrate, an SOI substrate, a glass substrate, or the like is used as the substrate 1190. The ROM 1199 and the ROM interface 1189 may be provided over separate chips.

Needless to say, the CPU illustrated in FIG. 52 is just an example of a simplified structure, and an actual CPU may have a variety of structures depending on the usage. For example, the CPU may have a structure where a plurality of cores each including the CPU illustrated in FIG. 52 or an arithmetic circuit are included and the cores operate in parallel, i.e., a GPU-like structure. The number of bits that the CPU can process in an internal arithmetic circuit, a data bus, or the like can be 8, 16, 32, or 64 or more, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device, a peripheral circuit, or the like on the basis of its priority or a mask state, and processes the request. The register controller 1197 generates an address of the register 1196, and reads or writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal on the basis of a reference clock signal, and supplies the internal clock signal to the above various circuits.

In the CPU illustrated in FIG. 52, a memory cell is provided in the register 1196. The register 1196 may include the memory device described in the above embodiment, for example.

In the CPU illustrated in FIG. 52, the register controller 1197 selects a retention operation in the register 1196 in accordance with an instruction from the ALU 1191. That is, the register controller 1197 selects whether data retention by a flip-flop is performed or data retention by a capacitor is performed in the memory cell included in the register 1196. When data retention by the flip-flop is selected, power supply voltage is supplied to the memory cell in the register 1196. When data retention by the capacitor is selected, the data is rewritten into the capacitor, and supply of power supply voltage to the memory cell in the register 1196 can be stopped.

Note that this embodiment can be combined with any of the other embodiments described in this specification as appropriate.

### Embodiment 7

In this embodiment, an example of employing the semiconductor device described in the above embodiment in a display apparatus will be described.

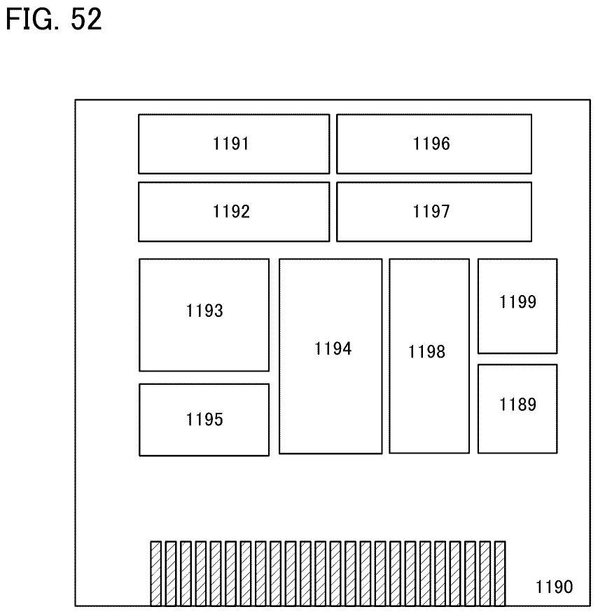

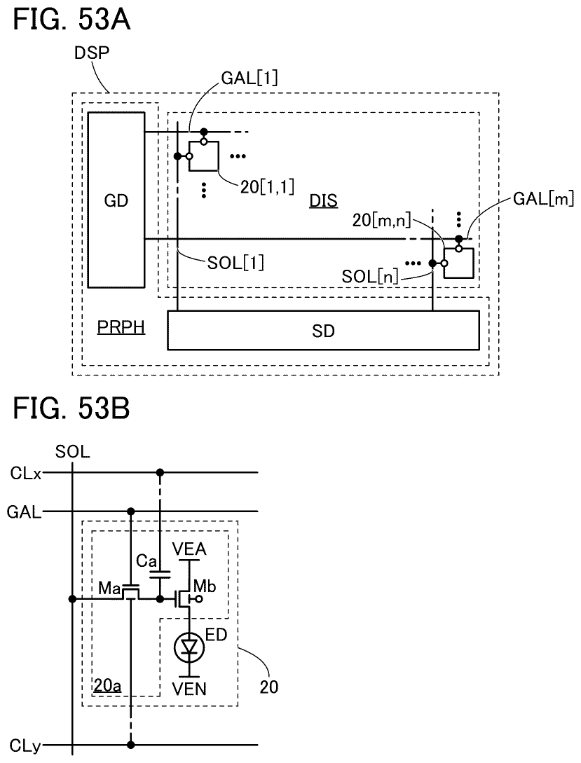

FIG. 53A is a block diagram illustrating an example of a display apparatus.

A display apparatus DSP includes a display portion DIS and a peripheral circuit PRPH. The display portion DIS includes a plurality of pixel circuits 20 arranged in an array, and the peripheral circuit PRPH includes a driver circuit SD and a driver circuit GD.

In the display portion DIS in FIG. 53A, the pixel circuits 20 are arranged in a matrix of m rows and n columns (here, m is an integer of 1 or more and n is an integer of 1 or more), for example. A pixel circuit 20[1,1] is electrically connected to a wiring GAL[1] and a wiring SOL[1]. A pixel circuit 20[m,n] is electrically connected to a wiring GAL[m] and a wiring SOL[n].

The driver circuit GD is electrically connected to the wiring GAL[1] to the wiring GAL[m]. The driver circuit SD is electrically connected to the wiring SOL[1] to the wiring SOL[n].

The driver circuit GD has a function of transmitting selection signals for selecting the pixel circuits 20 to which image data is written, for example. That is, the driver circuit GD is referred to as a gate driver circuit in some cases, for example.

The driver circuit SD has a function of transmitting image data to the pixel circuits 20, for example. That is, the driver circuit SD is referred to as a source driver circuit in some cases, for example.

Next, a circuit structure example of the pixel circuit 20 is described.

FIG. 53B illustrates a structure example of the pixel circuit 20 included in the display portion DIS. The pixel circuit 20 in FIG. 53B includes a circuit portion 20a and a light-emitting device ED, for example.

Examples of the light-emitting device ED include an organic EL element (OLED (Organic Light Emitting Diode)), an inorganic EL element, an LED (including a micro LED), a QLED (Quantum-dot Light Emitting Diode), and a semiconductor laser. Note that in the description in this embodiment, a light-emitting device containing an organic EL material is used as the light-emitting device ED.

The circuit portion 20a includes a transistor Ma, a transistor Mb, and a capacitor Ca.

A first terminal of the transistor Ma is electrically connected to a gate of the transistor Mb and a first terminal of the capacitor Ca, a second terminal of the transistor Ma is electrically connected to a wiring SOL, a gate of the transistor Ma is electrically connected to a wiring GAL, and a back gate of the transistor Ma is electrically connected to a wiring CLy. A first terminal of the transistor Mb is electrically connected to a wiring VEA, and a second terminal of the transistor Mb is electrically connected to an anode of the light-emitting device ED. A cathode of the light-emitting device ED is electrically connected to a wiring VEN.

Note that the wiring VEA functions as a wiring that supplies an anode potential to the light-emitting device ED, for example. The wiring VEN functions as a wiring that supplies a cathode potential to the light-emitting device ED, for example.

A wiring CLx functions as a wiring that supplies a constant potential, for example. The constant potential can be, for example, a high-level potential, a low-level potential, the ground potential, or a negative potential. Similarly, the wiring CLy functions as a wiring that supplies a constant potential, for example. The constant potential can be, for example, a high-level potential, a low-level potential, the ground potential, or a negative potential.

Like the memory cell MC described in Embodiment 1, the circuit portion 20a illustrated in FIG. 53B has a structure that includes two transistors and one capacitor and in which a first terminal of one of the transistors is electrically connected to a first terminal of the capacitor and a gate of the other of the transistors. Thus, the circuit portion 20a can employ the stacked-layer structure described in Embodiment 1.

FIG. 54 illustrates an example of a structure of a display apparatus having the stacked-layer structure described in Embodiment 1.

The display apparatus DSP illustrated in FIG. 54 includes the peripheral circuit PRPH provided over a substrate, a circuit layer 70_k and a circuit layer 70_k+1 (here, k is an integer of 1 or more) provided above the peripheral circuit PRPH, and a light-emitting device layer ELY provided above the circuit layer 70_k and the circuit layer 70_k+1.

As illustrated in FIG. 54, the peripheral circuit PRPH can be provided over a substrate containing a semiconductor as a material, for example. As the substrate containing a semiconductor as a material, a single crystal silicon substrate can be used. In that case, the driver circuit GD and the driver circuit SD each include a silicon transistor. For the silicon transistor, the description of the driver circuit layer 50 in FIG. 50 is referred to.

A plurality of circuit portions 20a of the display portion DIS are provided in the circuit layer 70_k and the circuit layer 70_k+1. As illustrated in FIG. 54, the circuit portion 20a has the same structure as the memory cell MC in FIG. 37 in Embodiment 2.

For example, the transistor Ma illustrated in FIG. 54 corresponds to the transistor M1 in FIG. 37, the transistor Mb illustrated in FIG. 54 corresponds to the transistor M2 in FIG. 37, and the capacitor Ca illustrated in FIG. 54 corresponds to the transistor C1 in FIG. 37. The back gate of the transistor Ma illustrated in FIG. 54 (the wiring CLy illustrated in FIG. 53B) corresponds to the conductor 160_1 in FIG. 37, and the second terminal of the capacitor Ca illustrated in FIG. 54 (the wiring CLx illustrated in FIG. 53B) corresponds to the conductor 160_3 in FIG. 37.

A plurality of light-emitting devices ED are arranged in an array in the light-emitting device layer ELY. A substrate 80 having a light-transmitting property is provided above the plurality of light-emitting devices ED.

The above structure enables the display apparatus DSP to emit light from the light-emitting device ED upward through the substrate 80. In addition, an image can be displayed on the display portion DIS by adjusting the color of light emitted from each light-emitting device ED.

As described in this embodiment, the display apparatus in which the memory cell MC described in Embodiment 1 is used in the circuit portion 20a illustrated in FIG. 53B can be manufactured.

Note that although the structure in which the pixel circuit 20 includes the light-emitting device ED is described as an example in this embodiment, the pixel circuit 20 may include a liquid crystal display device.

Note that this embodiment can be combined with any of the other embodiments described in this specification as appropriate.

### Embodiment 8

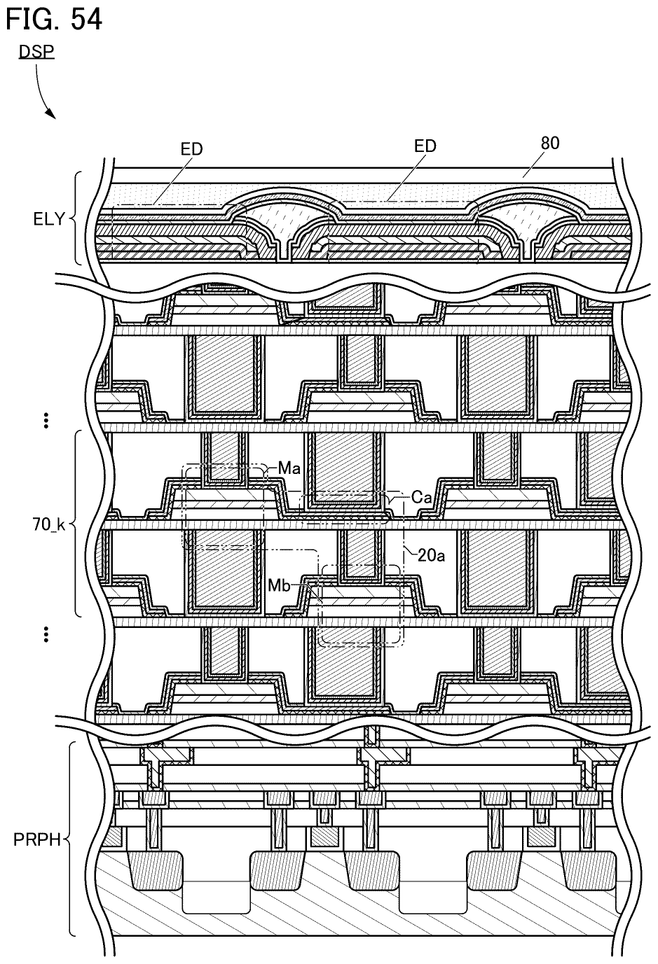

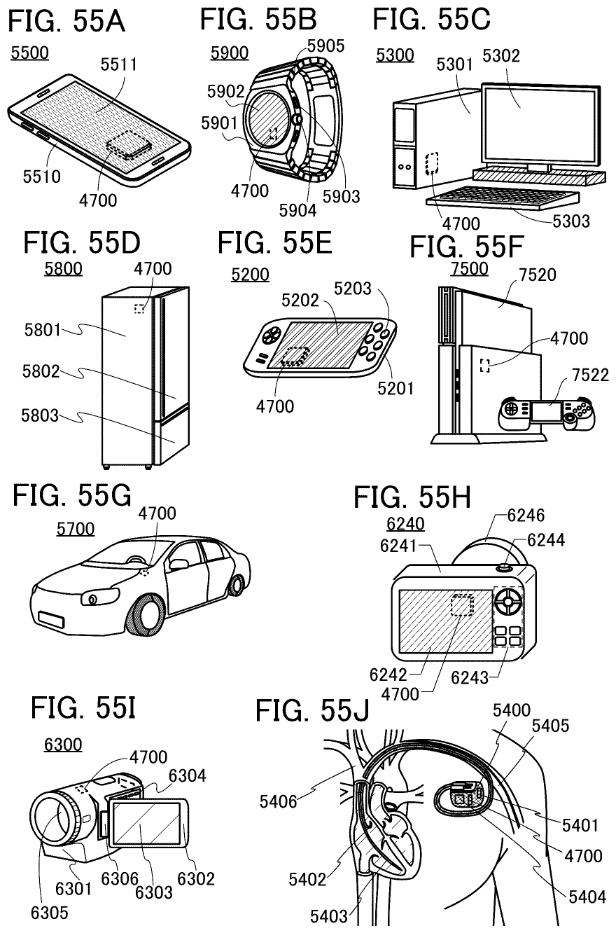

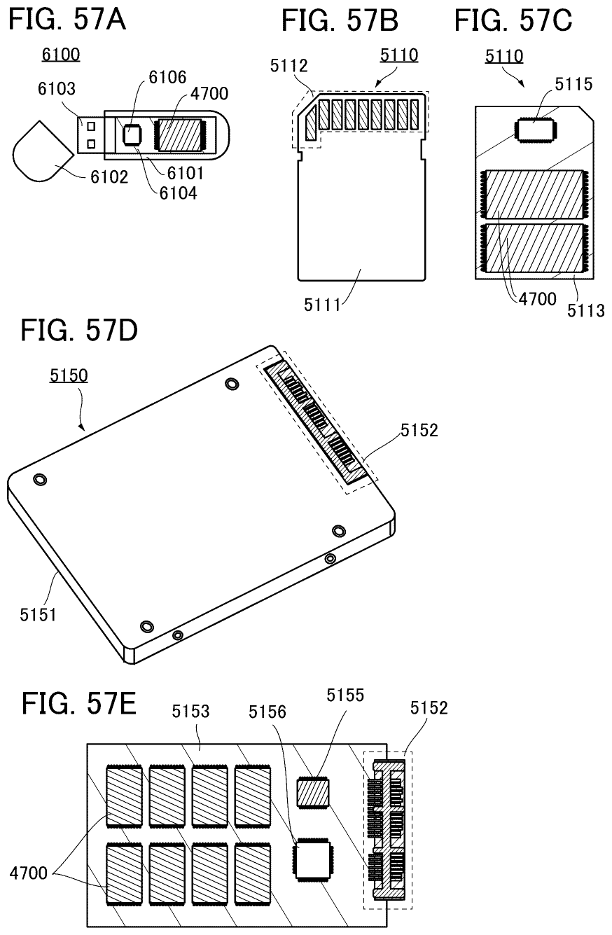

In this embodiment, examples of electronic devices each including the memory device described in the above embodiment are described. FIG. 55A to FIG. 55J and FIG. 57A to FIG. 57E illustrate electronic devices each of which includes the electronic component 4700 including the memory device.

### [Mobile Phone]

An information terminal 5500 illustrated in FIG. 55A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

By using the memory device described in the above embodiment, the information terminal 5500 can retain a temporary file generated at the time of executing an application (e.g., a web browser's cache).

### [Wearable Terminal]

FIG. 55B illustrates an information terminal 5900 that is an example of a wearable terminal. The information terminal 5900 includes a housing 5901, a display portion 5902, an operation button 5903, an crown 5904, and a band 5905.

Like the information terminal 5500 described above, the wearable terminal can retain a temporary file generated at the time of executing an application by using the memory device described in the above embodiment.

### [Information Terminal]

FIG. 55C illustrates a desktop information terminal 5300. The desktop information terminal 5300 includes a main body 5301 of the information terminal, a display 5302, and a keyboard 5303.

Like the information terminal 5500 described above, the desktop information terminal 5300 can retain a temporary file generated at the time of executing an application by using the memory device described in the above embodiment.

Note that although the smartphone, the wearable terminal, and the desktop information terminal are respectively illustrated in FIG. 55A to FIG. 55C as examples of the electronic device, one embodiment of the present invention can be applied to an information terminal other than a smartphone, a wearable information terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

FIG. 55D illustrates an electric refrigerator-freezer 5800 as an example of a household appliance. The electric refrigerator-freezer 5800 includes a housing 5801, a refrigerator door 5802, and a freezer door 5803.

When the memory device described in the above embodiment is used in the electric refrigerator-freezer 5800, the electric refrigerator-freezer 5800 can be used for IoT (Internet of Things), for example. When used for IoT, the electric refrigerator-freezer 5800 can send and receive information on food stored in the electric refrigerator-freezer 5800 and food expiration dates, for example, to/from the above-described information terminal and the like via the Internet. When sending the information, the electric refrigerator-freezer 5800 can retain the information as a temporary file in the memory device.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

FIG. 55E illustrates a portable game machine 5200 that is an example of a game machine. The portable game machine 5200 includes a housing 5201, a display portion 5202, and a button 5203.

FIG. 55F illustrates a stationary game machine 7500 that is another example of a game machine. The stationary game machine 7500 includes a main body 7520 and a controller 7522. Note that the controller 7522 can be connected to the main body 7520 with or without a wire. Furthermore, although not illustrated in FIG. 55F, the controller 7522 can include one or two or more selected from a display portion that displays a game image, and an input interface besides a button, such as a touch panel, a stick, a rotating knob, and a sliding knob, for example. The shape of the controller 7522 is not limited to that illustrated in FIG. 55F, and can be changed variously in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using one or both of a gesture and a voice instead of a controller.

In addition, videos displayed on the game machine can be output with a display apparatus such as a television device, a personal computer display, a game display, or a head-mounted display.

When the memory device described in the above embodiment is used in the portable game machine 5200 and the stationary game machine 7500, the portable game machine 5200 with low power consumption can be achieved. Moreover, heat generation from a circuit can be reduced owing to low power consumption; thus, the influence of heat generation on the circuit itself, a peripheral circuit, and a module can be reduced.

Moreover, with the use of the memory device described in the above embodiment, the portable game machine 5200 and the stationary game machine 7500 can retain a temporary file necessary for arithmetic operation that occurs during game play.

Although FIG. 55E and FIG. 55F illustrate a portable game machine and a stationary game machine, respectively, as examples of game machines, the electronic device of one embodiment of the present invention is not limited thereto. Examples of the electronic device of one embodiment of the present invention include an arcade game machine installed in entertainment facilities (e.g., a game center and an amusement park), and a throwing machine for batting practice installed in sports facilities.

### [Moving Vehicle]

The memory device described in the above embodiment can be used for an automobile, which is a moving vehicle, and around the driver's seat in an automobile.

FIG. 55G illustrates an automobile 5700 that is an example of a moving vehicle.

An instrument panel capable of displaying various kinds of information such as a speedometer, a tachometer, a mileage, a fuel meter, a gearshift state, and air-conditioning settings is provided around the driver's seat in the automobile 5700. In addition, a display device showing the above information may be provided around the driver's seat.

In particular, the display device can compensate for the view obstructed by the pillar or the like, the blind areas for the driver's seat, and the like by displaying a video taken by an imaging device (not illustrated) provided for the automobile 5700, thereby providing a high level of safety.

The memory device described in the above embodiment can temporarily retain data; thus, the memory device can be used to retain temporary data necessary in an automatic driving system for the automobile 5700 and a system for navigation and risk prediction, for example. The display device may be configured to display temporary information regarding navigation, risk prediction, or the like. Moreover, the memory device may be configured to retain a video of a driving recorder provided in the automobile 5700.

Although an automobile is described above as an example of a moving vehicle, the moving vehicle is not limited to an automobile. Examples of moving vehicles include a train, a monorail train, a ship, and a flying object (e.g., a helicopter, an unmanned aircraft (a drone), an airplane, or a rocket).

### [Camera]

The memory device described in the above embodiment can be used for a camera.

FIG. 55H illustrates a digital camera 6240 that is an example of an imaging device. The digital camera 6240 includes a housing 6241, a display portion 6242, operation buttons 6243, and a shutter button 6244, and a detachable lens 6246 is attached to the digital camera 6240. Although the digital camera 6240 is configured here such that the lens 6246 is detachable from the housing 6241 for replacement, the lens 6246 may be integrated with the housing 6241. In addition, the digital camera 6240 can be additionally equipped with a stroboscope or a viewfinder.

When the memory device described in the above embodiment is used for the digital camera 6240, the digital camera 6240 with low power consumption can be achieved. Moreover, heat generation from a circuit can be reduced owing to low power consumption; thus, the influence of heat generation on the circuit itself, a peripheral circuit, and a module can be reduced.

### [Video Camera]

The memory device described in the above embodiment can be used for a video camera.

FIG. 55I illustrates a video camera 6300 that is an example of an imaging device. The video camera 6300 includes a first housing 6301, a second housing 6302, a display portion 6303, operation keys 6304, a lens 6305, and a joint 6306. The operation keys 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Images displayed on the display portion 6303 may be changed in accordance with the angle at the joint 6306 between the first housing 6301 and the second housing 6302.

When images taken by the video camera 6300 are recorded, the images need to be encoded in accordance with a data recording format. By using the above memory device, the video camera 6300 can retain a temporary file generated in encoding.

### [ICD]

The memory device described in the above embodiment can be used for an implantable cardioverter-defibrillator (ICD).

FIG. 55J is a schematic cross-sectional view illustrating an example of an ICD. An ICD main unit 5400 includes at least a battery 5401, the electronic component 4700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor or the like, the number of times the treatment with pacing is performed, and the time taken for the treatment, for example, can be stored in the electronic component 4700.

The antenna 5404 can receive power, and the battery 5401 is charged with the power. Furthermore, when the ICD main unit 5400 includes a plurality of batteries, safety can be increased. Specifically, even when some of the batteries in the ICD main unit 5400 are dead, the other batteries can function properly; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

### [Head-Mounted Display]

The memory device described in the above embodiment can be used for an electronic device for XR (Extended Reality or Cross Reality), such as AR (augmented reality) or VR (virtual reality).

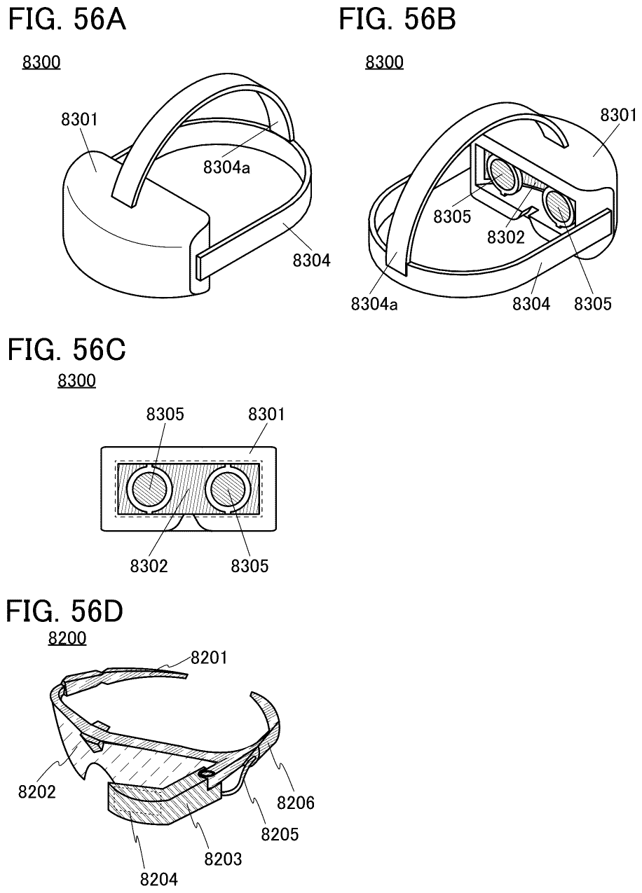

FIG. 56A to FIG. 56C are diagrams illustrating the appearance of an electronic device 8300 that is a head-mounted display. The electronic device 8300 illustrated in FIG. 56A to FIG. 56C includes a housing 8301, a display portion 8302, a band-like fixing member 8304, a fixing member 8304a worn on a head, and a pair of lenses 8305. Note that the electronic device 8300 may include an operation button.

A user can see display on the display portion 8302 through the lenses 8305. Note that the display portion 8302 is preferably curved and placed because the user can feel a high realistic sensation. Another image displayed in another region of the display portion 8302 is seen through the lenses 8305, so that three-dimensional display using parallax or the like can be performed. Note that the structure is not limited to the structure where one display portion 8302 is provided; two display portions 8302 may be provided and one display portion may be provided per eye of the user.

For the display portion 8302, a display apparatus with an extremely high resolution is preferably used, for example. When a high-resolution display apparatus is used for the display portion 8302, it is possible to display a more realistic video that does not allow the user to perceive pixels even when the displayed image is magnified using the lenses 8305 as illustrated in FIG. 56C.

The head-mounted display, which is an electronic device of one embodiment of the present invention, may be an electronic device 8200 illustrated in FIG. 56D, which is a glasses-type head-mounted display.

The electronic device 8200 includes a wearing portion 8201, a lens 8202, a main body 8203, a display portion 8204, a cable 8205, and the like. A battery 8206 is incorporated in the wearing portion 8201.

The cable 8205 supplies electric power from the battery 8206 to the main body 8203. The main body 8203 includes a wireless receiver or the like to receive video data and display it on the display portion 8204. The main body 8203 includes a camera, and data on the movement of eyeballs or eyelids of the user can be used as an input means.

The wearing portion 8201 may be provided with a plurality of electrodes capable of detecting current flowing in response to the movement of the user's eyeball in a position in contact with the user to have a function of recognizing the user's sight line. Furthermore, the wearing portion 8201 may have a function of monitoring the user's pulse with use of current flowing through the electrodes. The wearing portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, and the like.

### [Expansion Device for PC]

The memory device described in the above embodiment can be used for a calculator such as a PC (Personal Computer) and an expansion device for an information terminal.

FIG. 57A illustrates, as an example of the expansion device, a portable expansion device 6100 that includes a chip capable of retaining information and is externally provided on a PC. The expansion device 6100 can store information using the chip when connected to a PC with a USB (Universal Serial Bus) or the like, for example. Note that FIG. 57A illustrates the portable expansion device 6100; however, the expansion device of one embodiment of the present invention is not limited thereto and may be a comparatively large expansion device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the memory device or the like described in the above embodiment. For example, the substrate 6104 is provided with the electronic component 4700 and a controller chip 6106. The USB connector 6103 functions as an interface for connection to an external device.

### [SD Card]

The memory device described in the above embodiment can be used for an SD card that can be attached to an electronic device such as an information terminal or a digital camera.

FIG. 57B is a schematic external diagram of an SD card, and FIG. 57C is a schematic diagram of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, electronic components 4700 and a controller chip 5115 are attached to the substrate 5113. Note that the circuit structures of the electronic components 4700 and the controller chip 5115 are not limited to those described above, and can be changed as appropriate according to circumstances. For example, a write circuit, a row driver, a read circuit, and the like that are provided in an electronic component may be incorporated into the controller chip 5115 instead of the electronic component 4700.

When the electronic components 4700 are provided also on a rear surface side of the substrate 5113, the capacitance of the SD card 5110 can be increased. In addition, a wireless chip with a wireless communication function may be provided on the substrate 5113. This allows wireless communication between an external device and the SD card 5110 and enables data reading and writing from and to the electronic components 4700.

### [SSD]

The memory device described in the above embodiment can be used for an SSD (Solid State Drive) that can be attached to an electronic device such as an information terminal.

FIG. 57D is a schematic external view of an SSD, and FIG. 57E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the electronic components 4700, a memory chip 5155, and a controller chip 5156 are attached to the substrate 5153. When the electronic components 4700 are also provided on a rear surface side of the substrate 5153, the capacity of the SSD 5150 can be increased. A work memory is incorporated in the memory chip 5155. For example, a DRAM chip is used as the memory chip 5155. A processor, an ECC circuit, and the like are incorporated in the controller chip 5156. Note that the circuit structures of the electronic components 4700, the memory chip 5155, and the controller chip 5156 are not limited to those described above, and the circuit structures can be changed as appropriate according to circumstances. For example, a memory functioning as a work memory may also be provided in the controller chip 5156.

The memory device described in the above embodiment is used as each of the memory devices included in the above electronic devices, whereby novel electronic devices can be provided.

Note that this embodiment can be combined with any of the other embodiments described in this specification as appropriate.

### REFERENCE NUMERALS

DEV: semiconductor device, ALYa: memory layer, ALYb: memory layer, ALYc: memory layer, MC: memory cell, MCa: memory cell, MCb: memory cell, MCc: memory cell, M1: transistor, M2: transistor, M3: transistor, C1: capacitor, WBLa: wiring, WBLb: wiring, RBLa: wiring, RBLb: wiring, BLa: wiring, BLb: wiring, WWLa: wiring, WWLb: wiring, SLa: wiring, SLb: wiring, SLc: wiring, CLa: wiring, CLa1: wiring, CLa2: wiring, CLb: wiring, CLb1: wiring, CLb2: wiring, PL: opening, Ma: transistor, Mb: transistor, Ca: capacitor, GAL: wiring, SOL: wiring, CLx: wiring, CLy: wiring, VEN: wiring, VEA: wiring, PRPH: peripheral circuit, DIS: display portion, WL: wiring, SL: wiring, 10: memory cell, 20: pixel circuit, 20a: circuit portion, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 60: memory layer, 60_1: memory layer, 60_2: memory layer, 60_3: memory layer, 60_k: memory layer, 60_N: memory layer, 80: substrate, 100: memory device, 101: insulator, 124: insulator, 124Af: insulating film, 124A: insulating layer, 130: oxide, 130a: oxide, 130b: oxide, 130Af: oxide film, 130Bf: oxide film, 142a: conductor, 142a1: conductor, 142a2: conductor, 142b: conductor, 142b1: conductor, 142b2: conductor, 142Af: conductive film, 142A: conductive layer, 142Bf: conductive film, 142B: conductive layer, 142c: conductor, 142d: conductor, 153_1: insulator, 153_2: insulator, 153_3: insulator, 153A: insulating film, 153AA: insulating film, 154_1: insulator, 154_2: insulator, 154_3: insulator, 154A: insulating film, 154AA: insulating film, 158A: opening, 158B: opening, 159: opening, 160_1: conductor, 160a_1: conductor, 160b_1: conductor, 160_2: conductor, 160a_2: conductor, 160b_2: conductor, 160A: conductive film, 160B: conductive film, 160AA: conductive film, 160BA: conductive film, 160_3: conductor, 175: insulator, 180: insulator, 201: insulator, 224: insulator, 230: oxide, 230a: oxide, 230b: oxide, 242a: conductor, 242a1: conductor, 242a2: conductor, 242b: conductor, 250: conductor, 253: insulator, 253_1: insulator, 254: insulator, 254_1: insulator, 258A: opening, 258B: opening, 260: conductor, 260a: conductor, 260b: conductor, 260_1: conductor, 260a_1: conductor, 260b_1: conductor, 270: conductor, 270a: conductor, 270A: conductive film, 270b: conductor, 270B: conductive film, 270_1: conductor, 272: conductor, 275: insulator, 280: insulator, 301: insulator, 302: conductor, 303: conductor, 311: substrate, 312: insulator, 315: insulator, 316: conductor, 320: insulator, 324: insulator, 326: insulator, 328: conductor, 330: conductor, 350: insulator, 352: insulator, 356: conductor, 357: insulator, 400: transistor, 1189: ROM interface, 1190: substrate, 1192: ALU controller, 1193: instruction decoder, 1194: interrupt controller, 1195: timing controller, 1196: register, 1197: register controller, 1198: bus interface, 1199: ROM, 4700: electronic component, 4702: printed circuit board, 4710: semiconductor device, 4711: mold, 4712: land, 4714: wire, 4730: electronic component, 4735: semiconductor device, 4800: semiconductor wafer, 4801: wafer, 4801a: wafer, 4802: circuit portion, 4803: spacing, 4803a: spacing, 5110: SD card, 5111: housing, 5112: connector, 5113: substrate, 5115: controller chip, 5151: housing, 5152: connector, 5153: substrate, 5156: controller chip, 5200: portable game machine, 5201: housing, 5202: display portion, 5203: button, 5300: desktop information terminal, 5301: main body, 5302: display, 5303: keyboard, 5400: ICD main unit, 5401: battery, 5402: wire, 5403: wire, 5404: antenna, 5500: information terminal, 5510: housing, 5511: display portion, 5700: automobile, 5800: electric refrigerator-freezer, 5801: housing, 5802: refrigerator door, 5803: freezer door, 5900: information terminal, 5901: housing, 5902: display portion, 5903: operation button, 5904: crown, 5905: band, 6100: expansion device, 6101: housing, 6102: cap, 6103: USB connector, 6104: substrate, 6106: controller chip, 6240: digital camera, 6241: housing, 6243: operation button, 6246: lens, 6242: display portion, 6301: first housing, 6302: second housing, 6303: display portion, 6304: operation key, 6305: lens, 6306: joint, 7500: stationary game machine, 7520: main body, 7522: controller, 8200: electronic device, 8201: wearing portion, 8202: lens, 8203: main body, 8204: display portion, 8205: cable, 8206: battery, 8300: electronic device, 8301: housing, 8302: display portion, 8304: fixing member, 8304a: fixing member, 8305: lens

1. A semiconductor device comprising:
a first layer and a first insulator,
wherein the first layer is located on a top surface of the first insulator,
wherein the first layer comprises a first transistor, a second transistor, a first conductor, a second conductor, a second insulator, and a third insulator,
wherein each of the first transistor and the second transistor comprises a source electrode, a drain electrode, a gate electrode, and an oxide semiconductor,
wherein the oxide semiconductor of the first transistor is located above the first insulator,
wherein each of the source electrode and the drain electrode of the first transistor is located on a top surface and a side surface of the oxide semiconductor of the first transistor and the top surface of the first insulator,
wherein the gate electrode of the first transistor is located in a region overlapping with the oxide semiconductor of the first transistor,
wherein the second insulator is located above the first insulator and each of the source electrode and the drain electrode of the first transistor,
wherein the second insulator comprises a first opening reaching the first insulator, in a region not overlapping with the source electrode or the drain electrode of the first transistor,
wherein the first conductor is located in the first opening,
wherein the third insulator is located on a top surface of the second insulator, a top surface of the first conductor, and a top surface of the gate electrode of the first transistor,
wherein the third insulator comprises a second opening reaching the gate electrode of the first transistor, in a region above the gate electrode of the first transistor,
wherein the second conductor is located in the second opening,
wherein the oxide semiconductor of the second transistor is located above the third insulator in a region overlapping with the first conductor,
wherein one of the source electrode and the drain electrode of the second transistor is located on a top surface and a side surface of the oxide semiconductor of the second transistor and a top surface of the third insulator,
wherein the other of the source electrode and the drain electrode of the second transistor is located on the top surface and the side surface of the oxide semiconductor of the second transistor, the top surface of the third insulator, and a top surface of the second conductor, and
wherein the gate electrode of the second transistor is located in a region overlapping with the oxide semiconductor of the second transistor.

2. The semiconductor device according to claim 1,
wherein the first layer comprises a fourth insulator, a fifth insulator, and a third conductor,
wherein the fourth insulator is located above the third insulator and each of the source electrode and the drain electrode of the second transistor,
wherein the fourth insulator comprises a third opening reaching the other of the source electrode and the drain electrode of the second transistor, in a region not overlapping with the oxide semiconductor of the second transistor,
wherein the fifth insulator is located on the top surface of the second conductor in the third opening and a side surface of the third insulator in the third opening, and
wherein the third conductor is located on a top surface of the fifth insulator.

3. The semiconductor device according to claim 2,
wherein the gate electrode of the first transistor and the first conductor comprise the same conductive material, and
wherein the gate electrode of the second transistor and the third conductor comprise the same conductive material.

4. The semiconductor device according to claim 3, further comprising:
a second layer and a sixth insulator,
wherein the second layer is located on a top surface of the sixth insulator,
wherein the second layer comprises a third transistor,
wherein the third transistor comprises an oxide semiconductor,
wherein the sixth insulator is located on a top surface of the fourth insulator, the top surface of the fifth insulator, a top surface of the third conductor, and a top surface of the gate electrode of the second transistor, and
wherein the oxide semiconductor of the third transistor is located above the sixth insulator in a region overlapping with the third conductor.

5. The semiconductor device according to claim 4,
wherein each of the oxide semiconductor of the first transistor, the oxide semiconductor of the second transistor, and the oxide semiconductor of the third transistor comprises one or more selected from indium, zinc, and an element M, and
wherein the element M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium.

6. A memory device comprising the semiconductor device according to claim 1, and a driver circuit,
wherein the first layer is located above the driver circuit.

7. An electronic device comprising the memory device according to claim 6, and a housing.

8. A semiconductor device comprising:
a first transistor; and
a second transistor over the first transistor,
wherein each of the first transistor and the second transistor comprises a source electrode, a drain electrode, a first gate electrode over an oxide semiconductor, a second gate electrode, and the oxide semiconductor over the second gate electrode, and
wherein the first gate electrode of the first transistor and the second gate electrode of the second transistor are formed by a same conductive film.

9. A semiconductor device comprising:
a first transistor;
a second transistor over the first transistor;
a third transistor over the second transistor; and
a capacitor over the first transistor,
wherein each of the first transistor, the second transistor, and the third transistor comprises a source electrode, a drain electrode, a first gate electrode over an oxide semiconductor, a second gate electrode, and the oxide semiconductor over the second gate electrode,
wherein a first conductor comprising a region configured to be one of the source electrode and the drain electrode of the second transistor comprises a region configured to be a first electrode of the capacitor,
wherein a second conductor comprising a region configured to be the second gate electrode of the third transistor comprises a region configured to be a second electrode of the capacitor, and
wherein the one of the source electrode and the drain electrode of the second transistor is electrically connected to the first gate electrode of the first transistor.
